(19) United States
(12) Patent Application Publication
(10) Pub. No.: US 2024/0407211 A1
(43) Pub. Date: Dec. 5, 2024

(54) DISPLAY DEVICE

(71) Applicant: SEMICONDUCTOR ENERGY LABORATORY CO., LTD., Atsugi-shi, Kanagawa-ken (JP)

(72) Inventors: Masahiro KATAYAMA, Isehara, Kanagawa (JP); Yukinori SHIMA, Tatebayashi, Gunma (JP); Masataka NAKADA, Tochigi, Tochigi (JP); Shingo EGUCHI, Atsugi, Kanagawa (JP); Daiki NAKAMURA, Atsugi, Kanagawa (JP); Koji KUSUNOKI, Isehara, Kanagawa (JP); Kensuke YOSHIZUMI, Atsugi, Kanagawa (JP)

(21) Appl. No.: 18/695,104

(22) PCT Filed: Sep. 21, 2022
(86) PCT No.: PCT/IB2022/058903

§ 371 Date: Mar. 25, 2024

(30) Foreign Application Priority Data
Sep. 30, 2021 (JP) 2021-160928

(51) Int. Cl. H10K 59/131; H10K 50/19; H10K 59/38

(52) U.S. Cl. CPC H10K 59/131; H10K 50/19; H10K 59/38

(57) ABSTRACT

A display device in which a voltage drop is inhibited adequately is provided. The display device includes a common electrode included in a first light-emitting device in which a plurality of light-emitting layers are stacked and a second light-emitting device in which a plurality of light-emitting layers are stacked and an auxiliary wiring electrically connected to the common electrode. The auxiliary wiring includes a first wiring layer and a second wiring layer, the second wiring layer is electrically connected to the first wiring layer through a contact hole of an insulating layer, and the first wiring laver has a lattice shape in a top view.

### TECHNICAL FIELD

One embodiment of the present invention relates to a display device.

Note that one embodiment of the present invention is not limited to the above technical field. Examples of the technical field of one embodiment of the present invention disclosed in this specification and the like include a semiconductor device, a light-emitting apparatus, a power storage device, a memory device, an electronic device, a lighting device, an input device, an input/output device, and a manufacturing method thereof.

### BACKGROUND ART

An active matrix display device using an organic EL element with a structure in which an auxiliary wiring is provided has been proposed (see Patent Document 1).

There has been a problem in which the above auxiliary wiring is placed around the organic EL element and consequently the layout space of the auxiliary wiring restricts the aperture ratio of a pixel (see Patent Document 2).

As a method for manufacturing an organic EL element, a method for manufacturing an organic optoelectronic device employing standard UV photolithography is disclosed (see Non-Patent Document 1).

### REFERENCES

### Patent Documents

[Patent Document 1] Japanese Published Patent Application No. 2006-58815
[Patent Document 2] Japanese Published Patent Application No. 2010-85866

### Non-Patent Document

[Non-Patent Document 1] B. Lamprecht et al., “Organic optoelectronic device fabrication using standard UV photolithography”, phys. stat. sol. (RRL) 2, No. 1, pp. 16-18 (2008).

### SUMMARY OF THE INVENTION

### Problems to be Solved by the Invention

In order to solve the above problem, Patent Document 2 proposes a structure including an upper electrode connection wiring provided in a layer that is the same as a lower electrode of a light-emitting element and a lower auxiliary wiring (also referred to as a resistance adjusting wiring) provided below the lower electrode.

In the structure described in Patent Document 2, the lower auxiliary wiring is formed in the same layer as a signal line, a power supply line, or a scan line. The lower auxiliary wiring cannot be in contact with the signal line, the power supply line, and the scan line, thereby placing restrictions on the layout of the lower auxiliary wiring. Such a lower auxiliary wiring has not achieved adequate inhibition of a voltage drop, which is the effect of the auxiliary wiring.

It is difficult to provide a high-resolution display device by the method disclosed in Non-Patent Document 1.

In view of the above, an object of one embodiment of the present invention is to provide an auxiliary wiring capable of inhibiting a voltage drop adequately, or specifically, an auxiliary wiring having a novel structure. Another object is to provide a display device including the auxiliary wiring.

Note that the description of these objects does not preclude the existence of other objects. These objects should be construed as being independent of one another. One embodiment of the present invention only needs to achieve at least one of these objects and does not necessarily achieve all the objects. Other objects can be derived from the description of the specification, the drawings, and the claims, which are this specification and the like.

### Means for Solving the Problems

In view of the above, one embodiment of the present invention is a display device that includes the following: a first light-emitting device including a first lower electrode, a first light-emitting layer positioned over the first lower electrode, a first layer positioned over the first light-emitting layer, and a second light-emitting layer positioned over the first layer; a second light-emitting device including a second lower electrode, a third light-emitting layer positioned over the second lower electrode, a second layer positioned over the third light-emitting layer, and a fourth light-emitting layer positioned over the second layer; a common electrode included in the first light-emitting device and the second light-emitting device; and an auxiliary wiring electrically connected to the common electrode. A color exhibited by a light-emitting material included in the first light-emitting layer is the same as a color exhibited by a light-emitting material included in the second light-emitting layer. A color exhibited by a light-emitting material included in the third light-emitting layer is the same as a color exhibited by a light-emitting material included in the fourth light-emitting layer. The first layer and the second layer each include lithium. The auxiliary wiring includes a first wiring layer and a second wiring layer. The second wiring layer is electrically connected to the first wiring layer through a contact hole of an insulating layer. The first wiring layer has a lattice shape in a top view.

Another embodiment of the present invention is a display device that includes the following: a first light-emitting device including a first lower electrode, a first light-emitting layer positioned over the first lower electrode, a first layer positioned over the first light-emitting layer, and a second light-emitting layer positioned over the first layer; a second light-emitting device including a second lower electrode, a third light-emitting layer positioned over the second lower electrode, a second layer positioned over the third light-emitting layer, and a fourth light-emitting layer positioned over the second layer; a common electrode included in the first light-emitting device and the second light-emitting device; and an auxiliary wiring electrically connected to the common electrode. A color exhibited by a light-emitting material included in the first light-emitting layer is the same as a color exhibited by a light-emitting material included in the second light-emitting layer. A color exhibited by a light-emitting material included in the third light-emitting layer is the same as a color exhibited by a light-emitting material included in the fourth light-emitting layer. The first layer and the second layer each include lithium. The auxiliary wiring includes a first wiring layer and a second wiring layer. The second wiring layer is electrically connected to the first wiring layer through a contact hole of an insulating layer. The first wiring layer has a lattice shape in a top view. Each of the first lower electrode, the second lower electrode, and the second wiring layer includes a region positioned over the insulating layer.

Another embodiment of the present invention is a display device that includes the following: a first light-emitting device including a first lower electrode, a first light-emitting layer positioned over the first lower electrode, a first layer positioned over the first light-emitting layer, and a second light-emitting layer positioned over the first layer; a second light-emitting device including a second lower electrode, a third light-emitting layer positioned over the second lower electrode, a second layer positioned over the third light-emitting layer, and a fourth light-emitting layer positioned over the second laver; a common electrode included in the first light-emitting device and the second light-emitting device, and an auxiliary wiring electrically connected to the common electrode. A color exhibited by a light-emitting material included in the first light-emitting layer is the same as a color exhibited by a light-emitting material included in the second light-emitting layer. A color exhibited by a light-emitting material included in the third light-emitting layer is the same as a color exhibited by a light-emitting material included in the fourth light-emitting layer. The first layer and the second layer each include lithium. The auxiliary wiring includes a first wiring layer and a second wiring layer. The second wiring layer is electrically connected to the first wiring layer through a contact hole of an insulating layer. Each of the first wiring layer and the second wiring layer has a lattice shape in atop view. Each of the first lower electrode, the second lower electrode, and the second wiring layer includes a region positioned over the insulating layer. The width of the second wiring layer is smaller than the width of the first wiring layer.

Another embodiment of the present invention is a display device that includes the following: a first light-emitting device including a first lower electrode, a first light-emitting layer positioned over the first lower electrode, a first layer positioned over the first light-emitting layer, and a second light-emitting layer positioned over the first layer; a first color filter positioned to overlap with the first light-emitting device; a second light-emitting device including a second lower electrode, a third light-emitting layer positioned over the second lower electrode, a second layer positioned over the third light-emitting laver, and a fourth light-emitting layer positioned over the second layer; a second color filter positioned to overlap with the second light-emitting device; a common electrode included in the first light-emitting device and the second light-emitting device; and an auxiliary wiring electrically connected to the common electrode. A color exhibited by a light-emitting material included in the first light-emitting layer is the same as a color exhibited by a light-emitting material included in the second light-emitting layer. A color exhibited by a light-emitting material included in the third light-emitting layer is the same as a color exhibited by a light-emitting material included in the fourth light-emitting layer. The first layer and the second layer each include lithium. The auxiliary wiring includes a first wiring layer and a second wiring layer. The second wiring layer is electrically connected to the first wiring layer through a contact hole of an insulating layer. The first wiring layer has a lattice shape in a top view.

Another embodiment of the present invention is a display device that includes the following: a first light-emitting device including a first lower electrode, a first light-emitting layer positioned over the first lower electrode, a first laver positioned over the first light-emitting layer, and a second light-emitting layer positioned over the first layer; a first color filter positioned to overlap with the first light-emitting device; a second light-emitting device including a second lower electrode, a third light-emitting layer positioned over the second lower electrode, a second layer positioned over the third light-emitting layer, and a fourth light-emitting layer positioned over the second laver; a second color filter positioned to overlap with the second light-emitting device; a common electrode included in the first light-emitting device and the second light-emitting device; and an auxiliary wiring electrically connected to the common electrode. A color exhibited by a light-emitting material included in the first light-emitting layer is the same as a color exhibited by a light-emitting material included in the second light-emitting layer. A color exhibited by a light-emitting material included in the third light-emitting layer is the same as a color exhibited by a light-emitting material included in the fourth light-emitting layer. The first layer and the second layer each include lithium. The auxiliary wiring includes a first wiring layer and a second wiring layer. The second wiring layer is electrically connected to the first wiring layer through a contact hole of an insulating layer. The first wiring layer has a lattice shape in a top view. Each of the first lower electrode, the second lower electrode, and the second wiring layer includes a region positioned over the insulating layer.

Another embodiment of the present invention is a display device that includes the following: a first light-emitting device including a first lower electrode, a first light-emitting layer positioned over the first lower electrode, a first laver positioned over the first light-emitting layer, and a second light-emitting layer positioned over the first layer; a first color filter positioned to overlap with the first light-emitting device; a second light-emitting device including a second lower electrode, a third light-emitting layer positioned over the second lower electrode, a second layer positioned over the third light-emitting layer, and a fourth light-emitting layer positioned over the second layer; a second color filter positioned to overlap with the second light-emitting device; a common electrode included in the first light-emitting device and the second light-emitting device; and an auxiliary wiring electrically connected to the common electrode. A color exhibited by a light-emitting material included in the first light-emitting layer is the same as a color exhibited by a light-emitting material included in the second light-emitting layer. A color exhibited by a light-emitting material included in the third light-emitting layer is the same as a color exhibited by a light-emitting material included in the fourth light-emitting layer. The first layer and the second layer each include lithium. The auxiliary wiring includes a first wiring layer and a second wiring layer. The second wiring layer is electrically connected to the first wiring layer through a contact hole of an insulating layer. Each of the first wiring layer and the second wiring layer has a lattice shape in a top view. Each of the first lower electrode, the second lower electrode, and the second wiring layer includes a region positioned over the insulating layer. The width of the second wiring layer is smaller than the width of the first wiring layer.

According to another embodiment of the present invention, the distance between the first lower electrode and the common electrode is preferably shorter than the distance between the second lower electrode and the common electrode.

According to another embodiment of the present invention, end portions of the first lower electrode and the second lower electrode each preferably have a tapered shape.

According to another embodiment of the present invention, in a cross-sectional view, the taper angle of an end surface of an organic compound layer including the first light-emitting layer and the second light-emitting layer is preferably greater than or equal to 45° and less than 90°.

According to another embodiment of the present invention, in a cross-sectional view, the taper angle of an end surface of an organic compound layer including the third light-emitting layer and the fourth light-emitting layer is preferably greater than or equal to 45° and less than 90°.

### Effect of the Invention

According to one embodiment of the present invention, an auxiliary wiring having a novel structure can be provided. A display device in which a voltage drop is adequately inhibited owing to the auxiliary wiring can be provided.

Note that the description of these effects does not preclude the existence of other effects. These effects should be construed as being independent of one another. One embodiment of the present invention only needs to have at least one of these effects and does not necessarily have all the effects. Other effects can be derived from the description of the specification, the drawings, and the claims, which are this specification and the like.

### BRIEF DESCRIPTION OF THE DRAWINGS

FIG. 1A and FIG. 1B are diagrams each illustrating a pixel portion including an auxiliary wiring.

FIG. 2A and FIG. 2B are diagrams each illustrating a pixel portion including an auxiliary wiring.

FIG. 3A is a perspective view of an auxiliary wiring, and FIG. 3B and FIG. 3C are each a top view of a pixel portion.

FIG. 4A to FIG. 4F are each a top view of a pixel portion including an auxiliary wiring.

FIG. 5A is a perspective view of an auxiliary wiring, and FIG. 5B and FIG. 5C are each a top view of a pixel portion.

FIG. 6A and FIG. 6B are each a perspective view of an auxiliary wiring.

FIG. 7A and FIG. 7B are diagrams each illustrating a pixel portion including an auxiliary wiring.

FIG. 8A and FIG. 8B are diagrams each illustrating a pixel portion including an auxiliary wiring.

FIG. 9A is a cross-sectional view of an auxiliary wiring, and FIG. 9B and FIG. 9C are each a top view of a pixel portion.

FIG. 10A to FIG. 10I are each a top view of a pixel portion and an auxiliary wiring.

FIG. 11A to FIG. 11F are each a top view of a pixel portion and an auxiliary wiring.

FIG. 12A to FIG. 12F are each a top view of a pixel portion and an auxiliary wiring.

FIG. 13A is a top view of a pixel portion, FIG. 13B is a cross-sectional view of the pixel portion, and FIG. 13C is a cross-sectional view of a connection portion.

FIG. 14A and FIG. 14B are cross-sectional views of light-emitting devices.

FIG. 15A and FIG. 15B are cross-sectional views of light-emitting devices.

FIG. 16A is a circuit diagram of a display device and the like, and FIG. 16B to FIG. 16E are pixel circuit diagrams.

FIG. 17A to FIG. 17D are cross-sectional views of transistors.

FIG. 18A to FIG. 18C are each a top view of a pixel portion, and FIG. 18D is a circuit diagram.

FIG. 19A to FIG. 19C are cross-sectional views illustrating a manufacturing method.

FIG. 20A to FIG. 20C are cross-sectional views illustrating a manufacturing method.

FIG. 21A to FIG. 21C are cross-sectional views illustrating a manufacturing method.

FIG. 22A to FIG. 22C are cross-sectional views illustrating a manufacturing method.

FIG. 23A and FIG. 23B are cross-sectional views illustrating a manufacturing method.

FIG. 24A to FIG. 24C are cross-sectional views illustrating a manufacturing method.

FIG. 25 is a cross-sectional view illustrating a manufacturing method.

FIG. 26 is a cross-sectional view illustrating a manufacturing method.

FIG. 27A is a top view of a display device, and FIG. 27B and FIG. 27C are perspective views of the display device.

FIG. 28A and FIG. 28B are each a cross-sectional view of a display device.

FIG. 29A and FIG. 29B are each a cross-sectional view of a display device.

FIG. 30A and FIG. 30B are perspective views of a display device.

FIG. 31A to FIG. 31D are diagrams of electronic devices.

FIG. 32A and FIG. 32B are diagrams of an electronic device.

### MODE FOR CARRYING OUT THE INVENTION

In this specification and the like, components are classified based on their functions and the components are described using independent blocks in a diagram in some cases, however, it is difficult to classify actual components based on their functions, and one component may have a plurality of functions.

In this specification and the like, the terms “source” and “drain” of a transistor interchange with each other depending on the polarity of the transistor or the levels of potentials applied to the terminals. In general, in an n-channel transistor, a terminal to which a lower potential is supplied is called a source, and a terminal to which a higher potential is supplied is called a drain. In a p-channel transistor, a terminal to which a lower potential is supplied is called a drain, and a terminal to which a higher potential is supplied is called a source. Although the names of the source and the drain sometimes interchange with each other in reality depending on the above-described relationship of potentials, a source and a drain are fixed for convenience in the description of the connection relationship of a transistor in this specification and the like.

In this specification and the like, a source of a transistor means a source region that is part of a semiconductor layer functioning as an active layer or means a source electrode connected to the source region. Similarly, a drain of a transistor means a drain region that is part of the semiconductor film or a drain electrode connected to the drain region. Moreover, a gate of a transistor means a gate electrode.

In this specification and the like, a state where transistors are connected in series means, for example, a state where only one of a source and a drain of a first transistor is connected to only one of a source and a drain of a second transistor. In addition, a state where transistors are connected in parallel means a state where one of a source and a drain of a first transistor is connected to one of a source and a drain of a second transistor and the other of the source and the drain of the first transistor is connected to the other of the source and the drain of the second transistor.

In this specification and the like, connection is sometimes referred to as electrical connection and includes a state where current, voltage, or a potential can be supplied or transmitted. Accordingly, connection includes connection via an element such as a wiring, a resistor, a diode, or a transistor. Electrical connection includes direct connection without via an element such as a wiring, a resistor, a diode, or a transistor.

In this specification and the like, a first electrode and a second electrode are used for description of a source and a drain of a transistor in some cases; when one of the first electrode and the second electrode refers to a source, the other thereof refers to a drain.

In this specification and the like, a conductive layer sometimes has a plurality of functions such as those of a wiring and an electrode.

In this specification and the like, a tapered shape indicates a shape in which at least part of a side surface of a structure inclined to a formation surface or a substrate surface. For example, an angle formed by an inclined side surface and a substrate surface is referred to as a taper angle, and a tapered shape indicates a region whose taper angle is less than 90°. Note that a side surface of the structure may be a substantially planar surface having a fine curvature or a substantially planar surface having a fine unevenness. The taper angle can be measured by providing a line from a top end to a bottom end of the side surface of the structure. Similarly, the formation surface or the substrate surface may be a substantially planar surface having a fine curvature or a substantially planar surface having a fine unevenness.

In this specification and the like, a light-emitting device is referred to as a light-emitting element in some cases. In the light-emitting device, an organic compound layer which is a stack in which functional layers are stacked between a pair of electrodes is positioned. Examples of the functional layers include a light-emitting layer, carrier-injection layers (a hole-injection layer and an electron-injection layer), carrier-transport layers (a hole-transport layer and an electron-transport layer), carrier-blocking layers (a hole-blocking layer and an electron-blocking layer), and the like. The hole-injection layer refers to a layer containing a substance having a high hole-injection property. The electron-injection layer refers to a layer containing a substance having a high electron-injection property. The hole-transport layer refers to a layer containing a substance having a high hole-transport property. The electron-transport layer refers to a layer containing a substance having a high electron-transport property. The hole-blocking layer refers to a layer containing a substance with a high hole-blocking property. The electron-blocking layer refers to a layer containing a substance with a high electron-blocking property.

The light-emitting device can function when the above functional layers include no layers other than the light-emitting layer. The functional layer contains an inorganic material or an inorganic compound material in addition to the organic compound material in some cases. Thus, the organic compound layer positioned between a pair of electrodes is referred to as an EL layer or a light-emitting unit in some cases.

In this specification and the like, one of a pair of electrodes included in the light-emitting device functions as an anode and the other functions as a cathode. One of the pair of electrodes may be referred to as a lower electrode and the other may be referred to as an upper electrode. One of the pair of electrodes that is positioned on the extraction side of light from the light-emitting laver may be referred to as an extraction electrode and the other may be referred to as a counter electrode. Note that one and the other are just examples and can be interchanged with each other.

In this specification and the like, a light-emitting device formed using a metal mask or an FMM (a fine metal mask or a high-resolution metal mask) may be referred to as a device having an MM (metal mask) structure. In this specification and the like, a light-emitting device formed using neither a metal mask nor an FMM may be referred to as a device having an MML (metal maskless) structure.

In this specification and the like, light-emitting devices exhibiting, for example, red, green, and blue are sometimes referred to as a red-light-emitting device, a green-light-emitting device, and a blue-light-emitting device, respectively. Fabrication of a red-light-emitting device, a green-light-emitting device, and a blue-light-emitting device enables a full-color display device to be provided.

In this specification and the like, a structure in which light-emitting layers of light-emitting devices with different emission wavelengths are separately formed is sometimes referred to as an SBS (Side By Side) structure. For example, a red-light-emitting device, a green-light-emitting device, and a blue-light-emitting device can be fabricated using an SBS structure. In an SBS structure, materials of the functional layers or stacked-layer structures of the functional layers can be optimized for each light-emitting device and can accordingly be selected with considerable freedom, whereby the luminance and the reliability can be easily improved.

In this specification and the like, a light-emitting device in which a plurality of light-emitting layers are stacked can employ a tandem structure. In the tandem structure, two or more light-emitting units are provided between a pair of electrodes. Each of the two or more light-emitting units includes one or more light-emitting layers. In the tandem structure, a charge-generation or the like is preferably provided between the two or more light-emitting units. The charge-generation layer has a function of injecting holes into one of the light-emitting units that is formed in contact with the charge-generation layer and a function of injecting electrons into the other light-emitting unit, when voltage is applied between the cathode and the anode. This indicates that the charge-generation layer is positioned between light-emitting units. Thus, the charge-generation layer is referred to as an intermediate layer in some cases. Note that one and the other are just examples and can be interchanged with each other.

In this specification and the like, a light-receiving device is referred to as a light-receiving element in some cases. The light-receiving device includes at least an active layer that functions as a photoelectric conversion layer between a pair of electrodes.

In this specification and the like, the mask layer has a function of protecting the light-emitting layer of the light-emitting device or the active layer of the light-receiving device in the manufacturing process. Specifically, the mask layer is formed in a position that can prevent the light-emitting layer or the active layer from suffering damage due to processing when the light-emitting device or the light-receiving device is processed. In the process of manufacturing the light-emitting device or the light-receiving device, the mask layer may be removed entirely or may be left partly. The mask layer may be referred to as a sacrificial layer.

In this specification and the like, a structure in which a connector such as an FPC (Flexible Printed Circuit) or a TCP (Tape Carrier Package) is attached to a substrate of a display panel, or a structure in which an IC is mounted on a substrate by a COG (Chip On Glass) method or the like is referred to as a display module in some cases. Thus, the display module is one embodiment of a display device.

Next, embodiments will be described in detail with reference to the drawings. Note that the present invention is not limited to the following description, and it will be readily understood by those skilled in the art that modes and details of the present invention can be modified in various ways without departing from the spirit and scope of the present invention. Thus, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

In this embodiment, a structure example of a display device of one embodiment of the present invention will be described.

### <Function of Auxiliary Wiring>

The display device of one embodiment of the present invention includes an auxiliary wiring. The auxiliary wiring refers to a layer having an auxiliary function for a main electrode, and an example of the auxiliary function is a function of inhibiting a voltage drop caused by the main electrode. An example of the main electrode is an extraction electrode of a light-emitting device. The extraction electrode is formed using a so-called transparent conductive material that transmits visible light in order for light from the light-emitting layer to be extracted. As a transparent conductive material, an oxide containing indium and tin (referred to as ITO in some cases) is given and ITO is known to have higher resistivity than metals. In view of the above, the auxiliary wiring is electrically connected to the extraction electrode in order to inhibit a voltage drop caused by the extraction electrode. In the structure where the extraction electrode and the auxiliary wiring are electrically connected, the extraction electrode includes a conductive material with high resistivity and the auxiliary wiring includes a conductive material with low resistivity.

The extraction electrode can be a continuous layer without being divided between a plurality of light-emitting devices. A continuous layer is referred to as a common layer and a continuous electrode is referred to as a common electrode in some cases. The extraction electrode has a larger area with an increase in the size of the display device and is formed using ITO, thereby easily causing a voltage drop. In view of this, the structure where the auxiliary wiring is electrically connected to the extraction electrode to inhibit the voltage drop caused by the extraction electrode is suitable for a large display device.

Note that the auxiliary wiring is sometimes referred to as an auxiliary electrode according to its shape; in this specification and the like, description is made using the term “auxiliary wiring” regardless of its shape.

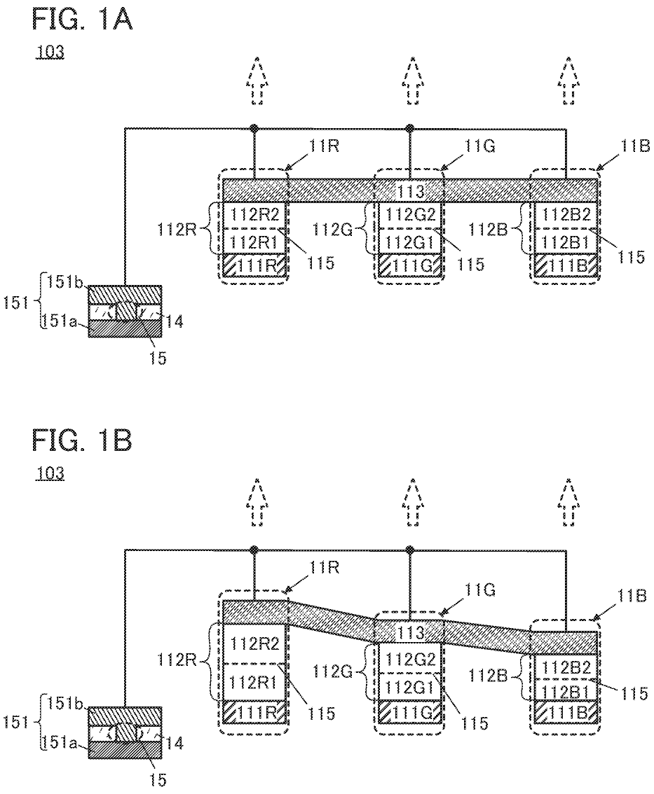

FIG. 1A is a conceptual diagram of a pixel portion 103 included in the display device of one embodiment of the present invention.

### <Feature of Auxiliary Wiring>

The auxiliary wiring 151 of one embodiment of the present invention has a novel structure in which two or more wiring layers provided in different layers are included. The auxiliary wiring 151 includes a first wiring layer 151a and a second wiring layer 151b as illustrated in FIG. 1A, for example. The first wiring layer 151a is formed in a layer different from that of the second wiring layer 151b, and the formation surface of the first wiring layer 151a can be regarded as being different from the formation surface of the second wiring layer 151b. Wiring layers whose formation surfaces are different from each other are referred to as wiring layers provided in different layers.

Note that the wiring layer is sometimes referred to as an electrode layer according to its shape, in this specification and the like, description is made using the term “wiring layer” regardless of its shape.

As illustrated in FIG. 1A, an insulating layer 14 is positioned between the first wiring layer 151a and the second wiring layer 151b. The first wiring layer 151a is electrically connected to the second wiring layer 151b through a contact hole 15 of the insulating layer 14.

Although the two wiring layers formed in different layers are described, three or more wiring layers may be formed in different layers. Such wiring layers are referred to as a multilayered wiring layer in some cases. The effect of the multilayered wiring layer is that each wiring layer has high flexibility in the layout. For example, one of the multilayered wiring layer can be laid out in a layer different from a lower electrode. Then, the one wiring layer is not restricted by the layout of the lower electrode. Furthermore, the one wiring layer can also secure a large area so as to overlap with the lower electrode. Such a multilayered wiring layer can function as the auxiliary wiring, establishing electrical interconnection through a contact hole of an insulating layer.

### <Conductive Material Contained in Auxiliary Wiring>

As a conductive material contained in the auxiliary wiring 151 of one embodiment of the present invention, i.e., a conductive material contained in the first wiring layer 151a or the second wiring layer 151b, a metal such as aluminum, copper, silver, gold, platinum, chromium, or molybdenum can be used. An alloy of the metal can also be used as the conductive material. The above conductive material is a metal and is a conductive material having a non-light-transmitting property. An electrode using a conductive material having anon-light-transmitting property is referred to as a reflective electrode in some cases. The first wiring layer 151a or the second wiring layer 151b can be formed as a single layer or stacked layers with the use of the conductive material. For example, the first wiring layer 151a may be stacked layers and the second wiring layer 151b may be a single layer. Alternatively, the first wiring layer 151a may be a single layer and the second wiring layer 151b may be stacked layers. In the case where the first wiring layer 151a or the second wiring layer 151b employs a stacked-layer structure, at least one or more layers preferably include the above-described conductive material having a non-light-transmitting property.

As the conductive material contained in the auxiliary wiring of one embodiment of the present invention, i.e., the conductive material contained in the first wiring layer 151a or the second wiring layer 151b, a light-transmitting conductive material may be used. Specifically. ITO, an oxide containing indium, silicon, and tin (also referred to as In—Si—Sn oxide or ITSO), an oxide containing indium and zinc (also referred to as indium zinc oxide or In—Zn oxide), an oxide containing indium, tungsten, and zinc (also referred to as In—W—Zn oxide), or the like can be used. An electrode using a conductive material having a light-transmitting property is referred to as a transparent electrode in some cases. The first wiring layer 151a or the second wiring layer 151b can be formed as a single layer or stacked layers with the use of the conductive material. For example, the first wiring layer 151a may be stacked layers and the second wiring layer 151b may be a single layer. Alternatively, the first wiring layer 151a may be a single layer and the second wiring layer 151b may be stacked layers. In the case where the first wiring layer 151a or the second wiring layer 151b employs a stacked-layer structure, at least one or more layers preferably include the above-described conductive material having a light-transmitting property.

The resistivity of the conductive material used for the auxiliary wiring of one embodiment of the present invention, i.e., the resistivity of the conductive material used for the first wiring layer 151a or the second wiring layer 151b, is preferably lower than the resistivity of a conductive material used for the extraction electrode. Further preferably, the conductive material used for the wiring layer with a larger area, based on a comparison of the areas of the first wiring layer and the second wiring layer in a top view, has lower resistivity than the conductive material used for the extraction electrode. Note that in the case where a voltage drop caused by the extraction electrode can be inhibited adequately, the resistivity relationship is not necessarily satisfied.

### <Contact Hole>

A contact hole refers to an opening formed in an insulating layer and enables a wiring layer positioned below the insulating layer (referred to as a lower wiring layer) to be electrically connected to a wiring layer positioned above the insulating layer (referred to as an upper wiring layer). For the electrical connection, in a cross-sectional view, the lower wiring layer includes a region exposed in the opening, and the upper wiring layer includes a region positioned in the opening in a cross-sectional view.

In the display device of one embodiment of the present invention, an insulating layer provided with a contact hole may be an insulating layer having a stacked-layer structure (sometimes referred to as a stacked-layer insulating layer). For example, in the case where a contact hole is formed in a stacked-layer insulating layer in which a first insulating layer and a second insulating layer are stacked, a first contact hole is formed in the first insulating layer and a second contact hole is formed in the second insulating layer. In that case, the first contact hole has a region overlapping with at least the second contact hole so that the lower wiring layer can be electrically connected to the upper wiring layer. In the case where the second insulating layer is positioned over the first insulating layer, for example, the width of the second contact hole is preferably larger than the width of the first contact hole in a cross-sectional view; however, the widths of the contact holes in the insulating layers are not particularly limited as long as the lower wiring layer can be electrically connected to the upper wiring layer.

<Light-Emitting Device>

As illustrated in FIG. 1A, the pixel portion 103 includes a red-light-emitting device 11R, a green-light-emitting device 11G, and a blue-light-emitting device 11B in addition to the auxiliary wiring 151. The red-light-emitting device 11R includes a lower electrode 111R, an organic compound layer 112R, and an upper electrode 113. The green-light-emitting device 11G includes a lower electrode 111G, an organic compound layer 112G, and the upper electrode 113. The blue-light-emitting device 11B includes a lower electrode 111B, an organic compound layer 112B, t and the upper electrode 113. Each of the lower electrodes 111R, 111G, and 111B preferably has an end portion with a tapered shape. When the end portion has a tapered shape, a film formed over the lower electrode as a formation surface is less likely to be divided.

The organic compound layer 112R has a structure in which a first organic compound layer 112R1 and a second organic compound layer 112R2 are stacked with a charge-generation layer 115 therebetween. The organic compound layer 112R employs what is called a tandem structure. Note that in FIG. 1A, the charge-generation layer 115 is indicated by a dotted line. Although the function or the material of the charge-generation layer 115 is described later, the charge-generation layer may be referred to as a layer containing lithium in the case where one of the materials included in the charge-generation layer is lithium. The first organic compound layer 112R1 includes at least one light-emitting layer and the light-emitting layer is referred to as a first light-emitting layer in some cases. The second organic compound layer 112R2 includes at least one light-emitting layer and the light-emitting layer is referred to as a second light-emitting layer in some cases. In the tandem structure, the number of stacked layers of the first organic compound layers 112R1 included in the light-emitting unit positioned under the charge-generation layer 115 may be different from the number of stacked layers of the second organic compound layers 112R2 included in the light-emitting unit positioned over the charge-generation layer 115.

The color of light emitted from the light-emitting material included in the first light-emitting layer is the same as the color of light emitted from the light-emitting material included in the second light-emitting layer. Since the light-emitting device 11R emits red light, red light is emitted from both the light-emitting material included in the first light-emitting layer and the light-emitting material included in the second light-emitting layer. As the light-emitting materials emitting red light in the first light-emitting layer and the second light-emitting layer, the same material can be used and the same material is not necessarily used as long as the light-emitting materials can emit red light.

The above is the description of the organic compound layer 112R, and the same applies to the organic compound layer 112G and the organic compound layer 112B.

The organic compound layer 112G has a structure in which a first organic compound layer 112G1 and a second organic compound layer 112G2 are stacked with the charge-generation layer 115 therebetween. The first organic compound layer 112G1 includes at least one light-emitting layer and the light-emitting layer is referred to as a first light-emitting layer in some cases. The second organic compound layer 112G2 includes at least one light-emitting layer and the light-emitting layer is referred to as a second light-emitting layer in some cases. In the tandem structure, the number of stacked layers of the first organic compound layers 112G1 included in the light-emitting unit positioned under the charge-generation layer 115 may be different from the number of stacked layers of the second organic compound layers 112G2 included in the light-emitting unit positioned over the charge-generation layer 115.

The color of light emitted from the light-emitting material included in the first light-emitting layer is the same as the color of light emitted from the light-emitting material included in the second light-emitting layer. Since the light-emitting device 11G emits green light, green light is emitted from both the light-emitting material included in the first light-emitting layer and the light-emitting material included in the second light-emitting layer. As the light-emitting materials emitting green light in the first light-emitting layer and the second light-emitting layer, the same material can be used and the same material is not necessarily used as long as the light-emitting materials can emit green light.

The organic compound layer 112B has a structure in which a first organic compound layer 112B1 and a second organic compound layer 112B2 are stacked with the charge-generation layer 115 therebetween. The first organic compound layer 112B1 includes at least one light-emitting layer and the light-emitting layer is referred to as a first light-emitting layer in some cases. The second organic compound layer 112B2 includes at least one light-emitting layer and the light-emitting layer is referred to as a second light-emitting layer in some cases. In the tandem structure, the number of stacked layers of the first organic compound layers 112B1 included in the light-emitting unit positioned under the charge-generation layer 115 may be different from the number of stacked layers of the second organic compound layers 112B2 included in the light-emitting unit positioned over the charge-generation layer 115.

The color of light emitted from the light-emitting material included in the first light-emitting layer is the same as the color of light emitted from the light-emitting material included in the second light-emitting layer. Since the light-emitting device 11B emits blue light, blue light is emitted from both the light-emitting material included in the first light-emitting layer and the light-emitting material included in the second light-emitting layer. As the light-emitting materials emitting blue light in the first light-emitting layer and the second light-emitting layer, the same material can be used and the same material is not necessarily used as long as the light-emitting materials can emit blue light.

As the light-emitting device, an OLED (Organic Light-Emitting Diode) or a QLED (Quantum-dot Light-Emitting Diode) is preferably used, for example. Examples of a light-emitting material (also referred to as a light-emitting substance) contained in the light-emitting device include a substance that emits fluorescent light (a fluorescent material), a substance that emits phosphorescent light (a phosphorescent material), a substance that exhibits thermally activated delayed fluorescence (a thermally activated delayed fluorescent (TADF) material), and an inorganic compound (a quantum dot material or the like). In addition, an LED (Light Emitting Diode) such as a micro LED can also be used as the light-emitting device.

The emission color of the light-emitting device can be cyan, magenta, yellow, or white, for example, in addition to the above. When the emission color of the light-emitting device is infrared, the light-emitting device can be used as a light source of a sensor. The sensor is described in Embodiment 6 and the like.

A structure and a material of the light-emitting device is described in Embodiment 4, for example

As illustrated in FIG. 1A, the upper electrode 113 is shared by the light-emitting devices 11R, 11G, and JIB. Such a laver may be referred to as a common layer, and in the case of functioning as an electrode, it may be referred to as a common electrode. That is, the upper electrode 113 can be rephrased as the common electrode.

Needless to say, the upper electrode 113 may be divided between the light-emitting devices.

Light emitted from the light-emitting devices 11R, 11G, and 11B can be extracted through the upper electrode 113. That is, the upper electrode 113 is the extraction electrode. In FIG. 1A, arrows indicate the direction in which light is emitted. The display device in which the upper electrode 113 is the extraction electrode is referred to as a top-emission display device in some cases.

As described above, a conductive material with high resistivity such as ITO is used for the extraction electrode. Thus, the auxiliary wiring 151 is electrically connected to the extraction electrode, i.e., the upper electrode as the main electrode. This state is shown by solid lines in FIG. 1A as in a circuit diagram. Voltage drops of the upper electrodes 113 to which the auxiliary wiring 151 is electrically connected are adequately inhibited.

Note that the effect of the auxiliary wiring 151 can be understood by those skilled in the art of this specification and the like also when the upper electrodes, the common electrode, and the extraction electrode can be replaced with each other

The SBS structure in which the light-emitting layers are separately formed is preferably employed for the light-emitting devices 11R, 11G, and 11B. In the SBS structure, a lithography method or the like is preferably used to divide the organic compound layer including the light-emitting layer. As the lithography method, a photolithography method can be employed.

Photolithography is a method in which light exposure is performed on a photosensitive substance to draw a desired pattern thereon and then a pattern is formed from an exposed portion and a non-exposed portion. As the light exposure, reduction exposure with use of a stepper can be employed.

Division performed by a photolithography method or the like may be referred to as patterning or simply as processing. The end surfaces of the organic compound layers 112R, 112G, and 112B processed by a photolithography method rise perpendicularly or substantially perpendicularly from a formation surface such as a substrate in many cases. A taper angle of the end surface of the organic compound layer 112 can be greater than or equal to 45° and less than 90°. The taper angle can be found from a side surface in a cross-sectional view, and the taper angle of the side surface is greater than or equal to 45° and less than 90°. Since the organic compound layers 112R, 112G, and 112B are stacked layers, the taper angle of the side surface can be regarded as an angle formed by a formation surface such as a substrate and a line extending from the upper end of the uppermost layer to the lower end of the lowermost layer in the stacked layers.

The distance between the organic compound layers 112R and 112G or the organic compound layers 112G and 112B processed by a photolithography method can be less than or equal to 5 μm, less than or equal to 1 μm, less than or equal to 500 nm, less than or equal to 200 nm, less than or equal to 100 nm, or less than or equal to 50 nm. Since the organic compound layers 112R, 112G, and 112B are stacks of layers, the distance can be regarded as the distance between the lower edges of the lowest layers in the stacks.

Meanwhile, by a method in which the organic compound layer is patterned with the use of a fine metal mask in vacuum evaporation, it is difficult to shorten the distance between the organic compound layers. Typically, making the distance between the adjacent organic compound layers less than or equal to 10 μm is difficult with the use of a fine metal mask.

Note that a method for fabricating a light-emitting device that involves a photolithography method or the like will be described in Embodiment 8 and the like.

### <Microcavity Structure>

The light-emitting device of one embodiment of the present invention may employ a microcavity structure. When a microcavity structure is employed, the color purity of extracted light that has been emitted from the light-emitting device can be increased.

FIG. 1B illustrates an example in which a microcavity structure is applied to the light-emitting devices and the like illustrated in FIG. 1A. In the case of the light-emitting devices in FIG. 1B employing the microcavity structure, the distances between the electrodes differ between the light-emitting devices. In other words, the above-described different distances between the electrodes of the light-emitting devices in FIG. 1B are different from those of the light-emitting devices in FIG. 1A. Meanwhile, the other structures of FIG. 1B are similar to those of FIG. 1A and the description thereof is omitted.

The microcavity structure is a structure that generates resonance at a specific wavelength λ between the extraction electrode and the counter electrode.

For resonance at the specific wavelength λ, t extraction electrode preferably has a structure in which a transparent electrode and a reflective electrode are stacked. That is, the extraction electrode contains a conductive material having a light-transmitting property and a conductive material having a light-reflecting property. Such an electrode is sometimes referred to as a transflective electrode. As the extraction electrode, a reflective electrode having a thickness greater than or equal to 1 nm and less than or equal to 10 nm so as to transmit visible light may be used.

For resonance at the specific wavelength λ, a reflective electrode is preferably used as the counter electrode. The counter electrode may have a structure in which a reflective electrode and a transparent electrode are stacked. In the structure in which the reflective electrode and the transparent electrode are stacked, light passing through the transparent electrode is reflected by the reflective electrode, whereby the resonance at the specific wavelength a is achieved.

The transparent electrode preferably has a light transmittance higher than or equal to 40%. The transparent electrode used in the light-emitting device preferably has a visible light (light with wavelengths greater than or equal to 400 nm and less than 750 nm) transmittance higher than or equal to 40%. As already described above, ITO, an oxide containing indium, silicon, and tin (also referred to as In—Si—Sn oxide or ITSO), an oxide containing indium and zinc (also referred to as indium zinc oxide or In—Zn oxide), an oxide containing indium, tungsten, and zinc (also referred to as In—W—Zn oxide), or the like can be used as the transparent electrode.

The transflective electrode preferably has a light reflectance higher than or equal to 10% and lower than or equal to 95%, further preferably higher than or equal to 30% and lower than or equal to 80%. For example, the transflective electrode used in the light-emitting device preferably has a visible light (light with wavelengths greater than or equal to 400 nm and less than 750 nm) reflectance higher than or equal to 10% and lower than or equal to 95%, further preferably higher than or equal to 30% and lower than or equal to 80%.

The reflective electrode has a light reflectance higher than or equal to 40% and lower than or equal to 100%, preferably higher than or equal to 70% and lower than or equal to 100%. For example, the reflective electrode used in the light-emitting device preferably has a visible light (light with wavelengths greater than or equal to 400 nm and less than 750 nm) reflectance higher than or equal to 40% and lower than or equal to 100%, further preferably higher than or equal to 70%, preferably 100%. As already described above, for the reflective electrode, a metal such as aluminum, copper, silver, gold, platinum, chromium, or molybdenum, or an alloy of the above metals for the conductive material, for example, can be used.

The specific wavelength λ corresponds to the wavelength λ of light extracted from the light-emitting device. Since the light-emitting devices differ in specific wavelength λ, the light-emitting devices differ in the optical distance between the electrodes in the display device having the microcavity structure. The difference in optical distance amounts to the difference among the distance from the top surface of the lower electrode 111R to the bottom surface of the upper electrode 113, the distance from the top surface of the lower electrode 111G to the bottom surface of the upper electrode 113, and the distance from the top surface of the lower electrode 111B to the bottom surface of the upper electrode 113, which is illustrated in FIG. 1B. In the typical example in FIG. 1B, the distance from the top surface of the lower electrode 111B to the bottom surface of the upper electrode 113 is shorter than the distance from the top surface of the lower electrode 111G to the bottom surface of the upper electrode 113, and the distance from the top surface of the lower electrode 111G to the bottom surface of the upper electrode 113 is shorter than the distance from the top surface of the lower electrode 111R to the bottom surface of the upper electrode 113. In the display device with such a microcavity structure, the distances between the electrodes differ between the light-emitting devices. Note that the distance between the electrodes corresponds to the distance between surfaces that reflect light. In a transflective electrode, a surface that reflects light is a surface of a reflective electrode, for example. Note that the light-emitting devices having different distances between the electrodes can also be referred to as the light-emitting devices having organic compound layers with different thicknesses.

In order to obtain the light-emitting devices having different distances between the electrodes, the organic compound layers included in the respective light-emitting devices may differ in the number of stacked layers. In the case where the distances between the electrodes in FIG. 1B are obtained, the number of stacked layers included in the organic compound layer 112G may be smaller than the number of stacked layers included in the organic compound layer 112R and the number of stacked layers included in the organic compound layer 112B may be smaller than the number of stacked layers included in the organic compound layer 112G.

In order to resonate the specific wavelength λ, the optical path length is, for example, nλ/2 (where n is an integer greater than or equal to 1 and λ is a wavelength of light to be resonated). In the above formula, the value of n may vary between the light-emitting devices. For example, the optical path length between electrodes in a subpixel that emits red light or a subpixel that emits green light may be determined with n being 1, and the optical path length between electrodes in a subpixel that emits blue light may be determined with n being 2. In this case, in each of the light-emitting devices illustrated in FIG. 1B, the distance from the top surface of the lower electrode 111G to the bottom surface of the upper electrode 113 is shorter than the distance from the top surface of the lower electrode 111R to the bottom surface of the upper electrode 113, and the distance from the top surface of the lower electrode 111R to the bottom surface of the upper electrode 113 is shorter than the distance from the top surface of the lower electrode 111B to the bottom surface of the upper electrode 113.

In a microcavity structure, light with a wavelength that is not resonated is attenuated. Therefore, light with a small half width can be extracted from the light-emitting device. Light with a small half width has high directivity and is thus preferable, and light with high color purity can be extracted from the light-emitting device.

In the case where the light-emitting device can employ a combination of a tandem structure and a microcavity structure, the optical path length between the pair of electrodes, i.e., the distance between the pair of electrodes, increases in some cases. This might increase voltage applied between the pair of electrodes; thus, the optical path length between the pair of electrodes is preferably as short as possible. For example, in the case of a light-emitting device having a tandem structure, the thickness of one light-emitting unit is reduced as much as possible and the optical path length between a pair of electrodes is set to nλ/2. The functional layer can be omitted as described above so that the thickness of the light-emitting unit is reduced.

### <Color Filter>

A color filter may be used for the light-emitting device of one embodiment of the present invention. When a color filter is employed, the color purity of extracted light that has been emitted from the light-emitting device can be increased.

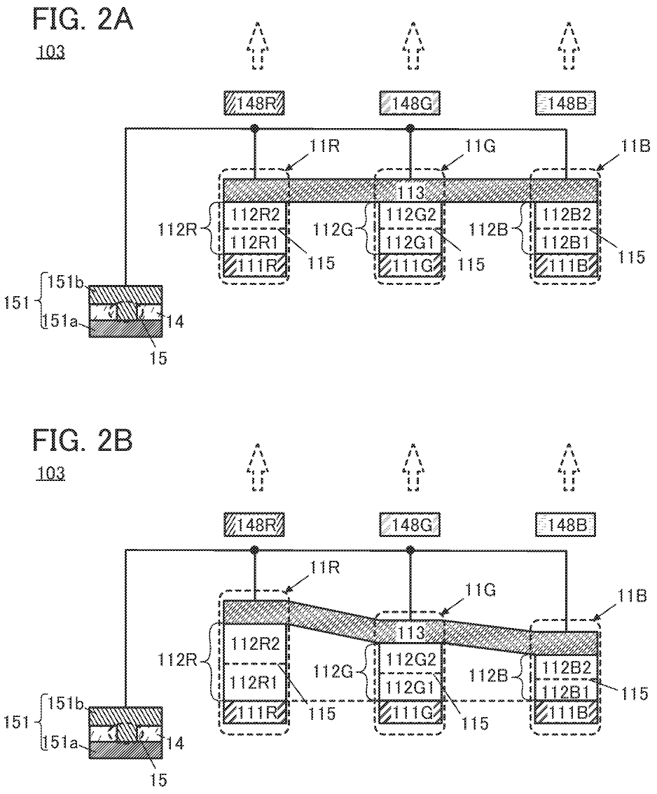

FIG. 2A illustrates an example in which color filters 148R, 148G, and 148B are used for the light-emitting devices and the like illustrated in FIG. 1A. Since the other structures are similar to those in FIG. 1A, the descriptions thereof are omitted. FIG. 2B illustrates an example in which the color filters 148R, 148G, and 148B are used as the light-emitting devices and the like illustrated in FIG. 1B. Since the other structures are similar to those in FIG. 1B, the descriptions thereof are omitted.

As the color filters, the red color filter 148R that transmits light in a red wavelength range, the green color filter 148G that transmits light in a green wavelength range, and the blue color filter 148B that transmits light in a blue wavelength range are used. The light-emitting devices can emit red, green, and blue light in the direction of arrows through the color filters 148.

A color filter can be called a coloring layer that transmits light in a specific wavelength range. Transmitting light in a specific wavelength range refers to a state where light transmitted through a color filter has a peak at the wavelength corresponding to at least the specific color.

The color filters can be formed in desired positions using any of various materials such as a chromatic light-transmitting resin by a printing method, an ink-jet method, or a photolithography method and an etching method, for example. As the chromatic light-transmitting resin, a photosensitive or non-photosensitive organic resin can be used, and a photosensitive organic resin is preferably used because the above etching process can be omitted.

Chromatic colors are colors except achromatic colors such as black, gray, and white; specifically, red, green, blue, and the like can be used. The colors of the color filters may be cyan, magenta, yellow, and the like.

The thickness of each of the color filters can be greater than or equal to 500 nm and less than or equal to 5 μm.

The use of the color filters can eliminate the need for an optical element such as a circularly polarizing plate or a polarizing plate. Eliminating the need for the optical element is preferable, in which case a display device can be lightweight or thin.

### <Overall View 1 of Auxiliary Wiring and the Like>

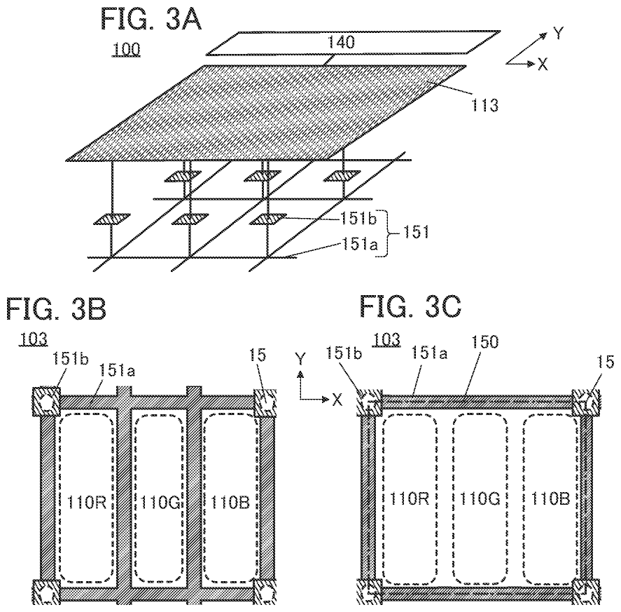

A display device 100 illustrated in FIG. 3A includes the upper electrode 113, the auxiliary wiring 151 which is positioned below the upper electrode 113 and connected to the upper electrode, and a connection portion 140 having a function of supplying a signal to the upper electrode 113. The connection portion 140 is described in Embodiment 3 and the like. The auxiliary wiring 151 is electrically connected to the upper electrode 113. Specifically, the auxiliary wiring 151 includes the first wiring layer 151a having a lattice shape in a top view and the second wiring layer 151b positioned above the first wiring layer 151a. A contact hole is provided in a region overlapping with the second wiring layer 151b to enable electrical connection between the upper electrode 113 and the auxiliary wiring 151. The contact hole is omitted in FIG. 3A. The contact hole is preferably positioned at least close to the connection portion 140 so that a plurality of contact holes are provided for the upper electrode 113. Although the second wiring layer 151b has an island shape, the present invention is not limited to this; the second wiring layer 151b may have a band shape, a lattice shape, or the like. Note that the island shape refers to a shape in which the length in the X direction and the length in the Y direction are equal or substantially equal in a top view. The band shape refers to a shape in which one of the lengths in the X direction and the Y direction is different from the lengths in the X direction and the Y direction, i.e., longer in atop view. The lattice shape refers to a shape including at least a region extending in the X direction and the Y direction.

A signal from the connection portion 140 is supplied to the auxiliary wiring 151 through the contact hole (not illustrated in FIG. 3A) while being supplied to the upper electrode 113, whereby a voltage drop can be inhibited.

The upper electrode 113 is supplied with a power supply potential (e.g., a cathode potential) or a signal through the connection portion 140. Since the light-emitting device is an element driven with current, specifically, a current is supplied from the light-emitting device to the connection portion 140 when the upper electrode 113 is a cathode and a current is supplied from the connection portion 140 to the light-emitting device when the upper electrode 113 is an anode. The current is also supplied to the auxiliary wiring 151 through the contact hole (not illustrated in FIG. 3A). With this structure, a current can be supplied through the auxiliary wiring 151 even when a voltage drop can be caused by the upper electrode 113; thus, a voltage drop can be effectively inhibited.

As illustrated in FIG. 3A, the auxiliary wiring 151 has a configuration in which a power supply potential (e.g., a cathode potential) or a signal is not directly supplied. In other words, the auxiliary wiring 151 is not connected to any wiring or electrode other than the upper electrode 113.

### <Top Surface Shape 1 of Auxiliary Wiring>

FIG. 3B and FIG. 3C each illustrate a top view of the pixel portion 103, the first wiring layer 151a having a lattice shape as in FIG. 3A, and the contact hole 15. Since the contact hole 15 enables electrical connection between the first wiring layer 151a and the second wiring layer 151b, the second wiring layer 151b is provided in a position overlapping with the contact hole 15.

In FIG. 3B and FIG. 3C, the X direction and the Y direction intersecting with the X direction are indicated, and a layout or the like of the first wiring layer 151a is described using the directions in some cases.

### <Lattice-Shaped Auxiliary Wiring Surrounding Subpixel>

The first wiring layer 151a illustrated in FIG. 3B has a lattice shape such that the subpixels 110R 110G, and 110B are surrounded. That is, the first wiring layer 151a includes at least a region positioned between the subpixels. Although the first wiring layer 151a does not include a region overlapping with the subpixel in FIG. 3B, the first wiring layer 151a may include a region overlapping with the subpixels 110R, 110G, and 110B.

Note that the subpixels 110R, 110G, and 110B illustrated in diagrams of this embodiment each correspond to a top surface shape of a light-emitting region. For example, the subpixels each correspond to a top surface shape of the light-emitting region seen past the upper electrode 113 in the light-emitting devices illustrated in FIG. 1A and FIG. 1B. The subpixels each correspond to a top surface shape of the light-emitting region seen past the color filters 148R, 148G, and 148B in the light-emitting devices illustrated in FIG. 2A and FIG. 2B.

A layout of the first wiring layer 151a illustrated in FIG. 3B is described. The first wiring layer 151a has a lattice shape such that the subpixels 110R, 110G, and 110B are surrounded. The lattice-shaped first wiring layer 151a includes a plurality of vertical lines and a plurality of horizontal lines. The vertical lines correspond to the lines along the Y direction, and the first wiring layer 151a includes, as the line, a region overlapping with the gap between the subpixel 110R and the subpixel 110G, and, as the line, a region overlapping with the gap between the subpixel 110G and the subpixel 110B. In this manner, the first wiring layer 151a can be placed between the subpixels 110R, 110G, and 110B that are regularly laid out. Note that the gap between the subpixels refers to the gap between an end of the lower electrode 111R and an end of the lower electrode 111G and a region between an end of the lower electrode 111G and an end of the lower electrode 111B, for example, illustrated in FIG. 1A to FIG. 2B and the like.

Although the first wiring layer 151a illustrated in FIG. 3B does not include a region overlapping with the subpixel, the first wiring layer 151a may include a region overlapping with the subpixels 110R, 110G, and 111B.

There is no limitation on the density of the vertical lines or the density of the horizontal lines as long as the first wiring layer 151a illustrated in FIG. 3B includes the plurality of vertical lines and the plurality of horizontal lines. This indicates that the first wiring layer 151a does not necessarily have the regions provided in all the gaps between the subpixels and can be arranged at any interval.

### <Lattice-Shaped Auxiliary Wiring Surrounding Pixel>

The first wiring layer 151a illustrated in FIG. 3C is different from that in FIG. 3B in the density of the vertical lines. Specifically, the first wiring layer 151a illustrated in FIG. 3C has a lattice shape such that the pixel 150 is surrounded. The first wiring layer 151a includes a region overlapping with the gap between the pixels 150 as the line along the Y direction. In this manner, the first wiring layer 151a can be placed between the pixels 150 that are regularly laid out. Note that the gap between the pixels 150 refers to the gap between the end of the lower electrode 111R and the end of the lower electrode 111B of the pixels adjacent to each other in the X direction, for example, illustrated in FIG. 1A to FIG. 2B and the like.

Although the first wiring layer 151a illustrated in FIG. 3C does not include a region overlapping with the pixel 150, the first wiring layer 151a may include a region overlapping with the pixel 150.

FIG. 3B and FIG. 3C each illustrate the contact hole 15 that is positioned in a region overlapping with the second wiring layer 151b. The shape of the second wiring layer 151b is referred to as an island shape (including a shape in which a long side is equal or substantially equal to a short side). Thus, the first wiring layer 151a is electrically connected to the second wiring layer 151b through the contact hole 15.

The shape of the first wiring layer 151a is not limited to a lattice shape and may be a band shape (also referred to as a stripe shape, including a shape in which a long side is twice or more than twice as long as a short side). For example, the band-shaped first wiring layer 151a along the vertical line can be combined with the band-shaped second wiring layer 151b along the horizontal line to form an auxiliary wiring having a lattice shape. Also in such a case, the first wiring layer 151a can be electrically connected to the second wiring layer 151b through the contact hole 15.

### <Contact Hole in Auxiliary Wiring>

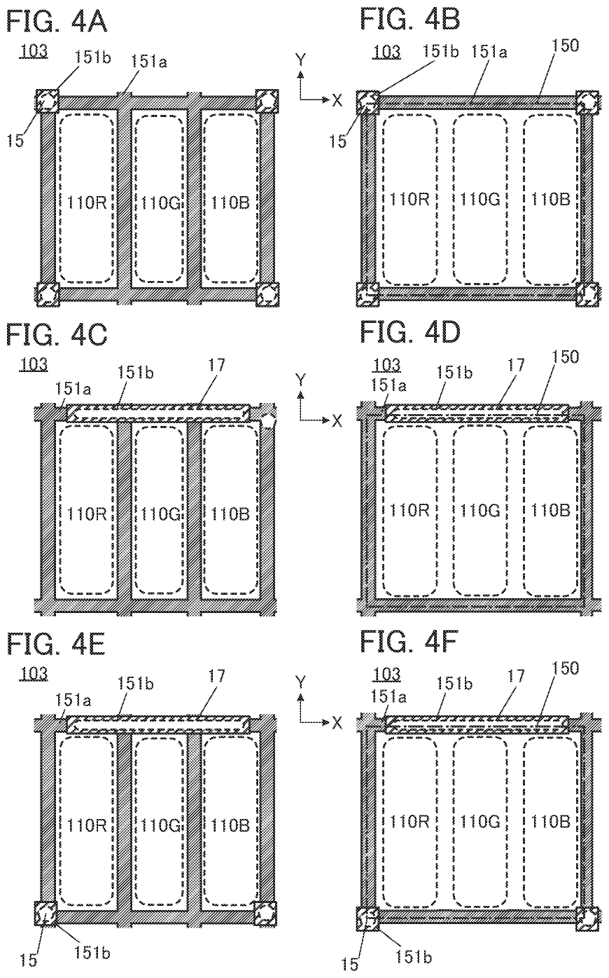

As described above, the first wiring layer 151a and the second wiring layer 151b are electrically connected to each other through the contact hole. The layout of the above-described contact hole or the above-described second wiring layer 151b, for example, are described with reference to FIG. 4A to FIG. 4F. FIG. 4A to FIG. 4F each illustrate the lattice-shaped first wiring layer 151a illustrated in FIG. 3B or FIG. 3C.

FIG. 4A illustrates the lattice-shaped first wiring layer 151a similar to that in FIG. 3B. That is, in FIG. 4A, the first wiring layer 151a has a lattice shape surrounding the subpixels 110R, 110G, and 110B. The auxiliary wiring further includes the second wiring layer 151b in the position overlapping with the contact hole 15. The second wiring layer 151b has an island shape as in FIG. 3A. The contact holes 15 and the second wiring layers 151b are provided at positions overlapping with the first wiring layer 151a which is close to an upper portion and a lower portion of the subpixel 110R and the first wiring layer 151a which is close to an upper portion and a lower portion of the subpixel 110B. The positions of the contact hole 15 and the second wiring layer 151b illustrated in FIG. 4A are equal to those of the contact hole 15 and the second wiring layer 151b illustrated in FIG. 4B which are described later. Thus, the contact hole 15 and the second wiring layer 151b are not necessarily provided for each subpixel.

FIG. 4B illustrates the lattice-shaped first wiring layer 151a similar to that in FIG. 3C. That is, in FIG. 4B, the first wiring layer 151a has a lattice shape surrounding the pixel 150. The auxiliary wiring further includes the second wiring layer 151b in the position overlapping with the contact hole 15. The second wiring layer 151b has an island shape as in FIG. 3A. The contact holes 15 and the second wiring layers 151b are provided at positions overlapping with the first wiring layer 151a which is close to an upper portion and a lower portion of the pixel 150.

Although the shape of the second wiring layer 151b is an island shape in FIG. 4A and FIG. 4B, one embodiment of the present invention is not limited to an island shape and may be a band shape, a lattice shape, or the like.

FIG. 4C and FIG. 4D each illustrate the band-shaped second wiring layer 151b; the first wiring layer 151a in FIG. 4C has a lattice shape surrounding the subpixels and the first wiring layer 151a in FIG. 4D has a lattice shape surrounding the pixels. The shape of the contact hole may be determined in accordance with the band-shaped second wiring layer 151b. In FIG. 4C and FIG. 4D, a contact hole 17 extending in the X direction is formed in accordance with the second wiring layer 151b. The first wiring layer 151a and the second wiring layer 151b are electrically connected to each other through the contact hole 17.

FIG. 4E and FIG. 4F illustrate, respectively, the band-shaped second wiring layer 151b and the island-shaped second wiring layer 151b; the first wiring layer 151a in FIG. 4E has a lattice shape surrounding the subpixels; and the first wiring layer 151a in FIG. 4F has a lattice shape surrounding the pixels. The shape of the contact hole may be determined in accordance with the band-shaped second wiring layer 151b. In FIG. 4E and FIG. 4F, the contact hole 15 and the contact hole 17 are formed in accordance with the second wiring layer 151b. The first wiring layer 151a and the second wiring layer 151b are electrically connected to each other through the contact hole 15 and the contact hole 17.

In the case where the first wiring layer 151a has a lattice shape as described above, the second wiring layer 151b can have various shapes. The above various shapes include shapes combining a plurality of shapes as illustrated in FIG. 4E and FIG. 4F. The contact hole 15 or the contact hole 17 preferably has a shape or an area along the shape of the second wiring layer 151b. Thus, the contact holes can also have various shapes like the second wiring layer. The above various shapes include shapes combining a plurality of shapes as illustrated in FIG. 4E and FIG. 4F.

### <Auxiliary Wiring and Other Wirings>

In the case where the lattice-shaped first wiring layer 151a a is formed, no wirings functioning as a scan line, a signal line, a power supply line, and the like are preferably provided in the same layer as the first wiring layer 151a. This is because the wirings having the functions need to extend in the X direction or the Y direction and thus cause a short circuit with the lattice-shaped first wiring layer 151a.

In the case where a wiring that has a function of a scan line, a signal line, a power supply line, or the like is provided in the same layer as the above-described lattice-shaped first wiring layer 151a, the wiring can be laid out to avoid a short circuit with the first wiring layer 151a by adjustment of the length of the scan line, signal line, power supply line, or the like in the X direction or the length thereof in the Y-axis direction. For the adjustment of the length in the X direction or the length in the Y-axis direction, abridge wiring is preferably prepared. The bridge wiring is to connect wirings having adjusted lengths to each other and is a conductive layer placed in a layer different from the wirings having adjusted lengths, for example. A bridge wiring is sometimes referred to as a bridge electrode according to its shape; in this specification and the like, description is made using the term “bridge wiring”.

### <Overall View 2 of Auxiliary Wiring and the Like>

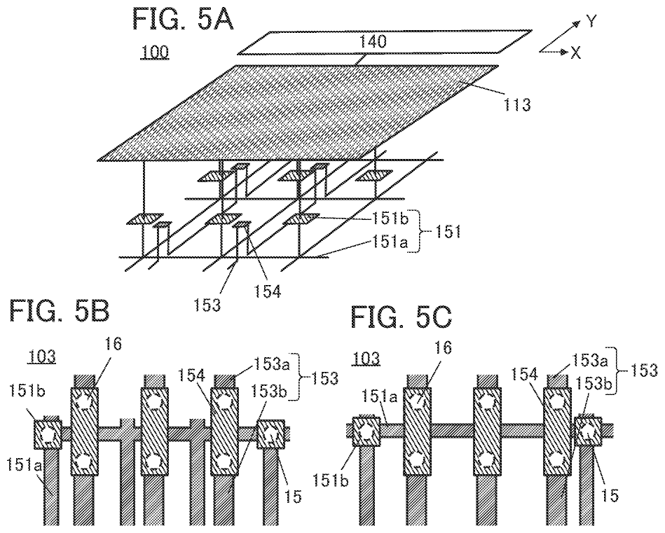

Like FIG. 3A, FIG. 5A illustrates the display device 100 including the upper electrode 113, the auxiliary wiring 151 that is positioned under the upper electrode 113 and connected to the upper electrode, and the connection portion 140 having a function of supplying a signal to the upper electrode 113. FIG. 5A further illustrates a signal line 153 along the auxiliary wiring 151 and a bridge wiring 154, unlike FIG. 3A. In FIG. 5A, the bridge wiring 154 is positioned in the same layer as the second wiring layer 151b.

FIG. 5B and FIG. 5C are top views of the pixel portion 103, each illustrating the lattice-shaped first wiring layer 151a and the island-shaped second wiring layer 151b similar to those in FIG. 3B and FIG. 3C, the bridge wiring 154, and the signal line 153. The signal line 153 has a structure in which the first conductive layer 153a and the second conductive layer 153b are electrically connected to each other through the bridge wiring 154. A contact hole 16 of the bridge wiring 154 and the first conductive layer 153a is also illustrated. A contact hole of the bridge wiring 154 and the second conductive layer 153b is illustrated like the contact hole 16.

The bridge wiring and the like enable the lattice-shaped first wiring layer 151a and the signal line 153 to be formed in the same layer.

Note that the bridge wiring 154 and the like can also enable a scan line or a power supply line, other than the signal line 153, to be formed in the same layer as the first wiring layer 151a.

### <Overall View 3 of Auxiliary Wiring and the Like>

In the display device of one embodiment of the present invention, a power supply potential (e.g., a cathode potential) or a signal may be directly supplied to the auxiliary wiring 151. In the case where a power supply potential (e.g., a cathode potential) or a signal is directly supplied to the auxiliary wiring 151, the power supply potential or the signal is supplied from the auxiliary wiring 151 to the upper electrode 113 even without the connection portion 140 or the like. The structure without the connection portion 140 or the like reduces the size of the display device.

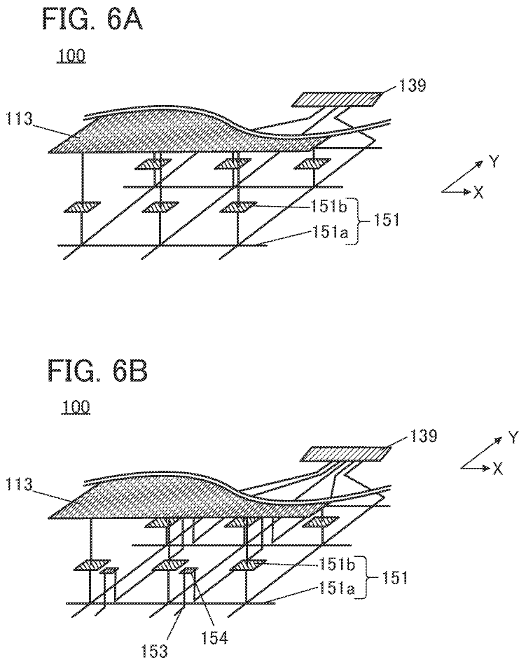

FIG. 6A illustrates the display device 100 in which a power supply potential (e.g., a cathode potential) or a signal can be directly supplied to the auxiliary wiring 151. In FIG. 6A, the auxiliary wiring 151 includes the lattice-shaped first wiring layer 151a and the island-shaped second wiring layer 151b, as in FIG. 3A. Unlike in FIG. 3A, in FIG. 6A, a terminal portion 139 supplied with a signal supplied from an FPC (Flexible Printed Circuit) or the like is included instead of the connection portion 140, and a power supply potential (e.g., a cathode potential) or a signal is supplied from the terminal portion to the auxiliary wiring 151. The power supply potential (e.g., cathode potential) or the signal supplied to the lattice-shaped first wiring layer 151a can be supplied to the upper electrode 113 through a plurality of contact holes. Since the first wiring layer 151a includes a conductive material with low resistivity, a voltage drop is inhibited. The display device illustrated in FIG. 6A can be reduced in size because the connection portion 140 can be omitted.

FIG. 6B illustrates the display device 100 in which a power supply potential (e.g., a cathode potential) or a signal can be directly supplied to the auxiliary wiring 151 and which includes the bridge wiring 154. In FIG. 6B, the auxiliary wiring 151 includes the lattice-shaped first wiring layer 151a, the island shaped second wiring layer 151b, the signal line 153, and the bridge wiring 154, as in FIG. 5A. Unlike in FIG. 5A, in FIG. 6B, a terminal portion 139 supplied with a signal supplied from an FPC or the like is included instead of the connection portion 140, and a power supply potential (e.g., a cathode potential) or a signal is supplied from the terminal portion to the auxiliary wiring 151. The power supply potential (e.g., cathode potential) or the signal supplied to the lattice-shaped first wiring layer 151a can be supplied to the upper electrode 113 through a plurality of contact holes. Since the first wiring layer 151a includes a conductive material with low resistivity, a voltage drop is inhibited. The display device illustrated in FIG. 6B can be reduced in size because the connection portion 140 can be omitted.

### <Cross-Sectional Shape 1 of Auxiliary Wiring>

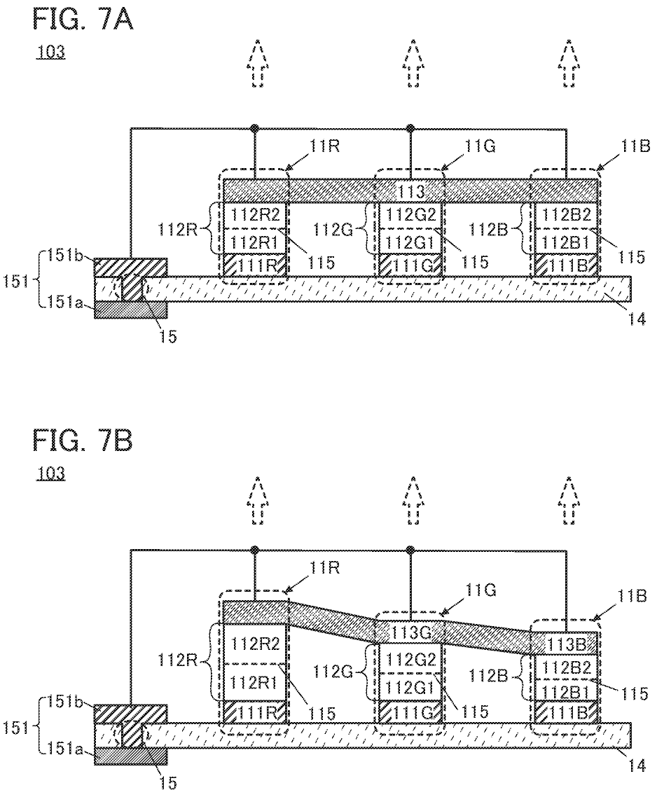

As illustrated in FIG. 7A, the second wiring layer 151b can be formed in the same layer as the lower electrodes 111R, 111G, and 111B. Specifically, the second wiring layer 151b and the lower electrodes 111R, 111G, and 111B can be formed over the insulating layer 14. Since the second wiring layer 151b does not occupy a larger area than the first wiring layer 151a as described above, the structure where the second wiring layer is formed in the same layer as the lower electrodes does not restrict the aperture ratio of the pixel. Note that the other structures in FIG. 7A are similar to those in FIG. 1A and thus are not described.

FIG. 7B illustrates an example in which a microcavity structure is applied to FIG. 7A. In FIG. 7B, the second wiring layer 151b and the lower electrodes 111R, 111G, and 111B can be formed over the insulating layer 14, as in FIG. 7A. Since the second wiring layer 151b does not occupy a larger area than the first wiring layer 151a as described above, the structure where the second wiring layer is formed in the same layer as the lower electrodes does not restrict the aperture ratio of the pixel. Note that the other structures in FIG. 7B are similar to those in FIG. 1B and thus are not described.

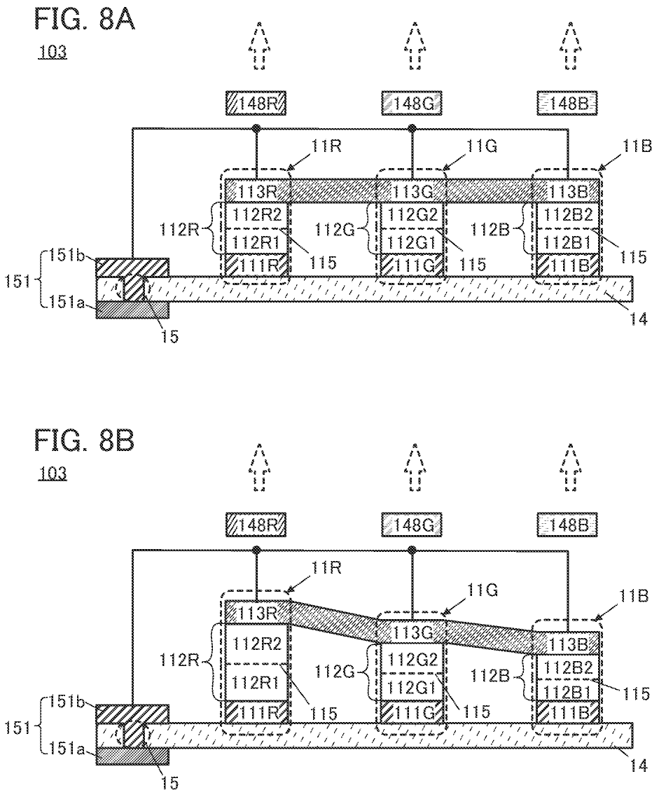

FIG. 8A illustrates an example in which color filters are employed for FIG. 7A. In FIG. 8A, the second wiring layer 151b and the lower electrodes 111R, 111G, and 111B can be formed over the insulating layer 14, as in FIG. 7A. Since the second wiring layer 151b does not occupy a larger area than the first wiring layer 151a as described above, the structure where the second wiring layer is formed in the same layer as the lower electrodes does not restrict the aperture ratio of the pixel. Note that the other structures in FIG. 8A are similar to those in FIG. 7A and thus are not described.

FIG. 8B illustrates an example in which color filters are employed for FIG. 7B. In FIG. 8B, the second wiring layer 151b and the lower electrodes 111R, 111G, and 111B can be formed over the insulating layer 14, as in FIG. 7A. Since the second wiring layer 151b does not occupy a larger area than the first wiring layer 151a as described above, the structure where the second wiring layer is formed in the same layer as the lower electrodes does not restrict the aperture ratio of the pixel. Note that the other structures in FIG. 8B are similar to those in FIG. 7B and thus are not described.

The structures of the top surface shapes illustrated in FIG. 3A to FIG. 6B as described above can be applied to the auxiliary wirings illustrated in FIG. 7A to FIG. 8B as appropriate.

### <Cross-Sectional Shape 2 of Auxiliary Wiring>

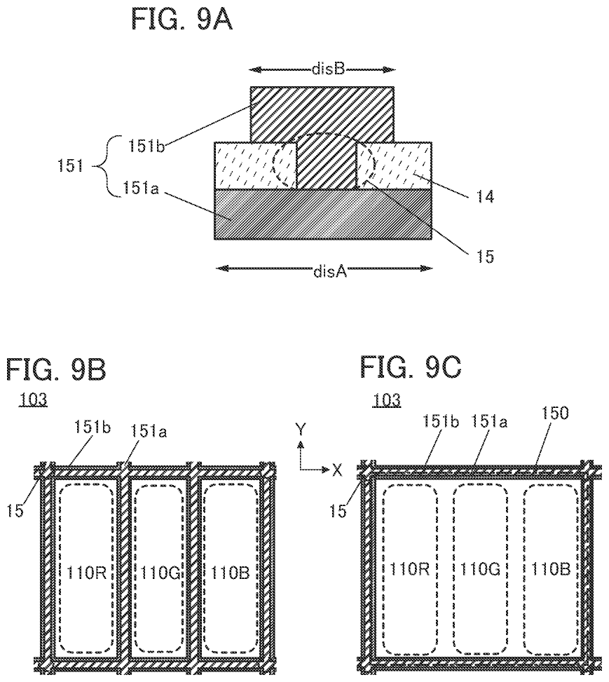

FIG. 9A illustrates another mode of the auxiliary wiring 151. The auxiliary wiring 151 in FIG. 9A has a structure in which the width of the second wiring layer 151b (a width denoted by disB) is smaller than the width of the first wiring layer 151a (a width denoted by disA) in a cross-sectional view along the X direction and the Y direction.

The structures of the top surface shapes illustrated in FIG. 3A to FIG. 6B as described above can be applied to the auxiliary wiring illustrated in FIG. 9A as appropriate.

### <Top Surface Shape 2 of Auxiliary Wiring>

Top surface shapes other than those illustrated in FIG. 3A to FIG. 6B are described. FIG. 9B and FIG. 9C each illustrate a top view of the pixel portion 103, where the first wiring layer 151a and the second wiring layer 151b each have a lattice shape. Specifically, the first wiring layer 151a in FIG. 9B has a lattice shape surrounding the subpixels 110R, 110G, and 110B, and the second wiring layer 151b also has a lattice shape surrounding the subpixels 110R, 110G, and 1101B. For the description of the lattice shape surrounding the subpixels 110R, 110G, and 110B, FIG. 3B and a paragraph describing the drawing can be referred to. The first wiring layer 151a in FIG. 9C has a lattice shape surrounding the pixel 150, and the second wiring layer 151b also has a lattice shape surrounding the pixel 150. For the description of the lattice shape surrounding the pixel 150, FIG. 3C and a paragraph describing the drawing can be referred to.

As described above, the contact hole 15 can be formed in the region overlapping with the second wiring layer 151b. In FIG. 9B and FIG. 9C, since the second wiring layer 151b overlaps with the first wiring layer 151a, the contact hole 15 can be formed in any region of the auxiliary wiring 151. FIG. 9B and FIG. 9C illustrate examples in which the contact holes 15 are provided in positions similar to those in FIG. 3B and FIG. 3C. The shape of the contact hole can be determined depending on the second wiring layer 151b, and the contact hole 17 extending in the X direction illustrated in FIG. 4C, FIG. 4D, and the like may be formed.

Since the auxiliary wiring 151 of one embodiment of the present invention includes a multilayered wiring layer in this manner, it has high flexibility in the layout. The auxiliary wiring 151 of one embodiment of the present invention is applicable to a high-resolution display device.

This embodiment can be combined with any of the other embodiments as appropriate. In this specification, in the case where a plurality of structure examples are described in one embodiment, the structure examples can be combined as appropriate.

### Embodiment 2

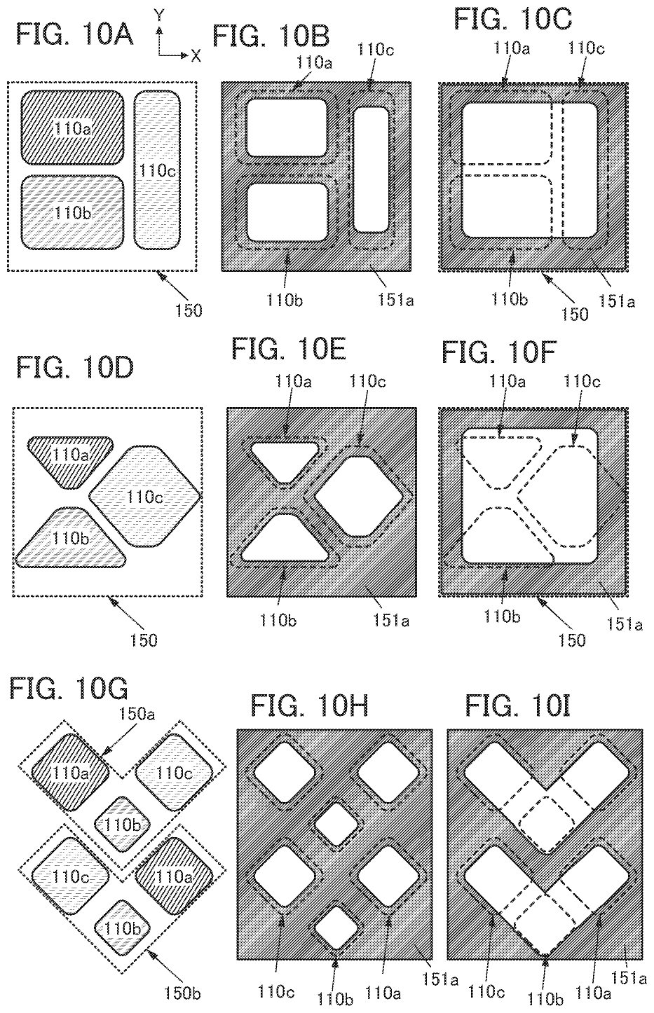

In this embodiment, the display device of one embodiment of the present invention is described with reference to FIG. 10 to FIG. 12.

### [Layout Examples of Pixel and Auxiliary Wiring]

In this embodiment, pixel layouts and auxiliary wiring layouts different from those in FIG. 3A to FIG. 6B, FIG. 9B, FIG. 9C, and the like are mainly described. There is no particular limitation on the arrangement of the subpixels, and a variety of methods can be employed. Examples of the arrangement of the subpixels include stripe arrangement, S stripe arrangement, matrix arrangement, delta arrangement, Bayer arrangement, or PenTile arrangement. These arrangements are described later. The top surface shape of the subpixel illustrated in a diagram in this embodiment corresponds to the top surface shape of a light-emitting region.

Examples of the top surface shape of the subpixel include polygons such as a triangle, a tetragon (including a rectangle and a square), and a pentagon; polygons with rounded corners; an ellipse, and a circle.

The pixel 150 illustrated in FIG. 10A employs S-stripe arrangement. The pixel 150 illustrated in FIG. 10A is composed of three subpixels 110a, 110b, and 110c. The subpixels 110a and 110b are adjacent to each other in the Y direction, and the subpixel 110c is adjacent to the subpixels 110a and 110b in the X direction. The other layouts of the subpixels 110a, 110b, and 110c can be found from FIG. 10A. The light-emitting area of the subpixel 111c can be different from those of the subpixels 110a and 110b and, for example, can be extended.

In this manner, the shapes and sizes of the subpixels can be determined for each light-emitting device. For example, the size of a subpixel including a light-emitting device with higher reliability can be smaller.

FIG. 10B and FIG. 10C illustrate auxiliary wiring layout examples that can be applied to the pixel 150 illustrated in FIG. 10A.

FIG. 10B illustrates the first wiring layer 151a of the auxiliary wiring 151. The first wiring layer 151a includes a region between the subpixel 110a and the subpixel 110b, a region between the subpixel 110b and the subpixel 110c, and a region between the subpixel 110c and the subpixel 110a. The first wiring layer 151a may overlap with the subpixels 110a, 110b, and 110c. Needless to say, the first wiring layer 151a can be laid out not to overlap with the subpixels 110a, 110b, or 110c. The other layout of the first wiring layer 151a can be found from FIG. 10B.

FIG. 10C illustrates the first wiring layer 151a of the auxiliary wiring 151. The first wiring layer 151a includes a region surrounding the pixel 150. The first wiring layer 151a may overlap with the subpixels 110a. 110b, and 110c. The other layout of the first wiring layer 151a can be found from FIG. 10C.

The pixel 150 illustrated in FIG. 10D includes the subpixel 110a whose top surface shape is a rough trapezoid with rounded corners, the subpixel 110b whose top surface shape is a rough triangle with rounded corners, and the subpixel 110c whose top surface shape is a rough tetragon or rough hexagon with rounded corners. The subpixel 110a is positioned along one side of the subpixel 110c, and the subpixel 110b is positioned along another side continuous with the one side of the subpixel 110c. The other layouts of the subpixels 110a, 110b, and 110c can be found from FIG. 10D. The light-emitting area of the subpixel 110c can be different from those of the subpixels 110a and 110b and, for example, can be extended.

In this manner, the shapes and sizes of the subpixels can be determined for each light-emitting device. For example, the size of a subpixel including a light-emitting device with higher reliability can be smaller.

FIG. 10E and FIG. 10F illustrate auxiliary wiring layout examples that can be applied to the pixel 150 illustrated in FIG. 10D.

FIG. 10E illustrates the first wiring layer 151a of the auxiliary wiring 151. The first wiring layer 151a includes a region between the subpixel 110a and the subpixel 110b, a region between the subpixel 110b and the subpixel 110c, and a region between the subpixel 110c and the subpixel 110a. The first wiring layer 151a may overlap with the subpixels 110a, 110b, and 110c. Needless to say, the first wiring layer 151a can be laid out not to overlap with the subpixels 110a, 110b, or 110c. The other layout of the first wiring layer 151a can be found from FIG. 10E.

FIG. 10F illustrates the first wiring layer 151a of the auxiliary wiring 151. The first wiring layer 151a includes a region surrounding the pixel 150. The first wiring layer 151a may overlap with the subpixels 110a, 110b, and 110c. The other layout of the first wiring layer 151a can be found from FIG. 10F.

In this manner, the shapes and sizes of the subpixels can be determined for each light-emitting device. For example, the size of a subpixel including a light-emitting device with higher reliability can be smaller.

The pixels 150a and 150b illustrated in FIG. 10G employ PenTile arrangement. The pixels 150a and 150b each include the subpixels 110a, 110b, and 110c, and the pixels 150a and 150b are different from each other in the arrangement of the subpixels 110a and 110c. Such pixels 150a and 150b are alternately arranged. The other layouts of the subpixels 110a, 110b, and 110c can be found from FIG. 10G. Each of the light-emitting areas of the subpixels 110a and 110c can be different from that of the subpixel 110b and, for example, can be extended.

In this manner, the shapes and sizes of the subpixels can be determined for each light-emitting device. For example, the size of a subpixel including a light-emitting device with higher reliability can be smaller.

FIG. 10H and FIG. 10I illustrate auxiliary wiring layout examples that can be applied to the pixel 150 illustrated in FIG. 10G.

FIG. 10H illustrates the first wiring layer 151a of the auxiliary wiring 151. The first wiring layer 151a includes a region between the subpixel 110a and the subpixel 110b, a region between the subpixel 110b and the subpixel 110c, and a region between the subpixel 110c and the subpixel 110a. The first wiring layer 151a may overlap with the subpixels 110a, 110b, and 110c. Needless to say, the first wiring layer 151a can be laid out not to overlap with the subpixels 110a, 110b, or 110c. The other layout of the first wiring layer 151a can be found from FIG. 10H.

FIG. 10I illustrates the first wiring layer 151a of the auxiliary wiring 151. The first wiring layer 151a includes a region surrounding the pixel 150. The first wiring layer 151a may overlap with the subpixels 110a, 110b, and 110c. The other layout of the first wiring layer 151a can be found from FIG. 10I.

In this manner, the shapes and sizes of the subpixels can be determined for each light-emitting device. For example, the size of a subpixel including a light-emitting device with higher reliability can be smaller.

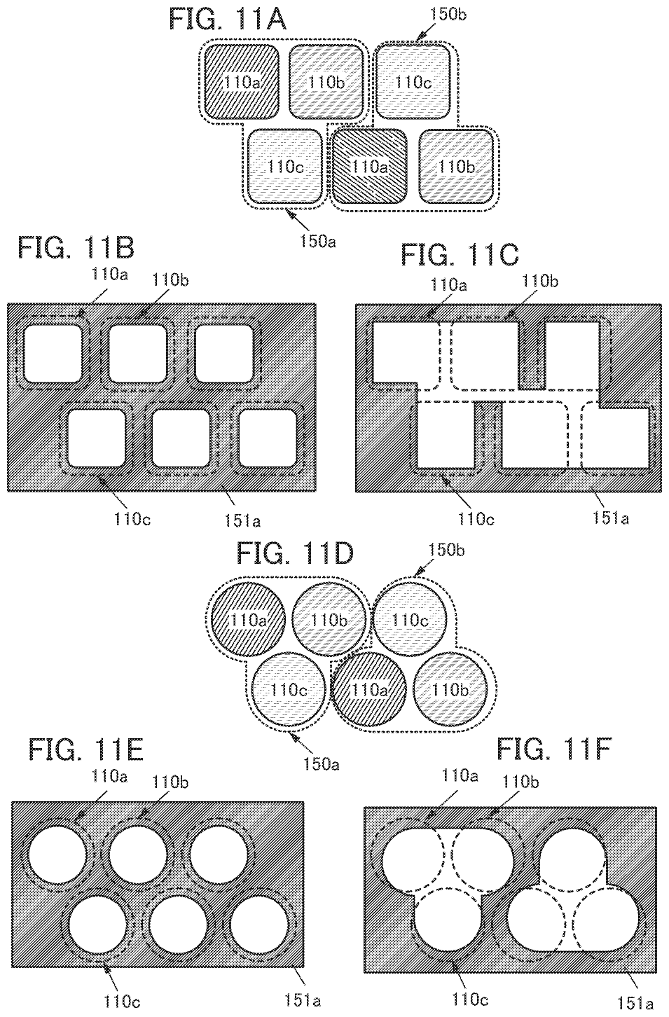

The pixels 150a and 150b illustrated in FIG. 11A employ delta arrangement. FIG. 1I A illustrates an example in which the top surface shape of each subpixel is a rough quadrangle with rounded corners. The pixel 150a includes two subpixels (the subpixels 110a and 110b) in the upper row (first row) and one subpixel (the subpixel 110c) in the lower row (second row). The pixel 150b includes one subpixel (the subpixel 110c) in the upper row (first row) and two subpixels (the subpixels 110a and 110b) in the lower row (second row). The other layouts of the subpixels 110a, 110b, and 110c can be found from FIG. 11A.

FIG. 11B and FIG. 11C illustrate auxiliary wiring layout examples that can be applied to the pixel 150 illustrated in FIG. 11A.

FIG. 11B illustrates the first wiring layer 151a of the auxiliary wiring 151. The first wiring layer 151a includes a region between the subpixel 110a and the subpixel 110b, a region between the subpixel 110b and the subpixel 110c, and a region between the subpixel 110c and the subpixel 110a. The first wiring layer 151a may overlap with the subpixels 110a, 110b, and 110c. Needless to say, the first wiring layer 151a can be laid out not to overlap with the subpixels 110a, 110b, or 110c. The other layout of the first wiring layer 151a can be found from FIG. 11B.

FIG. 11C illustrates the first wiring layer 151a of the auxiliary wiring 151. The first wiring layer 151a includes a region surrounding the pixel 150. The first wiring layer 151a may overlap with the subpixels 110a, 110b, and 110c. The other layout of the first wiring layer 151a can be found from FIG. 11C.

In this manner, the shapes and sizes of the subpixels can be determined for each light-emitting device. For example, the size of a subpixel including a light-emitting device with higher reliability can be smaller.

The pixels 150a and 150b illustrated in FIG. 11D employ delta arrangement. FIG. 11D illustrates an example in which the top surface shape of each subpixel is circular, unlike FIG. 11A. The pixel 150a includes two subpixels (the subpixels 110a and 110b) in the upper row (first row) and one subpixel (the subpixel 110c) in the lower row (second row). The pixel 150b includes one subpixel (the subpixel 110c) in the upper row (first row) and two subpixels (the subpixels 110a and 110b) in the lower row (second row). The other layouts of the subpixels 110a, 110b, and 110c can be found from FIG. 11D.

FIG. 11E and FIG. 11F illustrate auxiliary wiring layout examples that can be applied to the pixel 150 illustrated in FIG. 11D.

FIG. 11E illustrates the first wiring layer 151a of the auxiliary wiring 151. The first wiring layer 151a includes a region between the subpixel 110a and the subpixel 110b, a region between the subpixel 110b and the subpixel 110c, and a region between the subpixel 110c and the subpixel 110a. The first wiring layer 151a may overlap with the subpixels 110a, 110b, and 110c. Needless to say, the first wiring layer 151a can be laid out not to overlap with the subpixels 110a, 110b, or 110c. The other layout of the first wiring layer 151a can be found from FIG. 11E.

FIG. 11F illustrates the first wiring layer 151a of the auxiliary wiring 151. The first wiring layer 151a includes a region surrounding the pixel 150. The first wiring layer 151a may overlap with the subpixels 110a, 110b, and 110c. The other layout of the first wiring layer 151a can be found from FIG. 11F.

In this manner, the shapes and sizes of the subpixels can be determined for each light-emitting device. For example, the size of a subpixel including a light-emitting device with higher reliability can be smaller.

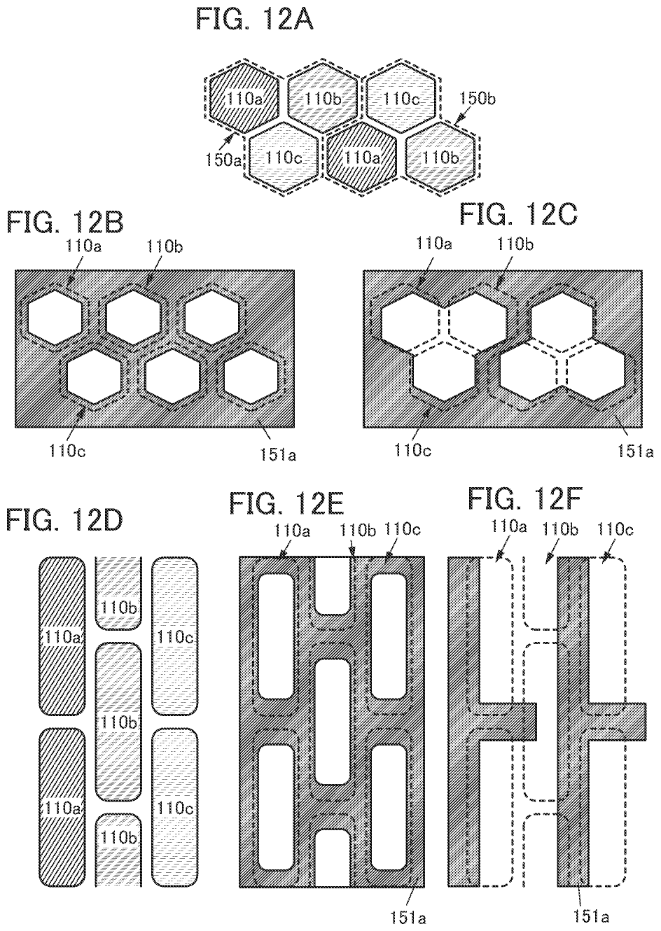

The pixels 150a and 150b illustrated in FIG. 12A employ delta arrangement. FIG. 12A illustrates an example in which each subpixel has a substantially hexagonal top surface shape, unlike FIG. 11A and FIG. 11D. The pixel 150a includes two subpixels (the subpixels 110a and 110b) in the upper row (first row) and one subpixel (the subpixel 110c) in the lower row (second row). The pixel 150b includes one subpixel (the subpixel 110c) in the upper row (first row) and two subpixels (the subpixels 110a and 110b) in the lower row (second row).

In FIG. 12A, subpixels are placed inside respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110a, the subpixel 110a is surrounded by three subpixels 110b and three subpixels 110c that are alternately arranged. The other layouts of the subpixels 110a, 110b, and 110c can be found from FIG. 12A.

FIG. 12B and FIG. 12C illustrate auxiliary wiring layout examples that can be applied to the pixel 150 illustrated in FIG. 12A.

FIG. 12B illustrates the first wiring layer 151a of the auxiliary wiring 151. The first wiring layer 151a includes a region between the subpixel 110a and the subpixel 110b, a region between the subpixel 110b and the subpixel 110c, and a region between the subpixel 110c and the subpixel 110a. The first wiring layer 151a may overlap with the subpixels 110a, 110b, and 110c. Needless to say, the first wiring layer 151a can be laid out not to overlap with the subpixels 110a, 110b, or 110c. The other layout of the first wiring layer 151a can be found from FIG. 12B.

FIG. 12C illustrates the first wiring layer 151a of the auxiliary wiring 151. The first wiring layer 151a includes a region surrounding the pixel 150. The first wiring layer 151a may overlap with the subpixels 110a. 110b, and 110c. The other layout of the first wiring layer 151a can be found from FIG. 12C.

In this manner, the shapes and sizes of the subpixels can be determined for each light-emitting device. For example, the size of a subpixel including a light-emitting device with higher reliability can be smaller.

FIG. 12D illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view. The other layouts of the subpixels 110a, 110b, and 110c can be found from FIG. 12D.

FIG. 12E and FIG. 12F illustrate auxiliary wiring layout examples that can be applied to the pixel 150 illustrated in FIG. 12D.

FIG. 12E illustrates the first wiring layer 151a of the auxiliary wiring 151. The first wiring layer 151a includes a region between the subpixel 110a and the subpixel 110b, a region between the subpixel 110b and the subpixel 110c, and a region between the subpixel 110c and the subpixel 110a. The first wiring layer 151a may overlap with the subpixels 110a, 110b, and 110c. Needless to say, the first wiring layer 151a can be laid out not to overlap with the subpixels 110a, 110b, or 110c. The other layout of the first wiring layer 151a can be found from FIG. 12E.

FIG. 12F illustrates the first wiring layer 151a of the auxiliary wiring 151. The first wiring layer 151a does not surround any pixel and includes a region with a long axis and a region with a short axis. The first wiring layer 151a may overlap with the subpixels 110a, 110b, and 110c. The other layout of the first wiring layer 151a can be found from FIG. 12F.

In this manner, the shapes and sizes of the subpixels can be determined for each light-emitting device. For example, the size of a subpixel including a light-emitting device with higher reliability can be smaller.

In this embodiment, preferably, the subpixel 110a is a subpixel R that emits red light, the subpixel 110b is a subpixel G that emits green light, and a subpixel 110c is the subpixel B that emits blue light, for example. Note that the structure of the subpixels is not limited to this, and the colors and arrangement order of the subpixels can be determined as appropriate. For example, the subpixel 110b may be the subpixel R emitting red light and the subpixel 110a may be the subpixel G emitting green light.

In a photolithography method, as a pattern to be formed by processing becomes finer, the influence of light diffraction becomes more difficult to ignore; accordingly, the fidelity in transferring a photomask pattern by light exposure is degraded, and it becomes difficult to process a resist mask into a desired shape. Thus, a pattern with rounded corners is likely to be formed even when a photomask pattern is rectangular. Consequently, the top surface shape of a subpixel may be a polygon with rounded corners, an ellipse, a circle, or the like.

As described above, the pixel composed of the subpixels each including the light-emitting device can employ any of a variety of layouts in the display device of one embodiment of the present invention.

This embodiment can be combined with any of the other embodiments as appropriate. In the case where a plurality of structure examples are described in one embodiment in this specification, the structure examples can be combined as appropriate.

### Embodiment 3

In this embodiment, a specific example of the display device of one embodiment of the present invention will be described.

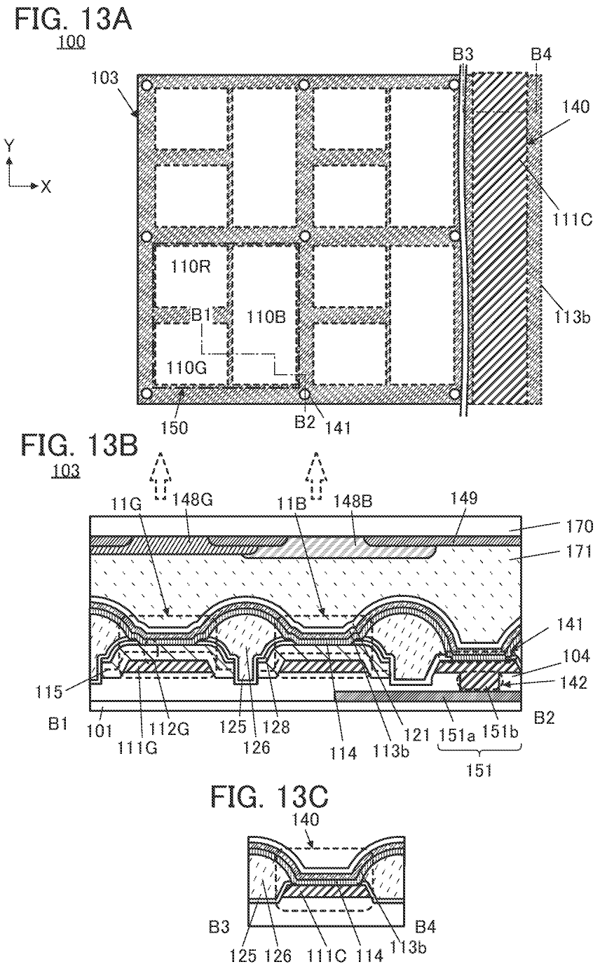

As illustrated in FIG. 13A, the display device 100 includes the pixel portion 103 and the connection portion 140 positioned outside the pixel portion 103. The pixel portion 103 is a region where the pixels 150 are regularly arranged and is referred to as a display region in some cases. The pixel 150 includes the subpixels 110R, 110G, and 110B, and the layouts of the subpixels 110R, 110G, and 110B illustrated in FIG. 13A are similar to those illustrated in FIG. 10A. Specifically, the subpixel 110R that is a red-light-emitting region, the subpixel 110G that is a green-light-emitting region, and the subpixel 110B that is a blue-light-emitting region are used as the subpixel 110a, the subpixel 110b, and the subpixel 110c, respectively, in FIG. 10A. The subpixel 110B can have a larger area than the subpixel 110R and the subpixel 110G.

Note that the emission colors of the display device of one embodiment of the present invention are not limited thereto, and a white-light-emitting region may be provided.

In FIG. 13A, the upper electrode of the light-emitting device is illustrated as the common electrode 113b and the common electrode 113b is provided across the connection portion 140 and the pixel portion 103. The common electrode 113b includes a region extending from the connection portion 140, and the region is indicated by a dotted line. In the connection portion 140, the connection wiring 111C is positioned below the common electrode 113b.

Furthermore, a contact hole 141 is positioned in the pixel portion 103 illustrated in FIG. 13A. The common electrode 113b can be electrically connected to the auxiliary wiring 151 through the contact hole 141. In this embodiment, the contact holes 141 are positioned at four corners surrounding the pixel 150; however, these positions of the contact holes 141 are an example.

FIG. 13B shows a cross-sectional view taken along a dashed-dotted line B1-B2 in FIG. 13A. As illustrated in FIG. 13B, the subpixel 110G includes the light-emitting device 11G and the color filter 148G, and corresponds to the light-emitting region where light passes through the color filter 148G in the direction indicated by an arrow. The subpixel 110B includes the light-emitting device 11B and the color filter 148B, and corresponds to the light-emitting region where light passes through the color filter 148B in the direction indicated by an arrow. Although not illustrated, the subpixel 110R includes a light-emitting device and a color filter and corresponds to the light-emitting region where light passes through the color filter, like the subpixels 110G and 110B.

The light-emitting devices 11R, 11G, and 11B include the lower electrodes 111R, 111G, and 111B, respectively. The lower electrodes 111R, 111G, and 111B preferably have tapered end portions. Owing to the tapered end portion, the organic compound layer formed over the lower electrode as a formation surface is less likely to be divided.

The light-emitting devices 11R, 11G, and 11B include the organic compound layers 112R, 112G, and 112B, respectively. Since the organic compound layers 112R, 112G, and 112B each have a tandem structure, each of the organic compound layers 112R, 112G, and 112B includes the charge-generation layer 115 and the light-emitting units over and under the charge-generation layer 115. Note that FIG. 13B does not illustrate the organic compound layer 112R.

The organic compound layers 112R, 112G, and 112B are processed by a photolithography method and separated from each other. Thus, the end portions of the organic compound layers 112R, 112G, and 112B each have a taper angle greater than or equal to 450 and less than 90°. The taper angle can be found from aside surface in a cross-sectional view, and the taper angle of the side surface is greater than or equal to 450 and less than 90°. Since the organic compound layers 112R, 112G, and 112B are stacked layers, the taper angle of the side surface can be regarded as an angle formed by a formation surface such as a substrate and a line extending from the upper end of the uppermost layer to the lower end of the lowermost layer in the stacked layers.

With the structure in which the organic compound layers are separated, crosstalk due to leakage current is inhibited, so that an image with extremely high display quality can be displayed. Moreover, both a high aperture ratio and high resolution can be achieved.

The subpixels 110R, 110G, and 110B may each include, in addition to the light-emitting devices, switching elements for controlling the light-emitting devices 11R, 11G, and 11B. Note that the switching elements are not illustrated in FIG. 13B. The display device of one embodiment of the present invention can perform display when light is emitted from the light-emitting devices controlled by the switching elements. A transistor can be used as the switching element, and a silicon semiconductor layer or an oxide semiconductor layer can be used as an active layer of the transistor.

The color filters 148G and 148B are provided on the substrate 170, and a light-blocking laver 149 is further provided on the substrate 170 so as to overlap with a boundary between the color filters 148G and 148B. The substrate 170 is referred to as a counter substrate in some cases. The substrate 170 is bonded to the substrate 101 and the like with an adhesive layer 171.

Since the contact hole 141 is positioned in a non-light-emitting region, as illustrated in FIG. 13B, the light-blocking layer 149 is formed also in a region overlapping with the contact hole 141.

As illustrated in FIG. 13B, the auxiliary wiring 151 includes the first wiring layer 151a and the second wiring layer 151b, and they are electrically connected to each other through a contact hole 142. Although the second wiring layer 151b is formed using a conductive layer provided in the same layer as the lower electrodes 111G and 111B, the first wiring layer 151a is a wiring layer provided in a layer different from the lower electrodes 111G and 111B. Thus, as illustrated in FIG. 13B, the first wiring layer 151a may include a region overlapping with the lower electrode 111G or 111B. The top surface shape of the first wiring layer 151a can have a lattice shape described above, or the like. Since the auxiliary wiring 151 includes a multilayered wiring layer, at least the first wiring layer 151a has high flexibility in the layout. The auxiliary wiring 151 of one embodiment of the present invention is applicable to a high-resolution display device.

An insulating layer 126 is preferably provided between two adjacent light-emitting devices. In FIG. 13B, the insulating layer 126 is positioned between the light-emitting device 11G and the light-emitting device 111B, for example. The insulating layer 126 is positioned also between the light-emitting device 11B and the contact hole 141. The insulating layer 126 is provided to fill the above gaps. Furthermore, the insulating layer 126 preferably includes a region overlapping with an end portion of the organic compound layer 112, specifically, an end portion of the insulating layer 126 is preferably positioned over the organic compound layer 112. Such a structure is preferably employed because it reduces the difference in height between the upper portion and the end portion of the insulating layer 126 to make the peeling of the insulating layer 126 difficult.

The upper portion of the insulating layer 126 preferably has a smooth projecting shape. An upper portion having a projecting shape can also be referred to as a shape in which the center portion of the insulating layer 126 rises above the end portion. The common layer 114 and the common electrode 113b that are provided to cover the insulating layer 126 are less likely to be divided, inhibiting display defects.

An insulating layer 125 is preferably provided in contact with the side surface of the organic compound layer 112. The insulating layer 125 is positioned between the insulating layer 126 and the organic compound layer 112 and functions as a protective film for preventing contact between the insulating layer 126 and the organic compound layer 112. In the case where the insulating layer 126 is in contact with the organic compound layer 112, the organic compound laver 112 might be dissolved by an organic solvent or the like used in the formation or processing of the insulating layer 126. In view of this, the insulating layer 125 is provided between the organic compound layer 112 and the insulating layer 126 as described in this embodiment to protect the organic compound layer 112.

The insulating layer 125 can bean insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film formed by an ALD method is used as the insulating layer 125, the insulating layer 125 having few pinholes and an excellent function of protecting the organic compound layer can be formed.

Note that in this specification and the like, an oxynitride refers to a material that contains more oxygen than nitrogen in its composition, and a nitride oxide refers to a material that contains more nitrogen than oxygen in its composition. For example, silicon oxynitride refers to a material that contains more oxygen than nitrogen in its composition, and a silicon nitride oxide refers to a material that contains more nitrogen than oxygen in its composition.

The insulating layer 125 can be formed by a sputtering method, a CVD method, a PLD method, an ALD method, or the like. The insulating layer 125 is preferably formed by an ALD method achieving good coverage.

An insulating layer containing an organic material can be suitably used as the insulating layer 126. For the insulating layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the insulating layer 126, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used.

Moreover, for the insulating layer 126, a photosensitive resin can be used. A photoresist may be used as the photosensitive resin. As the photosensitive resin, a positive material or a negative material can be used.

In the case where a material having photosensitivity is used for the insulating layer 126, light exposure and development are performed, whereby the processed insulating layer 126 can be formed. The surface of the processed insulating layer 126 may have a rounded shape or an uneven shape. Note that etching may be performed to adjust the surface level of the processed insulating layer 126. The insulating layer 126 is processed by ashing using oxygen plasma, so that the surface level can be adjusted.

The insulating layer 126 preferably contains a material absorbing visible light. For example, the insulating layer 126 itself may be formed of a material absorbing visible light, or the insulating layer 126 may contain a pigment absorbing visible light. For example, the insulating layer 126 can be formed using a resin that can be used as a color filter transmitting red, blue, or green light and absorbing other light, a resin that contains carbon black as a pigment and functions as a black matrix, or the like.

It is preferable that the top surface of the insulating layer 126 have a portion whose level is higher than the level of the top surface of the organic compound layer 112.

The insulating layer 126 can be formed by, for example, a wet formation method such as spin coating, dipping, spray coating, ink-jetting, dispensing, screen printing, offset printing, a doctor knife method, slit coating, roll coating, curtain coating, or knife coating. In particular, the organic insulating film to be the insulating layer 126 is preferably formed by spin coating.

After the insulating layer 126 is formed, heat treatment is preferably performed in the air at a temperature higher than or equal to 85° C. and lower than or equal to 120° C. for longer than or equal to 45 minutes and shorter than or equal to 100 minutes. The insulating layer 126 can be dehydrated or degassed.

Between the insulating layer 125 and the insulating layer 126, a reflective film (e.g., a metal film containing one or more selected from silver, palladium, copper, titanium, aluminum, and the like) may be provided. For example, after the insulating layer 125 is formed, the reflective film can be formed. With the reflective film, light emitted from the light-emitting layer can be reflected. This can increase the light extraction efficiency.

As illustrated in FIG. 13B, an insulating layer 128 may be provided between the insulating layer 125 and the top surface of the organic compound layer 112. The insulating layer 128 is a remaining part of a protective layer (also referred to as a mask layer) for protecting the organic compound layer 112 during etching of the organic compound layer 112. For the insulating layer 128, the material that can be used for the insulating layer 125 is preferably used. It is particularly preferable to use the same material for the insulating layer 128 and the insulating layer 125 to facilitate processing. For example, both the insulating layer 128 and the insulating layer 125 preferably include an aluminum oxide film, a hafnium oxide film, or a silicon oxide film.

The insulating layer 125, the insulating layer 126, and the insulating layer 128 are insulating layers positioned between the light-emitting devices and may be collectively referred to as an insulating stack. Since the common layer 114 and the common electrode 113b are provided over the insulating stack, the end portion of the insulating stack preferably has a tapered shape to prevent the common layer 114 and the common electrode 113b from being cut. In order that the end portion of the insulating stack can have a tapered shape, the end portion of the insulating layer 125 may have a tapered shape, the end portion of the insulating layer 126 may have a tapered shape, the end portion of the insulating layer 128 may have a tapered shape, or the end portions of the insulating layer 125, the insulating layer 126, and the insulating layer 128 may each have a tapered shape. In the case where a plurality of insulating layers form a tapered shape, the end portions of the insulating layers are preferably continuously formed to have a tapered shape.

Furthermore, the center portion of the top surface of the insulating stack preferably has a rounded shape. That is, the insulating stack has a shape in which the center portion rises above the end portion. To obtain the above shape, the insulating layer 126 positioned in the uppermost layer of the insulating stack is preferably formed using an organic material.

Furthermore, the end portion of the insulating stack can have various shapes. For example, the insulating layer 125 positioned as a lower layer of the insulating stack may protrude from the insulating layer 126. In that case, part of an upper portion of the insulating layer 125 is removed at the time of processing of the insulating layer 126 in some cases. Removing part of the upper portion of the insulating layer 125 that protrudes from the insulating layer 126 has an effect of preventing the common layer 114 and the common electrode 113b from being cut.

The insulating layer 128 may protrude from the insulating layer 126. In that case, part of an upper portion of the insulating layer 128 is removed at the time of processing of the insulating layer 126 in some cases. Removing part of the upper portion of the insulating layer 128 that protrudes from the insulating layer 126 has an effect of preventing the common layer 114 and the common electrode 113b from being cut.

When the insulating layer 128 protrudes from the insulating layer 126, it is preferable that the end portion of the insulating layer 125 positioned below the insulating layer 128 be aligned or substantially aligned with the end portion of the insulating layer 128.

As illustrated in FIG. 13B, a protective layer 121 is provided over the common electrode 113b. The protective layer 121 has a function of preventing diffusion of impurities into the light-emitting elements from above.

The protective layer 121 can have, for example, a single-layer structure or a stacked-layer structure at least including an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as an indium gallium oxide or an indium gallium zinc oxide may be used for the protective layer 121.

The protective layer 121 is bonded to the substrate 170 with an adhesive layer 171. For the adhesive layer 171, a variety of curable adhesives such as a reactive curable adhesive, a thermosetting adhesive, an anaerobic adhesive, and a photocurable adhesive such as an ultraviolet curable adhesive can be used. As the adhesive layer 171, an adhesive sheet or the like may be used.

In the connection portion 140 illustrated in FIG. 13C, an opening portion is provided in the insulating layer 125 and the insulating layer 126 over the connection wiring 111C. The connection wiring II IC and the common electrode 113b are electrically connected to each other in the opening portion.

FIG. 13C illustrates a structure in which the common layer 114 is provided over the connection wiring 111C and the common electrode 113b is provided over the common layer 114. In the case where a carrier-injection layer such as an electron-injection layer is used as the common layer 114, for example, the resistivity of a material used for the common layer 114 is sufficiently low; thus, the connection wiring 111C can be electrically connected to the common electrode 113b through the common layer 114. Accordingly, the common electrode 113b and the common layer 114 can be formed using the same area mask or rough metal mask, whereby the manufacturing cost can be reduced. The area mask or the rough metal mask is different from a fine metal mask. Needless to say, in the connection portion 140, the connection wiring 111C may include a region in direct contact with the common electrode 113b.

The display device of one embodiment of the present invention can be used in an ultra-large display with a size greater than or equal to 40 inches, greater than or equal to 100 inches, and even greater than 100 inches.

This embodiment can be combined with any of the other embodiments as appropriate. In the case where a plurality of structure examples are described in one embodiment in this specification, the structure examples can be combined as appropriate.

### Embodiment 4

In this embodiment, structure examples and material examples of a light-emitting device that can be used in the display device of one embodiment of the present invention will be described.

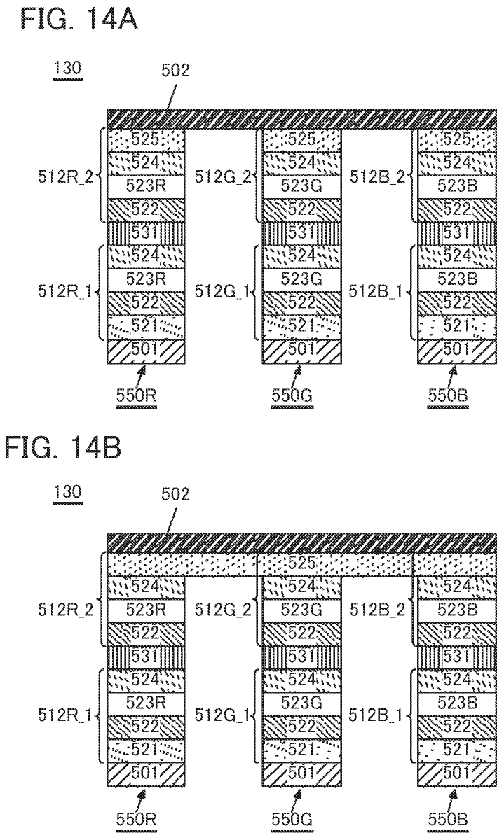

FIG. 14A illustrates a schematic cross-sectional view of the pixel portion 103 included in the display device. The display device includes a light-emitting device 550R that emits red light, a light-emitting device 550G that emits green light, and a light-emitting device 550B that emits blue light in the pixel portion 103.

The light-emitting device 550R has a tandem structure in which, between a pair of electrodes (an electrode 501 and an electrode 502), two light-emitting units (a light-emitting unit 512R_1 and a light-emitting unit 512R_2) are stacked with a charge-generation layer 531 therebetween. The light-emitting device 550G has a tandem structure in which, between the pair of electrodes, two light-emitting units (a light-emitting unit 512G_1 and a light-emitting unit 512G_2) are stacked with the charge-generation layer 531 therebetween. The light-emitting device 550B has a tandem structure in which, between the pair of electrodes, two light-emitting units (a light-emitting unit 512B_1 and a light-emitting unit 512R_B) are stacked with the charge-generation layer 531 therebetween.

The electrode 501 of each light-emitting unit in this embodiment can correspond to the lower electrode 111R, 111G, or 111B in Embodiment 1 and the like, the charge-generation layer 531 can correspond to the charge-generation layer 115 in Embodiment 1 and the like, and the electrode 502 can correspond to the upper electrode 113 in Embodiment 1 and the like.

As illustrated in FIG. 14A, the light-emitting unit 512R_1 includes a layer 521, a layer 522, a light-emitting layer 523R, and a layer 524. The light-emitting unit 512R_2 includes the layer 522, the light-emitting layer 523R, the layer 524, and a layer 525.

In the light-emitting device, the layer 521 includes a hole-injection layer, for example, when the electrode 501 functions as an anode and the electrode 502 functions as a cathode. The layer 522 includes a hole-transport layer or an electron-blocking layer, for example. In the layer 522, the functional layers may be stacked, and for example, a hole-transport layer and an electron-blocking layer can be included in the layer 522 in the case of a stacked-layer structure. In the layer 522 in which the above layers are stacked, the electron-blocking layer is preferably positioned on the light-emitting layer 523R side though the hole-transport layer may be positioned on the light-emitting layer 523R side. The layer 524 includes an electron-transport layer or a hole-blocking layer, for example. In the layer 524, the functional layers may be stacked, and for example, an electron-transport layer and a hole-blocking layer can be included in the layer 524 in the case of a stacked-layer structure. In the layer 524 in which the above layers are stacked, the hole-blocking layer is preferably positioned on the light-emitting layer 523R side though the electron-transport layer may be positioned on the light-emitting layer 523R side. The layer 525 includes an electron-injection layer, for example.

In the light-emitting device, the layer 521 includes an electron-injection layer, for example, when the electrode 501 functions as a cathode and the electrode 502 functions as an anode. The layer 522 includes an electron-transport layer or a hole-blocking layer, for example. In the layer 522, the functional layers may be stacked, and for example, an electron-transport layer and a hole-blocking layer can be included in the layer 522 in the case of a stacked-layer structure. In the layer 522 in which the above layers are stacked, the hole-blocking layer is preferably positioned on the light-emitting layer 523R side though the electron-transport layer may be positioned on the light-emitting layer 523R side. The layer 524 includes a hole-transport layer or an electron-blocking layer, for example. In the layer 524, the functional layers may be stacked, and for example, a hole-transport layer and an electron-blocking layer can be included in the layer 524 in the case of a stacked-layer structure. In the layer 524 in which the above layers are stacked, the electron-blocking layer is preferably positioned on the light-emitting layer 523R side though the hole-transport layer may be positioned on the light-emitting layer 523R side. The layer 525 includes a hole-injection layer, for example.

Note that the light-emitting unit 512R_1 and the light-emitting unit 512R_2 may be the same or different in the structure (material, thickness, or the like) of the layer 522, the light-emitting layer 523R, and the layer 524.

The above-described difference in the structure of the layer 522 is, for example, a structure in which the layer 522 in the light-emitting unit 512R_1 includes a hole-transport layer and the layer 522 in the light-emitting unit 512R_2 includes a hole-transport layer and an electron-blocking layer. The light-emitting unit 512R_1 and the light-emitting unit 512R_2 are just examples, and the light-emitting unit 512R_1 and the light-emitting unit 512R_2 may be interchanged.

The above-described difference in the structure of the light-emitting layer 523R is, for example, a structure in which the light-emitting layer 523R includes a different light-emitting substance as long as the wavelength range of red light is obtained.

The above-described difference in the structure of the layer 524 is, for example, a structure in which the layer 524 in the light-emitting unit 512R_1 includes an electron-transport layer and the layer 524 in the light-emitting unit 512R_2 includes an electron-transport layer and a hole-blocking layer. The light-emitting unit 512R_1 and the light-emitting unit 512R_2 are just examples, and the light-emitting unit 512R_1 and the light-emitting unit 512R_2 may be interchanged.

FIG. 14A illustrates the layer 521 and the layer 522 separately, however, this structure is just an example and one embodiment of the present invention is not limited thereto. For example, a hole-transport layer as the layer 522 may be omitted when the layer 521 has functions of both a hole-injection layer and the hole-transport layer. Alternatively, an electron-transport layer as the layer 522 may be omitted when the layer 521 has functions of both an electron-injection layer and the electron-transport layer.

In the case of a light-emitting device having a tandem structure, two light-emitting units are stacked with the charge-generation layer 531 therebetween. In the charge-generation layer 531, a region having a function of injecting electrons into one of the light-emitting unit 512R_1 and the light-emitting unit 512R_2 and injecting holes into the other when voltage is applied between the electrode 501 and the electrode 502 is referred to as a charge-generation region. That is, the charge-generation layer 531 includes at least the charge-generation region.

The light-emitting layer 523R included in the light-emitting device 550R contains alight-emitting substance (also referred to as a light-emitting material) that emits red light, a light-emitting layer 523G included in the light-emitting device 550G contains a light-emitting substance that emits green light, and a light-emitting layer 523B included in the light-emitting device 550B contains a light-emitting substance that emits blue light.

Note that the light-emitting device 550G has a structure in which the light-emitting layer 523R included in the light-emitting device 550R is replaced with the light-emitting layer 523G described above, and the other functional layers are similar to those of the light-emitting device 550R. Similarly, the light-emitting device 550B has a structure in which the light-emitting layer 523R included in the light-emitting device 550R is replaced with the light-emitting layer 523B described above, and the other functional layers are similar to those of the light-emitting device 550R. In consideration of the above, the same reference numerals are used for the functional layers and the like included in the light-emitting device 550R, the light-emitting device 550G, and the light-emitting device 550B in FIG. 14A.

The structure (material, thickness, and the like) of the layer 521, the layer 522, the layer 524, and the layer 525 may be the same among the light-emitting devices of two or more or all of the colors or different from each other among the light-emitting devices of all the colors.

As already described above, a structure in which a plurality of light-emitting units are connected in series with the charge-generation layer 531 therebetween as in the light-emitting device 550R, the light-emitting device 550G, and the light-emitting device 550B is referred to as a tandem structure. Note that the tandem structure may be referred to as a stack structure. The tandem structure enables a light-emitting device capable of high-luminance light emission. By contrast, a structure in which one light-emitting unit is provided between a pair of electrodes is referred to as a single structure. Furthermore, a tandem structure allows the amount of current needed for obtaining the same luminance to be reduced as compared to the case of using a single structure; thus, the light-emitting device can have higher reliability.

As already described above, the structure where at least the light-emitting layers of the light-emitting devices are separately formed, as in the light-emitting device 550R, the light-emitting device 550G, and the light-emitting device 550B, are referred to as an SBS structure. Furthermore, the light-emitting device 550R, the light-emitting device 550G, and the light-emitting device 550B each employ a tandem structure. The display device of the present invention takes advantages of both the tandem structure and the SBS structure.

Note that the light-emitting device illustrated in FIG. 14A has a structure in which two light-emitting units are formed in series, and thus may be referred to as a two-unit tandem structure. In the two-unit tandem structure illustrated in FIG. 14A, light-emitting units including the light-emitting layers that exhibit the same color are stacked. Specifically, in the light-emitting device 550R, a second light-emitting unit including a red-light-emitting layer is stacked over a first light-emitting unit including a red-light-emitting layer. Similarly, in the light-emitting device 550G, a second light-emitting unit including a green-light-emitting layer is stacked over a first light-emitting unit including a green-light-emitting layer. Similarly, in the light-emitting device 550B, a second light-emitting unit including a blue-light-emitting layer is stacked over a first light-emitting unit including a blue-light-emitting layer.

FIG. 14B is a modification example of the light-emitting device illustrated in FIG. 14A. The light-emitting device illustrated in FIG. 14B is an example in which, like the electrode 502, the layer 525 is shared by a plurality of light-emitting devices. In this case, the layer 525 can be referred to as a common layer. By providing one or more common layers for a plurality of light-emitting devices in this manner, the fabrication process can be simplified, resulting in a reduction in manufacturing cost.

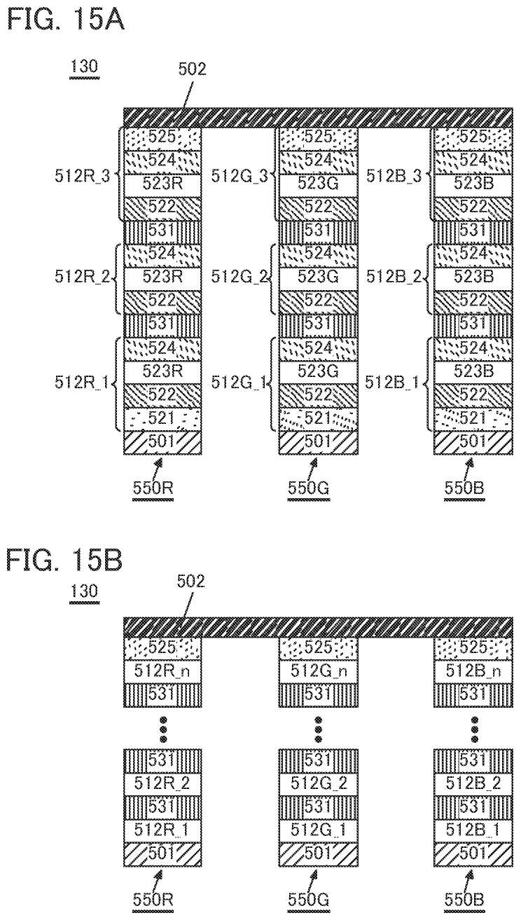

FIG. 15A illustrates an example of a three-unit tandem structure, i.e., the case in which three light-emitting units are stacked. In FIG. 15A, the light-emitting device 550R includes a light-emitting unit 512R_3 over the light-emitting unit 512R_2 with the charge-generation layer 531 therebetween. The light-emitting unit 512R_3 can have a structure similar to that of the light-emitting unit 512R_I or the light-emitting unit 512R_2. Specifically, the light-emitting unit 512R_3 can contain a light-emitting material similar to that of the light-emitting unit 512R_1 or the light-emitting unit 512R_2.

The light-emitting device 550G includes a light-emitting unit 512G_3 over the light-emitting unit 512G_2 with the charge-generation layer 531 therebetween. The light-emitting unit 512G_3 can have a structure similar to that of the light-emitting unit 512G_1 or the light-emitting unit 512G_2. Specifically, the light-emitting unit 512G_3 can contain a light-emitting material similar to that of the light-emitting unit 512G_1 or the light-emitting unit 512G_2.

The light-emitting device 550B includes a light-emitting unit 512B_3 over the light-emitting unit 512B_2 with the charge-generation layer 531 therebetween. The light-emitting unit 512B_3 can have a structure similar to that of the light-emitting unit 512B_1 or the light-emitting unit 512B_2. Specifically, the light-emitting unit 512B_3 can contain a light-emitting material similar to that of the light-emitting unit 512B_1 or the light-emitting unit 512B_2.

In the tandem structure, as the number of stacked light-emitting units is increased, the number of charge-generation layers 531 is also increased. In the case where a plurality of charge-generation layers 531 are included as described above, the plurality of charge-generation layers 531 may be the same or different in the structure (material, thickness, or the like) of the light-emitting devices. Furthermore, the structures of the plurality of charge-generation layers 531 may be entirely the same or may be different from each other.

FIG. 15B illustrates an example where an n-unit tandem structure, i.e., the case where n light-emitting units (n is an integer greater than or equal to 2) are stacked. The n-unit tandem structure includes (n−1) charge-generation layers 531.

When the number of stacked light-emitting units is increased in the above manner, luminance obtained from the light-emitting device with the same amount of current can be increased in accordance with the number of stacked layers. Moreover, increasing the number of stacked light-emitting units can reduce the amount of current needed for obtaining the same luminance; thus, power consumption of the light-emitting device can be reduced in accordance with the number of stacked layers.

Next, materials that can be used for the light-emitting device will be described.

A conductive film that transmits visible light is used for the electrode 501 or the electrode 502 to be the extraction electrode. A conductive film that reflects visible light is preferably used for the counter electrode opposite to the extraction electrode.

In the case where the display device additionally includes a light-emitting device emitting infrared light, a conductive film that transmits visible light and infrared light is preferably used for the extraction electrode and a conductive film that reflects visible light and infrared light is preferably used for the counter electrode.

A conductive film that transmits visible light may be used also for the counter electrode. In this case, the conductive film that transmits visible light is stacked with the conductive film that reflects visible light, and the conductive film that transmits visible light is positioned on the light-emitting layer side.

As a material that forms the pair of electrodes of the light-emitting device, a metal, an alloy, an electrically conductive compound, a mixture thereof, and the like can be used. Specific examples of the material include an alloy containing one or two selected from aluminum, titanium, chromium, manganese, iron, cobalt, nickel, copper, gallium, zinc, indium, tin, molybdenum, tantalum, tungsten, palladium, gold, platinum, silver, yttrium, neodymium, and the like. Examples of the material include an oxide containing indium and tin (also referred to as indium tin oxide, In—Sn oxide, or ITO), an oxide containing indium, silicon, and tin (also referred to as In—Si—Sn oxide or ITSO), an oxide containing indium and zinc (also referred to as indium zinc oxide or In—Zn oxide), and an oxide containing indium, tungsten, and zinc (also referred to as In—W—Zn oxide). Other examples of the material include an alloy containing aluminum (aluminum alloy) such as an alloy of aluminum, nickel, and lanthanum (Al—Ni—La), and an alloy containing silver such as an alloy of silver and magnesium and an alloy of silver, palladium, and copper (also referred to as Ag—Pd—Cu or APC). Other examples of the material include one selected from the elements belonging to Group 1 or Group 2 of the periodic table (e.g., lithium, cesium, calcium, and strontium), rare earth metals such as europium and ytterbium and alloys of two or more selected from the above. Other examples of the material include graphene.

As already described above, the light-emitting device includes at least the light-emitting laver. As the functional layers other than the light-emitting laver, the light-emitting device can include one or more of a hole-injection layer, a hole-transport layer, a hole-blocking layer, a charge-generation layer, an electron-blocking layer, an electron-transport layer, and an electron-injection layer.

For each of the functional layers, either a low-molecular compound or a high-molecular compound can be used, and an inorganic compound may also be used. Each layer included in the light-emitting device can be formed by a method such as an evaporation method (including a vacuum evaporation method), a transfer method, a printing method, an inkjet method, or a coating method.

### <Light-Emitting Layer>

The light-emitting layer contains one or more kinds of light-emitting substances. As the light-emitting substance, a substance whose emission color is blue, violet, bluish violet, green, yellowish green, yellow, orange, red, or the like is used as appropriate. Alternatively, as the light-emitting substance, a substance emitting near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (in particular, an iridium complex) having a 4H-triazole skeleton, a 1H-triazole skeleton, an imidazole skeleton, a pyrimidine skeleton, a pyrazine skeleton, or a pyridine skeleton. Other examples of the phosphorescent material include an organometallic complex (in particular, an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a substance having a high hole-transport property (a hole-transport material) and a substance having a high electron-transport property (an electron-transport material) can be used. As the hole-transport material, a later-described material with a high hole-transport property that can be used for the hole-transport layer can be used. As the electron-transport material, a material having a high electron-transport property which can be used for the electron-transport layer and will be described later can be used. As one or more kinds of organic compounds, a bipolar material or a TADF material may be used.

The light-emitting layer preferably contains a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When the combination of the materials is selected so as to form an exciplex that exhibits light emission whose wavelength overlaps with the wavelength on a lowest-energy-side absorption band of the light-emitting substance, energy can be transferred smoothly and light emission can be obtained efficiently. With the above structure, high efficiency, low-voltage driving, and a long lifetime of the light-emitting device can be achieved at the same time.

Note that light-emitting materials of the light-emitting layers are not particularly limited. In FIG. 15A, for example, a structure in which the two light-emitting layers 523R included in the light-emitting device 550R each contain a phosphorescent material, the two light-emitting layers 523G included in the light-emitting device 550G each contain a fluorescent material, and the two light-emitting layers 523B included in the light-emitting device 550B each contain a fluorescent material can be employed.

Alternatively, for example, a structure in which the two light-emitting layers 523R included in the light-emitting device 550R each contain a phosphorescent material, the two light-emitting layers 523G included in the light-emitting device 550G each contain a phosphorescent material, and the two light-emitting layers 523B included in the light-emitting device 550B each contain a fluorescent material can be employed.

For the display device of one embodiment of the present invention, a structure may be employed in which fluorescent materials are used for all the light-emitting layers included in the light-emitting devices 550R, 550G, and 550B or a structure may be employed in which phosphorescent materials are used for all the light-emitting layers included in the light-emitting devices 550R, 550G, and 550B.

A structure in which the light-emitting layer 523R included in the light-emitting unit 512R_1 contains a phosphorescent material and the light-emitting layer 523R included in the light-emitting unit 512R_2 contains a fluorescent material or a structure in which the light-emitting layer 523R included in the light-emitting unit 512R_1 contains a fluorescent material and the light-emitting layer 523R included in the light-emitting unit 512R_2 contains a phosphorescent material, i.e., a structure in which a light-emitting layer in a first unit and a light-emitting layer in a second unit contain different light-emitting materials may be employed. Note that here, the light-emitting unit 512R_1 and the light-emitting unit 512R_2 are described, and the same structure can also be applied to the light-emitting unit 512G_1 and the light-emitting unit 512G_2, and the light-emitting unit 512B_l and the light-emitting unit 512B_2.

### <Hole-Injection Layer>

The hole-injection layer is a layer that injects holes from an anode to the hole-transport laver and contains a material with a high hole-injection property. Examples of the material with a high hole-injection property include an aromatic amine compound. Other examples of the material with a high hole-injection property include an acceptor material (an electron-accepting material) and a composite material containing an acceptor material and a hole-transport material.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. An organic acceptor material containing fluorine can be used. An organic acceptor material such as a quinodimethane derivative, a chloranil derivative, or a hexaazatriphenylene derivative can be used.

As the hole-transport material, a later-described material with a high hole-transport property that can be used for the hole-transport layer can be used.

For example, a hole-transport material and a material containing an oxide of a metal belonging to Group 4 to Group 8 of the periodic table (typically, molybdenum oxide) may be used as the material having a high hole-injection property.

### <Hole-Transport Layer>

The hole-transport layer is a layer transporting holes, which are injected from the anode by the hole-injection layer, to the light-emitting layer. The hole-transport layer is a layer that contains a hole-transport material. As the hole-transport material, a substance having a hole mobility higher than or equal to 1×10⁻⁶ cm²/Vs is preferable. Note that other substances can also be used as long as they have a hole-transport property higher than an electron-transport property.

As the hole-transport material, materials having a high hole-transport property, such as a n-electron rich heteroaromatic compound (e.g., a carbazole derivative, a thiophene derivative, and a furan derivative) and an aromatic amine (a compound having an aromatic amine skeleton), can be given.

### <Electron-Blocking Layer>

The electron-blocking layer is a layer having a hole-transport property and containing a material that can block electrons. Any of the materials having an electron-blocking property among the above hole-transport materials can be used for the electron-blocking layer. Such an electron-blocking layer may be referred to as a hole-transport layer.

### <Electron-Transport Layer>

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility higher than or equal to 1×10⁶ cm²/Vs is preferable. Note that other substances can also be used as long as they have an electron-transport property higher than a hole-transport property.

As the electron-transport material, it is possible to use a material with a high electron-transport property, such as a metal complex having a quinoline skeleton, a metal complex having a benzoquinoline skeleton, a metal complex having an oxazole skeleton, and a metal complex having a thiazole skeleton. Other examples of the electron-transport material include an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, and a pyrimidine derivative. As the other electron-transport material, a material having a high electron-transport property, such as a n-electron deficient heteroaromatic compound including the other nitrogen-containing heteroaromatic compound, can be used.

### <Hole-Blocking Layer>

The hole-blocking layer is a layer having an electron-transport property and containing a material that can block holes. Any of the materials having a hole-blocking property among the above electron-transport materials can be used for the hole-blocking layer. Such a hole-blocking layer may be referred to as an electron-transport layer.

### <Electron-Injection Layer>

The electron-injection layer is a layer that injects electrons from the cathode to the electron-transport layer and contains a material with a high electron-injection property. Examples of the material with a high electron-injection property include an alkali metal, an alkaline earth metal, a compound of an alkali metal, and a compound of an alkaline earth metal As the material with a high electron-injection property, a composite material containing an electron-transport material and a donor material (an electron-donating material) can also be used.

The difference between the LUMO level of the material with a high electron-injection property and the work function value of the material used for the cathode is preferably small (specifically, smaller than or equal to 0.5 eV).

For the electron-injection layer, an alkali metal, an alkaline earth metal, or a compound thereof, such as lithium, cesium, ytterbium, lithium fluoride (LiF), cesium fluoride (CsF), calcium fluoride (CaFX, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ₎, or cesium carbonate, for example, can be used. The electron-injection layer may have a stacked-layer structure of two or more layers. The stacked-layer structure can be, for example, a structure where lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, a compound having one or more selected from a pyridine ring, a diazine ring (a pyrimidine ring, a pyrazine ring, or a pyridazine ring), and a triazine ring can be used.

Note that the lowest unoccupied molecular orbital (LUMO) level of an organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2-(1,3-phenylene)bis[9-phenyl-1,10-phenanthroline] (abbreviation: mPPhen2P), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPVTz), or the like can be used as the organic compound having an unshared electron pair. Note that NBPhen has a higher glass transition point (Tg) than BPhen and thus has high heat resistance.

### <Charge-Generation Layer>

As described above, the charge-generation layer includes at least a charge-generation region. The charge-generation region preferably contains an acceptor material. As the acceptor material, the material given in <Hole-injection layer> above can be used, for example. For example, the charge-generation layer may contain the same material as the acceptor material contained in the hole-injection layer.

Furthermore, the charge-generation region preferably contains a composite material containing an acceptor material and a hole-transport material, for example. As the hole-transport material, the material given in <Hole-transport layer> above can be used, for example. For example, the charge-generation layer may contain the same material as the hole-transport material contained in the hole-injection layer or the hole-transport layer. As the composite material containing an acceptor material and a hole-transport material, a stacked-layer structure of a layer containing an acceptor material and a layer containing a hole-transport material may be used or a layer in which an acceptor material and a hole-transport material are mixed may be used. The layer in which materials are mixed is obtained by, for example, co-evaporation of an acceptor material and a hole-transport material.

Note that the charge-generation layer may contain a donor material instead of an acceptor material. In the case of containing a donor material, a layer containing a donor material, the electron-transport material given in <Hole-injection layer> above, and the donor material is preferably used as the charge-generation layer.

### <Electron-Injection Buffer Layer>

The charge-generation layer sometimes includes a layer containing a material having a high electron-injection property in addition to the charge-generation region. The layer is sometimes extremely thin and referred to as a region. The layer can also be referred to as an electron-injection buffer layer, and the region can also be referred to as an electron-injection buffer region. By provision of the electron-injection buffer layer, an injection barrier between the charge-generation region and the electron-transport layer can be lowered; thus, electrons generated in the charge-generation region can be easily injected into the electron-transport layer. The electron-injection buffer layer is thus preferably provided between the charge-generation region and the electron-transport layer.

The electron-injection buffer layer preferably contains an alkali metal or an alkaline earth metal. For example, the electron-injection buffer layer can contain the above-described compound of an alkali metal or the above-described compound of an alkaline earth metal. Specifically, the electron-injection buffer layer is preferably formed using an alkali metal (e.g., lithium, sodium, or calcium), and is preferably formed using an inorganic compound containing the alkali metal and oxygen or an inorganic compound containing the alkali metal and fluorine. Examples of the inorganic compound containing an alkali metal and oxygen include an inorganic compound containing lithium and oxygen, and specifically lithium oxide (Li₂O). Examples of the inorganic compound containing an alkali metal and fluorine include an inorganic compound containing lithium and fluorine, and specifically lithium fluoride (LiF). The electron-injection buffer layer preferably contains an inorganic compound containing an alkaline earth metal and oxygen.

Alternatively, the material given in <Electron-injection layer> above can be favorably used for the electron-injection buffer layer. For example, the electron-injection buffer layer may contain the same material as the material having a high electron-injection property contained in the electron-injection layer.

The electron-injection buffer layer preferably contains a composite material containing an alkali metal or an alkaline earth metal and an electron-transport material, for example. As the inorganic compound containing an alkali metal and oxygen, an inorganic compound containing the alkali metal and oxygen may be used. As the electron-transport material, the material given in <Electron-transport layer> above can be used, for example. For example, the charge-generation layer may contain the same material as the electron-transport material contained in the electron-injection layer or the electron-transport layer. As an alkali metal, an alkaline earth metal, or the composite material containing the inorganic compound containing an alkali metal and oxygen or the inorganic compound containing an alkaline earth metal and oxygen and an electron-transport material, a stacked-layer structure in which a layer containing an alkali metal, an alkaline earth metal, an inorganic compound containing an alkali metal and oxygen, or an inorganic compound containing an alkaline earth metal and oxygen and a layer containing an electron-transport material may be used or a layer in which an alkali metal, an alkaline earth metal, an inorganic compound containing an alkali metal and oxygen, or an inorganic compound containing an alkaline earth metal and oxygen is mixed with an electron-transport material may be used. The mixed layer can be obtained by co-evaporation of an alkali metal, an alkaline earth metal, an inorganic compound containing an alkali metal and oxygen, or an inorganic compound containing an alkaline earth metal and oxygen and an electron-transport material, for example.

A boundary between the charge-generation region and the electron-injection buffer layer described above might be unclear. For example, both an element contained in the charge-generation region and an element contained in the electron-injection buffer layer might be detected by time-of-flight secondary ion mass spectrometry (referred to as TOF-SIMS) analysis of a very thin charge-generation layer. When lithium oxide is used for the electron-injection buffer layer, lithium might be detected from not only the electron-injection buffer layer but also the whole charge-generation layer because of the high diffusibility of an alkali metal such as lithium. Thus, a region where lithium is detected by TOF-SIMS can be regarded as the charge-generation layer.

### <Electron-Relay Layer>

The charge-generation layer sometimes includes a layer containing a material having a high electron-transport property in addition to the charge-generation region. The layer is sometimes extremely thin and referred to as a region. The layer can also be referred to as an electron-relay layer, and the region can also be referred to as an electron-relay region. The electron-relay layer has a function of preventing interaction between the charge-generation region and the electron-injection buffer layer (or the electron-transport layer) and smoothly transferring electrons. The electron-relay layer is thus preferably provided between the charge-generation region and the electron-injection buffer layer. In the case where the charge-generation layer does not include the electron-injection buffer layer, the electron-relay layer is preferably provided between the charge-generation region and the electron-transport layer.

For the electron-relay layer, the electron-transport material given in <Electron-transport layer> above can be suitably used. For the electron-relay layer, a phthalocyanine-based material such as copper(II) phthalocyanine (abbreviation: CuPc) can be suitably used. For the electron-relay layer, a metal complex having a metal-oxygen bond and an aromatic ligand can be suitably used.

In the charge-generation layer in which the electron-relay layer is provided between the charge-generation region and the electron-injection buffer layer, a boundary between the charge-generation region and the electron-relay layer or a boundary between the electron-relay layer and the electron-injection buffer layer might be unclear. For example, an element contained in the charge-generation region, an element contained in the electron-relay layer, and an element contained in the electron-injection buffer layer might all be detected by TOF-SIMS analysis of a very thin charge-generation layer. When lithium oxide is used for the electron-injection buffer layer, lithium might be detected from not only the electron-injection buffer layer but also the whole charge-generation layer because of the high diffusibility of an alkali metal such as lithium. Thus, a region where lithium is detected by TOF-SIMS can be regarded as the charge-generation layer.

In the charge-generation layer in which the electron-relay layer is provided between the charge-generation region and the electron-transport layer, a boundary between the charge-generation region and the electron-relay layer might be unclear. For example, both an element contained in the charge-generation region and an element contained in the electron-relay layer might be detected by TOF-SIMS analysis of a very thin charge-generation layer.

When the light-emitting units are stacked, provision of the charge-generation layer between two light-emitting units can inhibit an increase in driving voltage.

This embodiment can be combined with any of the other embodiments as appropriate. In the case where a plurality of structure examples are described in one embodiment in this specification, the structure examples can be combined as appropriate.

### Embodiment 5

In this embodiment, a display device will be described.

### [Structure Example of Display Device]

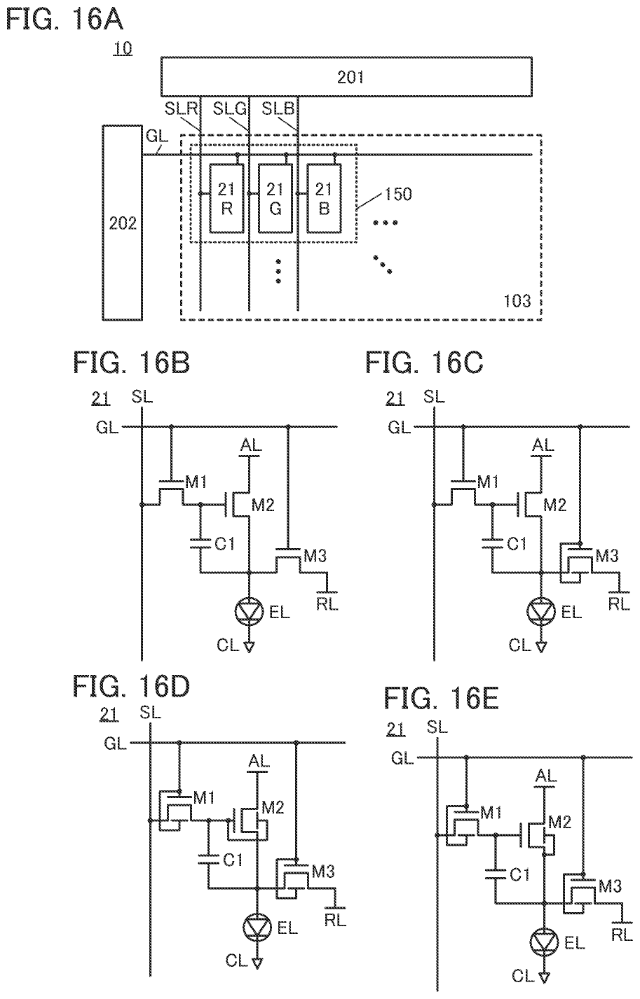

FIG. 16A illustrates a block diagram of a display device 10. The display device 10 includes the pixel portion 103, a driver circuit portion 201, a driver circuit portion 202, and the like.

The pixel portion 103 includes the plurality of pixels 150 laid out in a matrix. Each of the pixels 150 includes a subpixel 21R, a subpixel 21G, and a subpixel 21B.

The pixel 150 is electrically connected to a wiring GL, a wiring SLR, a wiring SLG, and a wiring SLB. The wiring SLR, the wiring SLG, and the wiring SLB are electrically connected to the driver circuit portion 201. The wiring GL is electrically connected to the driver circuit portion 202. The driver circuit portion 201 functions as a source line driver circuit (also referred to as a source driver), and the driver circuit portion 202 functions as a gate line driver circuit (also referred to as a gate driver). The wiring GL functions as a gate line, and the wiring SLR, the wiring SLG, and the wiring SLB each function as a source line.

The subpixel 21R emits red light. The subpixel 21G emits green light. The subpixel 21B emits blue light. Thus, the display device 10 can perform full-color display. Note that the pixel 150 may include a subpixel that emits light of another color. For example, the pixel 150 may include, in addition to the three subpixels, a subpixel that emits white light, a subpixel that emits yellow light, or the like.

The wiring GL is electrically connected to the subpixel 21R, the subpixel 21G, and the subpixel 21B arranged in the row direction (an extending direction of the wiring GL). The wiring SLR, the wiring SLG, and the wiring SLB are electrically connected to the subpixels 21R, the subpixels 21G, and the subpixels 21B (not illustrated), respectively, arranged in the column direction (an extending direction of the wiring SLR and the like).

### [Structure Example of Pixel Circuit]

FIG. 16B illustrates an example of a circuit diagram of the pixel 150 that can be used as the subpixel 21R, the subpixel 21G, and the subpixel 21B. The pixel 150 includes a transistor M1, a transistor M2, a transistor M3, a capacitor C1, and a light-emitting device EL. The wiring GL and a wiring SL are electrically connected to the pixel 150. The wiring SL corresponds to any of the wiring SLR, the wiring SLG, and the wiring SLB illustrated in FIG. 12A.

A gate of the transistor M1 is electrically connected to the wiring GL, one of a source and a drain of the transistor M1 is electrically connected to the wiring SL, and the other of the source and the drain of the transistor M1 is electrically connected to one electrode of the capacitor C1 and agate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device EL is electrically connected to a wiring CL.

A data potential D is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 150, the anode potential is a potential higher than the cathode potential. The reset potential supplied to the wiring RL can be set such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. The transistor M2 functions as a transistor for controlling current flowing through the light-emitting device EL. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In that case, an LTPS transistor can be used as at least one of a plurality of transistors included in the driver circuit portion 201 and a plurality of transistors included in the driver circuit portion 202, and OS transistors can be used as the other transistors. For example, OS transistors can be used as the transistors provided in the pixel portion 103, and LTPS transistors can be used as the transistors provided in the driver circuit portion 201 and the driver circuit portion 202.

As the OS transistor, a transistor containing an oxide semiconductor in a semiconductor layer where a channel is formed can be used. The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one or more kinds selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Further alternatively, it is preferable to use an oxide containing indium, gallium, tin, and zinc.

A transistor containing an oxide semiconductor having a wider band gap and a lower carrier density than silicon can achieve an extremely low off-state current. Accordingly, such a low off-state current enables long-term retention of charge accumulated in a capacitor that is connected to the transistor in series. Thus, it is particularly preferable to use a transistor containing an oxide semiconductor as the transistor M1 and the transistor M3 each of which is connected to the capacitor C1 in series. The use of the transistor containing an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long time without rewriting data in the pixel 150.

Although the transistors are illustrated as n-channel transistors in FIG. 16B, a p-channel transistor can also be used.

The transistors included in the pixel 150 are preferably formed to be arranged over the same substrate.

Transistors each including a pair of gates overlapping with each other with a semiconductor layer therebetween can be used as the transistors included in the pixel 150.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, w % ben a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 150 illustrated in FIG. 16C is an example of the case where a transistor including a pair of gates is used as the transistor M3. The gates of the transistor M3 are electrically connected to each other. Such a structure can shorten the period in which data is written to the pixel 150.

The pixel 150 illustrated in FIG. 16D is an example in which a transistor including a pair of gates is used also as each of the transistor M1 and the transistor M2 in addition to the transistor M3. In each of the transistors, the pair of gates are electrically connected to each other. When such a transistor is used at least as the transistor M2, the saturation characteristics are improved, so that the emission luminance of the light-emitting device EL can be controlled easily and the display quality can be improved.

The pixel 150 illustrated in FIG. 16E is an example of the case where one of the pair of gates of the transistor M2 in the pixel 150 illustrated in FIG. 16D is electrically connected to the source of the transistor M2.

### [Structure Example of Transistor]

Cross-sectional structure examples of the transistor will be described below.

### Structure Example 1

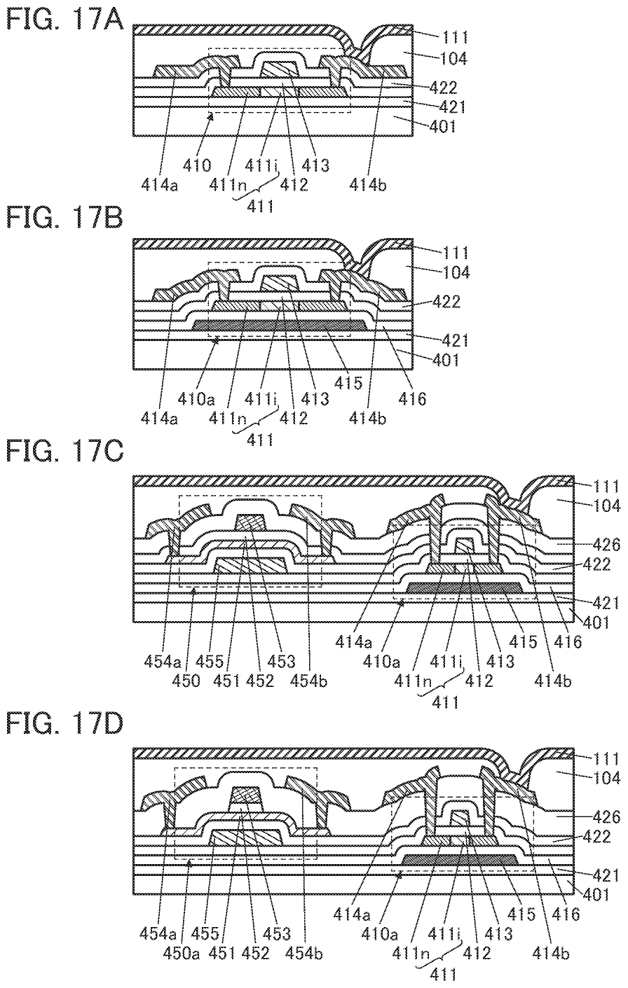

FIG. 17A is a cross-sectional view including a transistor 410.

The transistor 410 is provided over a substrate 401 and contains polycrystalline silicon in its semiconductor layer. The transistor 410 corresponds to the transistor M2 in the pixel 150, for example. That is. FIG. 17A illustrates an example in which one of a source and a drain of the transistor 410 is electrically connected to the lower electrode 111 of the light-emitting device.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating laver 412 functions as agate insulating layer. Part of the conductive layer 413 functions as agate electrode.

Note that the semiconductor layer 411 can include a metal oxide exhibiting semiconductor characteristics (also referred to as an oxide semiconductor). In that case, the transistor 410 can be referred to as an OS transistor.

The low-resistance regions 41 in are each a region containing an impurity element. For example, in the case where the transistor 410 is an n-channel transistor, phosphorus, arsenic, or the like is added to the low-resistance regions 411n. Meanwhile, in the case where the transistor 410 is a p-channel transistor, boron, aluminum, or the like is added to the low-resistance regions 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided in a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are electrically connected to the low-resistance regions 411n in opening portions provided in the insulating layer 422 and the insulating layer 412. Part of the conductive layer 414a functions as one of a source electrode and a drain electrode, and part of the conductive layer 414b functions as the other of the source electrode and the drain electrode. The insulating layer 104 is provided to cover the conductive layer 414a, the conductive layer 414b, and the insulating layer 422.

The lower electrode 111 functioning as a pixel electrode is provided over the insulating layer 104. The lower electrode 111 is provided over the insulating layer 104 and is electrically connected to the conductive layer 414b in an opening provided in the insulating layer 104. Although not illustrated here, an EL layer and a common electrode can be stacked over the lower electrode 111.

### Structure Example 2

FIG. 17B illustrates a transistor 410a including a pair of gate electrodes. The transistor 410a illustrated in FIG. 17B is different from the transistor in FIG. 17A mainly in including a conductive layer 415 and an insulating layer 416.

The conductive laver 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 17B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating laver 412 and the insulating laver 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case of using LTPS transistors as all of the transistors included in the pixels 150, the transistor 410 exemplified in FIG. 17A or the transistor 410a exemplified in FIG. 17B can be used. In that case, the transistors 410a may be used as all of the transistors included in the pixels 150, the transistors 410 may be used as all of the transistors, or the transistors 410a and the transistors 410 may be used in combination.

### Structure Example 3

Described below is an example of a structure including both a transistor containing silicon in its semiconductor layer and a transistor containing a metal oxide in its semiconductor layer.

FIG. 17C is a cross-sectional view including the transistor 410a and a transistor 450.

Structure example 1 described above can be referred to for the transistor 410a. Although an example of using the transistor 410a is illustrated here, a structure including the transistor 410 and the transistor 450 or a structure including all the transistor 410, the transistor 410a, and the transistor 450 may alternatively be employed.

The transistor 450 is a transistor containing a metal oxide in its semiconductor layer. The structure illustrated in FIG. 17C is an example in which the transistor 450 and the transistor 410a respectively correspond to the transistor M1 and the transistor M2 in the pixel 150. That is, FIG. 17C illustrates an example in which one of a source and a drain of the transistor 410a is electrically connected to the lower electrode 111.

Moreover, FIG. 17C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In that case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in opening portions provided in the insulating layer 426 and the insulating layer 452. Part of the conductive layer 454a functions as one of a source electrode and a drain electrode, and part of the conductive layer 454b functions as the other of the source electrode and the drain electrode. The insulating layer 104 is provided to cover the conductive laver 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b. In FIG. 17C, the conductive layer 414a, the conductive layer 414b, the conductive laver 454a, and the conductive layer 454b are formed on the same plane (i.e., in contact with the top surface of the insulating layer 426) and contain the same metal element. In that case, the conductive layer 414a and the conductive layer 414b are electrically connected to the low-resistance regions 411n through openings provided in the insulating layer 426, the insulating layer 452, the insulating layer 422, and the insulating layer 412. This is preferable because the fabrication process can be simplified.

Moreover, the conductive layer 413 functioning as the first gate electrode of the transistor 410a and the conductive layer 455 functioning as the second gate electrode of the transistor 450 are preferably formed by processing the same conductive film. FIG. 17C illustrates a structure in which the conductive layer 413 and the conductive layer 455 are formed on the same plane (i.e., in contact with the top surface of the insulating laver 412) and contain the same metal element. This is preferable because the fabrication process can be simplified.

In the structure in FIG. 17C, the insulating layer 452 functioning as the first gate insulating layer of the transistor 450 covers the end portion of the semiconductor layer 451; however, the insulating layer 452 may be processed to have the same or substantially the same top surface shape as the conductive layer 453 as in the transistor 450a illustrated in FIG. 17D.

Note that in this specification and the like, the expression “top surface shapes are substantially the same” means that at least outlines of stacked layers partly overlap with each other. For example, the case of processing an upper layer and a lower layer with the use of the same mask pattern or mask patterns that are partly the same is included. However, in some cases, the outlines do not completely overlap with each other and the upper layer is positioned inward from the lower layer or the upper layer is positioned outward from the lower layer; such cases are also represented by the expression “top surface shapes are substantially the same”.

Although the example in which the transistor 410a corresponds to the transistor M2 and is electrically connected to the pixel electrode is illustrated here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

By including the above pixel circuit and having the structure of the light-emitting device described in the above embodiment, the display device can display an image with any one or more of image crispness, image sharpness, high chroma, and a high contrast ratio. The display device is preferable; leakage current that might flow through the transistors in the pixel circuit is extremely low and lateral leakage current between the light-emitting devices in the above embodiment is extremely low, leading to little leakage of light or the like at the time of black display.

This embodiment can be combined with any of the other embodiments as appropriate. In the case where a plurality of structure examples are described in one embodiment in this specification, the structure examples can be combined as appropriate.

### Embodiment 6

In this embodiment, a display device including a light-receiving device (also referred to as a light-receiving element) will be described.

A pixel portion may include a light-receiving device in addition to a light-emitting device, in which case a display device having a light-receiving function can be provided. The display device having a light-receiving function can detect touch or approach of an object while displaying an image. A region where the light-receiving device is positioned is referred to as a light-receiving portion, and the light-receiving portion also includes a switching element that controls the light-receiving device. The light-receiving device controlled by the switching element can detect one or both of visible light and infrared light. Specifically, the light-receiving device has a function of receiving light from a light source and can convert the received light into an electric signal.

As a visible light source, light from the light-emitting device can be used. In the case of using the light-emitting device, a wavelength of green light obtained through a green color filter is preferably used because the light-receiving sensitivity is high. When some of the light-emitting devices emit light as a light source, an image may be displayed by the remaining subpixels. As an infrared light source, an infrared light source positioned outside the pixel portion can be used.

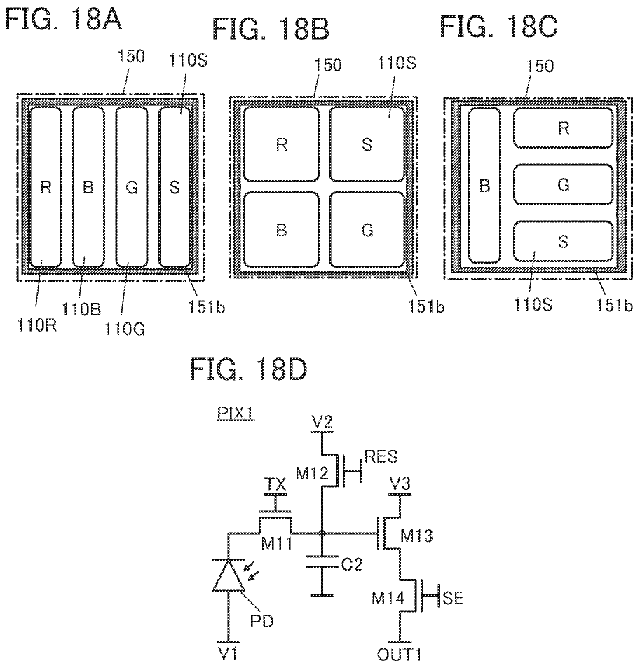

The pixel 150 illustrated in each of FIG. 18A, FIG. 18B, and FIG. 18C includes the subpixel 110G, the subpixel 110B, the subpixel 110R, and a light-receiving portion 110S, and further includes the auxiliary wiring. FIG. 18A, FIG. 18B, and FIG. 18C illustrate the second wiring layer 151b that is part of the auxiliary wiring 151. In FIG. 18A, FIG. 18B, and FIG. 18C, regions are denoted by reference numerals R, G. B, and S to easily differentiate the subpixels and the like.

The pixel 150 illustrated in FIG. 18A employs stripe arrangement, and the second wiring layer 151b is provided to surround the subpixel 110G, the subpixel 110B, the subpixel 110R, and the light-receiving portion 110S.

The pixel illustrated in FIG. 18B employs matrix arrangement, and the second wiring layer 151b is provided to surround the subpixel 110G, the subpixel 110B, the subpixel 110R, and the light-receiving portion 110S.

The pixel 150 illustrated in FIG. 18C employs arrangement in which three subpixels (the subpixel 110R, the subpixel 110G, and the light-receiving portion 110S) are vertically arranged next to one subpixel (the subpixel 110B), and the second wiring layer 151b is provided to surround the subpixel 110G, the subpixel 110B, the subpixel 110R, and the light-receiving portion 110S.

Note that the layout of the subpixels is not limited to the structures in FIG. 18A to FIG. 18C. The layout of the second wiring layer 151b is not limited to the structures in FIG. 18A to FIG. 18C.

In the case where a light-receiving area of the light-receiving portion 110S is smaller than a light-emitting area of each of the other subpixels, an image-capturing range becomes narrow, which can inhibit a blur in a captured result and increase the definition. Thus, the display device of one embodiment of the present invention can perform high-resolution or high-definition image capturing. For example, image capturing for personal authentication with the use of a fingerprint, a palm print, the iris, the shape of a blood vessel (including the shape of a vein and the shape of an artery), a face, or the like is possible by using the light-receiving portion 110S.

Moreover, the light-receiving portion 110S can be used in a touch sensor (also referred to as a direct touch sensor), a near touch sensor (also referred to as a hover sensor, a hover touch sensor, a contactless sensor, or a touchless sensor), or the like.

A touch sensor or a near touch sensor can sense an approach or contact of an object (a finger, a hand, a pen, or the like). The touch sensor can sense the object when the display device and the object come in direct contact with each other. The near touch sensor can sense an object even when the object is not in contact with the display device. For example, the display device is preferably capable of sensing an object when the distance between the display device and the object is more than or equal to 0.1 mm and less than or equal to 300 mm, preferably more than or equal to 3 mm and less than or equal to 50 mm. This structure enables the display device to be operated without direct contact of an object, that is, enables the display device to be operated in a contactless (touchless) manner. With the above-described structure, the display device can have a reduced risk of being dirty or damaged, or can be operated without the object directly touching dirt (e.g., dust or a virus) attached to the display device.

For high-resolution image capturing, the light-receiving portion 110S is preferably provided in all pixels included in the display device. Meanwhile, in the case where the light-receiving portion 110S is used in a touch sensor, a near touch sensor, or the like, high accuracy is not required as compared to the case of capturing an image of a fingerprint; accordingly, the light-receiving portion 110S only needs to be provided in some of the pixels in the display device. When the number of light-receiving portions 110S included in the display device is smaller than the number of subpixels 110R or the like, higher sensing speed can be achieved.

FIG. 18D illustrates an example of a pixel circuit of a subpixel (PIX1) including a light-receiving device.

The pixel circuit illustrated in FIG. 18D includes a light-receiving device PD, a transistor M11, a transistor M12, a transistor M13, a transistor M14, and a capacitor C2. Here, an example in which a photodiode is used as the light-receiving device PD is illustrated.

An anode of the light-receiving device PD is electrically connected to a wiring V1, and a cathode of the light-receiving device PD is electrically connected to one of a source and a drain of the transistor M11. A gate of the transistor M11 is electrically connected to a wiring TX, and the other of the source and the drain of the transistor M11 is electrically connected to one electrode of the capacitor C2, one of a source and a drain of the transistor M12, and a gate of the transistor M13. Agate of the transistor M12 is electrically connected to a wiring RES, and the other of the source and the drain of the transistor M12 is electrically connected to a wiring V2. One of a source and a drain of the transistor M13 is electrically connected to a wiring V3, and the other of the source and the drain of the transistor M13 is electrically connected to one of a source and a drain of the transistor M14. Agate of the transistor M14 is electrically connected to a wiring SE, and the other of the source and the drain of the transistor M14 is electrically connected to a wiring OUT1.

A constant potential is supplied to each of the wiring V1, the wiring V2, and the wiring V3. To drive the light-receiving device PD, the wiring V2 is supplied with a potential higher than the potential of the wiring V1. The transistor M12 is controlled by a signal supplied to the wiring RES and has a function of resetting the potential of a node connected to the gate of the transistor M13 to a potential supplied to the wiring V2. The transistor M11 is controlled by a signal supplied to the wiring TX and has a function of controlling the timing at which the potential of the node changes, in accordance with current flowing through the light-receiving device PD. The transistor M13 functions as an amplifier transistor for performing output corresponding to the potential of the node. The transistor M14 is controlled by a signal supplied to the wiring SE and functions as a selection transistor for reading the output corresponding to the potential of the node by an external circuit electrically connected to the wiring OUT1.

A transistor containing a metal oxide (an oxide semiconductor) in a semiconductor layer where a channel is formed (an OS transistor) is preferably used as each of the transistor M11, the transistor M12, the transistor M13, and the transistor M14.

An OS transistor having a wider band gap and a lower carrier concentration than silicon can achieve an extremely low off-state current.

Alternatively, a transistor containing silicon as a semiconductor where a channel is formed can be used as each of the transistor M11 to the transistor M14. It is particularly preferable to use silicon with high crystallinity, such as single crystal silicon or polycrystalline silicon, in which case high field-effect mobility can be achieved and higher-speed operation can be performed.

Alternatively, a transistor containing an oxide semiconductor may be used as one or more of the transistor M11 to the transistor M14, and transistors containing silicon may be used as the other transistors.

Although n-channel transistors are illustrated as the transistors in FIG. 18D, p-channel transistors can be used.

The refresh rate of the display device of one embodiment of the present invention can be variable. For example, the refresh rate is adjusted (in the range from 0.01 Hz to 240 Hz inclusive, for example) in accordance with contents displayed on the display device, whereby power consumption can be reduced. Moreover, driving with a lowered refresh rate that reduces the power consumption of the display device may be referred to as idling stop (IDS) driving.

The driving frequency of the touch sensor or the near touch sensor may be changed in accordance with the refresh rate. For example, when the refresh rate of the display device is 120 Hz, the driving frequency of the touch sensor or the near touch sensor can be higher than 120 Hz (can typically be 240 Hz). With this structure, low power consumption can be achieved, and the response speed of the touch sensor or the near touch sensor can be increased.

This embodiment can be combined with any of the other embodiments as appropriate. In the case where a plurality of structure examples are described in one embodiment in this specification, the structure examples can be combined as appropriate.

### Embodiment 7

In this embodiment, a metal oxide (also referred to as an oxide semiconductor) that can be used in the OS transistor described in the above embodiment will be described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a CVD method such as an MOCVD method, an ALD method, or the like.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method.

For example, the XRD spectrum of a quartz glass substrate shows a peak with a substantially bilaterally symmetrical shape. On the other hand, the peak of the XRD spectrum of an IGZO film having a crystal structure has a bilaterally asymmetrical shape. The bilaterally asymmetrical peak of the XRD spectrum clearly shows the existence of crystals in the film or the substrate. In other words, the crystal structure of the film or the substrate cannot be regarded as an amorphous state unless it has a bilaterally symmetrical peak in the XRD spectrum.

A crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass is in an amorphous state. Furthermore, not a halo pattern but a spot-like pattern is observed in the diffraction pattern of the IGZO film formed at room temperature. Thus, it is suggested that the IGZO film formed at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a plurality of fine crystals, the size of the crystal region may be approximately several tens of nanometers.

In the case of an In-M-Zn oxide (an element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Thus, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Hence, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

[a-like OS]

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. For example, the first region has higher [In] and lower [Ga] than the second region. Moreover, the second region has higher [Ga] and lower [In] than the first region.

Specifically, the first region contains an indium oxide, an indium zinc oxide, or the like as its main component. The second region contains a gallium oxide, a gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In a material composition of a CAC-OS in an In—Ga—Zn oxide that contains In, Ga. Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. That is, when carriers flow through the first region, the conductivity of a metal oxide is exhibited. Accordingly, when the first regions are distributed in a metal oxide like a cloud, high field-effect mobility (p) can be achieved.

The second region has a higher insulating property than the first region. That is, when the second regions are distributed in a metal oxide, leakage current can be inhibited.

Thus, in the case w % here a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (p), and excellent switching operation can be achieved.

A transistor using the CAC-OS has high reliability. Thus, the CAC-OS is most suitable for a variety of semiconductor devices such as display devices.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1-10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm.

When an oxide semiconductor with sufficiently reduced impurities is used for the channel formation region of the transistor, stable electrical characteristics can be given.

This embodiment can be combined with any of the other embodiments as appropriate. In the case where a plurality of structure examples are described in one embodiment in this specification, the structure examples can be combined as appropriate.

### Embodiment 8

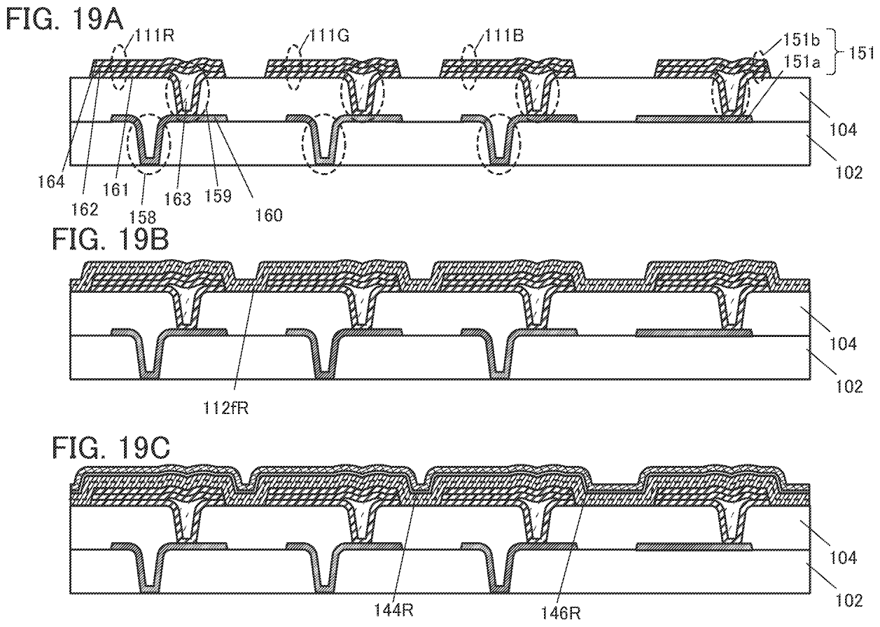

An example of a method for fabricating the above-described display device will be described with reference to FIG. 19 to FIG. 26 and the like. In the drawings, a region related to the pixel 150 is illustrated on the left side, and a region related to the auxiliary wiring 151 is illustrated on the right side.

### [Fabrication Method Example 1]

Thin films included in the display device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method and a thermal CVD method. An example of a thermal CVD method is a metal organic chemical vapor deposition (MOCVD: Metal Organic CVD) method.

Thin films included in the display device (insulating films, semiconductor films, conductive films, resin films, and the like) can be formed by a method such as spin coating, dipping, spray coating, ink-jetting, dispensing, screen printing, offset printing, a doctor knife method, slit coating, roll coating, curtain coating, or knife coating. These are wet formation methods.

The thin films included in the display device can be processed by a photolithography method or the like. Besides, the thin films may be processed by a nanoimprinting method, a sandblasting method, a lift-off method, or the like. Furthermore, the thin films may be directly formed by a formation method using a metal mask or the like.

There are the following two typical methods using a photolithography method. In one of the methods, a resist mask is formed over a thin film that is to be processed, the thin film is processed by etching or the like, and then the resist mask is removed. In the other method, a photosensitive thin film is deposited and then processed into a desired shape by light exposure and development.

For light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. Alternatively, for the light used for the light exposure, extreme ultraviolet (EUV) light, X-rays, or the like may be used. Furthermore, instead of the light used for the light exposure, an electron beam can also be used. Extreme ultraviolet light, X-rays, or an electron beam is preferably used, in which case extremely minute processing can be performed. Note that when light exposure is performed by scanning of a beam such as an electron beam, a resist mask is not needed.

For etching of the thin films, a dry etching method, a wet etching method, a sandblasting method, or the like can be used.

### [Preparation of Substrate]

Although not illustrated, a substrate is prepared. As the substrate, a substrate having at least heat resistance high enough to withstand heat treatment performed later can be used. In the case where an insulating substrate is used as the substrate, a glass substrate, a quartz substrate, a sapphire substrate, a ceramic substrate, an organic resin substrate, or the like can be used. Alternatively, it is possible to use a semiconductor substrate such as a single crystal semiconductor substrate or a polycrystalline semiconductor substrate containing silicon, silicon carbide, or the like as a material; a compound semiconductor substrate of silicon germanium or the like; or an SOI substrate.

As the substrate, it is preferable to prepare the semiconductor substrate or the insulating substrate where a pixel circuit including a semiconductor element such as a transistor is formed. A substrate where a gate line driver circuit (a gate driver), a source line driver circuit (a source driver), or the like is formed besides the pixel circuit may be used. In addition to the above, a substrate where an arithmetic circuit, a memory circuit, or the like is formed may be used.

### [Formation of Insulating Layer 102]

As illustrated in FIG. 19A, an insulating layer 102 is formed over the above substrate. For the insulating layer 102, an inorganic material or an organic material can be used. The organic material is preferable because it enables the insulating layer 104 to surely have a planar top surface. As the organic material, one or two or more selected from an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used. In the case where two or more of the organic materials are used, the selected organic materials are stacked.

As illustrated in FIG. 19A, the insulating layer 102 includes a contact hole 158. The contact hole 158 can be formed by a photolithography method, for example.

[Formation of Conductive Layer 160 and First Wiring Layer 151a]

As illustrated in FIG. 19A, a conductive layer 160 is formed over the insulating layer 102 and in the contact hole 158. The first wiring layer 151a is formed over the insulating layer 102. That is, the conductive layer 160 and the first wiring layer 151a are formed on the same formation surface through the same process. Specifically, a conductive film formed over the insulating layer 102 and in the contact hole 158 is processed to obtain the conductive layer 160 and the first wiring layer 151a.

The conductive layer 160 is electrically connected to the transistor of the pixel circuit. The conductive layer 160 can be processed to have an elongated shape over the insulating layer 102 and can function as a signal line, a power supply line, a scan line, or the like. The conductive layer 160 does not necessarily function as a wiring and may be a conductive layer for electrically connecting the transistor and the lower electrode 111 to each other. The first wiring layer 151a can function as a lower wiring layer of the auxiliary wiring 151 and is processed to have an elongated shape, a lattice shape, or the like over the insulating layer 102. Note that the first wiring layer 151a is not in contact with the conductive layer 160. The first wiring layer 151a can be formed to have a large area over the insulating layer 102 and is thus preferable as the auxiliary wiring.

For the conductive layer 160 and the first wiring layer 151a, a metal such as aluminum, copper, silver, gold, platinum, chromium, or molybdenum can be used. An alloy of the metal can be used as the conductive material. The metal and the alloy of the metal described above are materials with relatively low resistivity and preferably have lower resistivity than a conductive material contained in a shared electrode to be formed later.

The conductive layer 160 and the first wiring layer 151a may each have a single-layer structure containing the above metal or the above alloy or a stacked-layer structure containing the above metal material.

Other than the above, one or two or more metals selected from titanium, manganese, iron, cobalt, nickel, gallium, zinc, indium, tin, tantalum, tungsten, palladium, yttrium, neodymium, and the like, an alloy containing any of these, or the like can be used for the conductive layer 160 and the first wiring layer 151a. Since the resistivity of the metal and the alloy of the metal described above is not as low as that of the metal given in the upper paragraph, adjusting the thickness or forming a stacked-layer structure is preferably employed.

### [Formation of Insulating Layer 104]

As illustrated in FIG. 19A, the insulating layer 104 is formed over the insulating layer 102. For the insulating layer 104, an inorganic material or an organic material can be used. The organic material is preferable because it enables the insulating layer 104 to surely have a planar top surface. As the organic material, one or two or more selected from an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used. In the case where two or more of the organic materials are used, the selected organic materials are stacked.

The insulating layer 104 includes a contact hole 159. The contact hole 159 can be formed by a photolithography method or the like, and parts of the conductive layer 160 and the first wiring layer 151a are exposed in the contact hole 159. The contact hole 159 does not overlap with the contact hole 158 and is preferably provided in a position overlapping with the conductive layer 160 provided on the flat top surface of the insulating layer 102. In the case where the contact hole 159 overlaps with the contact hole 158, the diameter of the contact hole 159 in a cross-sectional view is preferably larger than the diameter of the contact hole 158.

### [Formation of Conductive Layer 161, Resin Layer 163, and Conductive Layer 162]

As illustrated in FIG. 19A, in the contact hole 159, a conductive layer 161 is formed followed by formation of a resin layer 163, and then a conductive layer 162 is formed. A conductive layer 164 described later may be formed without formation of the conductive layer 161, the resin layer 163, and the conductive layer 162.

A conductive film to be the conductive layer 161 is formed over the insulating layer 104 and the contact hole 159. Preferably, the top surface of the insulating layer 104 is a formation surface of the conductive film and has planarity to make the conductive film less likely to be cut.

For the conductive layer 160 and the first wiring layer 151a, a metal such as aluminum, copper, silver, gold, platinum, chromium, or molybdenum can be used. An alloy of the metal can be used as the conductive material. The metal and the alloy of the metal described above are materials with relatively low resistivity and preferably have lower resistivity than a conductive material contained in a shared electrode to be formed later.

The conductive layer 160 and the first wiring layer 151a may each have a single-layer structure containing the above metal or a stacked-layer structure containing the above metal material.

Other than the above, one or two or more metals selected from titanium, manganese, iron, cobalt, nickel, gallium, zinc, indium, tin, tantalum, tungsten, palladium, yttrium, neodymium, and the like, an alloy containing any of these, or the like can be used for the conductive layer 160 and the first wiring layer 151a. Since the resistivity of the metal and the alloy of the metal described above is not as low as that of the metal given in the upper paragraph, adjusting the thickness or forming a stacked-layer structure is preferably employed. For the conductive layer 161, one or two or more metals selected from aluminum, titanium, chromium, manganese, iron, cobalt, nickel, copper, gallium, zinc, indium, tin, molybdenum, tantalum, tungsten, palladium, gold, platinum, silver, yttrium, and neodymium; an alloy containing any of these, or the like can be used.

In the case where the surface of the formed conductive film has a depressed portion, a layer containing a resin as an organic material (referred to as a resin layer) 163 is preferably formed in the depressed portion. With the resin layer 163, unevenness due to the insulating layer 104, the contact hole 159, and the conductive layer 161 can be reduced.

It is preferable to use a photosensitive resin for the resin layer 163. In that case, the resin layer 163 can be formed in the following manner: a resin film is formed first, and the resin film is exposed to light through a photomask and is then subjected to development treatment. Further preferably, in order to adjust the level of the top surface of the resin layer 163, an upper portion of the resin layer 163 may be etched by ashing or the like.

In the case where a non-photosensitive resin is used for the resin layer 163, the resin layer 163 can be formed in the following manner: a resin film is formed, and then an upper portion of the resin film is etched by ashing or the like. The ashing is performed until part of the surface of the conductive film to be the conductive layer 161 is exposed. The thickness of the resin layer 163 can be optimized by ashing or the like.

Next, a conductive film to be the conductive layer 162 is formed over the resin layer 163. The conductive layer 162 preferably contains one or two or more selected from the metals and the like described for the conductive layer 161.

### [Formation of Conductive Layer 164]

As illustrated in FIG. 19A, a conductive film to be the conductive layer 164 is formed to cover the conductive film to be the conductive layer 161 and the conductive film to be the conductive layer 162. The conductive layer 164 preferably contains one or two or more selected from a metal and the like described for the conductive layer 161.

A stack of the conductive layer 161, the conductive layer 162, and the conductive layer 164 can correspond to the lower electrodes 111R, 111G, and 111B. In this embodiment, the term lower electrode 1 II is used in the description of the components common to the lower electrodes 111R, 111G, and 111B.

The lower electrode 111 functions as an anode or a cathode. Since the conductive layer 164 is positioned in the uppermost layer of the lower electrode 111, a specific material that can be used for the conductive layer 164 is preferably determined considering the work function.

Alternatively, a stack of the conductive layer 161, the conductive layer 162, and the conductive layer 164 can correspond to the second wiring layer 151b.

After that, a resist mask is formed over the three conductive films by a photolithography method, and unnecessary portions of the conductive films are removed by etching. Then, the resist mask is removed, whereby the conductive layer 161, the conductive layer 162, and the conductive layer 164 can be formed using the same resist mask in the same etching step. Owing to the resin layer 163 or the like, the conductive layer 164 can have a flat top surface.

Although the conductive layer 161 and the conductive layer 162 are formed using the same resist mask in the same etching step here, the conductive layer 161 and the conductive layer 162 may be separately processed using different resist masks. In that case, the conductive layer 161 and the conductive layer 162 are preferably processed such that the conductive layer 162 is positioned inward from the outline of the conductive layer 161 in a top view.

Although the conductive layer 162, the conductive layer 164, and the like are formed using the same resist mask in the same etching step, the conductive layer 162, the conductive layer 164, and the like may be separately processed using different resist masks. In that case, the conductive layer 162, the conductive layer 164, and the like are preferably processed such that the conductive layer 164 is positioned inward from the outlines of the conductive layer 162 and the like in a top view.

[Formation of Organic Compound Film 112fR]

As illustrated in FIG. 19B, an organic compound film that can emit red, green, or blue light is formed to cover the conductive layer 164. In this embodiment, for example, an organic compound film 112fR that can emit red light is formed.

The organic compound film 112fR has a stack including the functional layers of the light-emitting devices, and the functional layers are sequentially formed in accordance with the light-emitting device 550R illustrated in FIG. 14B described above in Embodiment 4, for example. Note that the layer 525 is not formed here and later formed. The organic compound film 112fR also includes the charge-generation layer. Note that the charge-generation layer is processed by etching or the like later; thus, a material that contains neither an alkali metal nor an alkaline earth metal may be used.

The functional layers included in the organic compound film 112fR can be formed by an evaporation method (including vacuum evaporation); without limitation thereto, the functional layers included in the organic compound film 112fR can also be formed by a sputtering method, an ink-jet method, or the like.

As already described above, in this embodiment, the electron-injection layer is a common layer and thus is not included in the organic compound film 112fR but is formed later. As the common layer, any layer can be selected as long as it is a functional layer positioned between the light-emitting layer and the common electrode. Needless to say, all the functional layers may be divided for each subpixel without providing the common layer, as illustrated in FIG. 14A described in Embodiment 4.

Since the electron-injection layer is not included in the organic compound film 112fR, an electron-transport layer is positioned in the uppermost layer of the organic compound film 112fR. The electron-transport layer is exposed to a processing process using a photolithography method, which is a later step. Thus, a material having high heat resistance is preferably used for the electron-transport layer. As the material having high heat resistance, a material whose glass transition point is higher than or equal to 110° C. and lower than or equal to 165° C., preferably higher than or equal to 120° C. and lower than or equal to 135° C. is preferably used, for example.

The electron-transport layer exposed to the processing may have a stacked-layer structure. An example of the stacked-layer structure is a structure in which a second electron-transport layer is stacked over a first electron-transport layer. The processing includes a period in which the first electron-transport layer is covered with the second electron-transport layer; accordingly, the first electron-transport layer may have lower heat resistance than the second electron-transport layer. For example, a material with a glass transition point higher than or equal to 110° C. and lower than or equal to 165° C., preferably higher than or equal to 120° C. and lower than or equal to 135° C. can be used for the second electron-transport layer, and a material with a glass transition point lower than that of the second electron-transport layer, for example, higher than or equal to 100° C. and lower than or equal to 155° C., preferably higher than or equal to 110° C. and lower than or equal to 125° C. can be used for the first electron-transport layer.

Since the electron-transport laver can be the common layer, the light-emitting layer can be regarded as the uppermost layer of the organic compound film 112fR; however, damage to the light-emitting layer caused by the processing might significantly degrade the reliability. Thus, in the fabrication of the display device of one embodiment of the present invention, the processing is preferably performed after the functional layer (e.g., the electron-transport layer) is formed above the light-emitting layer.

### [Formation of Mask Film 144R]

Furthermore, a mask layer or the like is preferably formed over the organic compound film 112fR. The mask layer can inhibit damage to the light-emitting layer caused by processing. This method can provide a highly reliable display panel. Note that in this specification and the like, the mask layer is positioned above the organic compound film and has a function of protecting the organic compound film in the manufacturing process. Thus, as illustrated in FIG. 19C, a mask film 144R is formed to cover the organic compound film 112fR.

As the mask film 144R, a film having high etching selectivity with respect to the organic compound film 112fR is preferably used during the etching treatment of the organic compound film 12fR. The mask film 144R is in a stacked-layer structure in some cases; a film having high etching selectivity with respect to a mask film in the upper layer described later (specifically, a mask film 146R) or the like is preferably used as the mask film 144R. Furthermore, at the time of removing the mask film 144R, it is preferable to use a film that can be removed by a wet etching method that is less likely to cause damage to the organic compound film 112fR.

The mask film 144R can be formed by any of a variety of deposition methods such as a sputtering method, an evaporation method, a CVD method, and an ALD method. Specifically, the mask film 144R, which is directly formed on the organic film 112fR, is preferably formed by an ALD method that gives less deposition damage to a formation layer.

As the mask film 144R, an inorganic film such as a metal film, an alloy film, a metal oxide film, a semiconductor film, or an inorganic insulating film can be suitably used, for example. As the inorganic film, an insulating film containing an inorganic material or an organic material or the like is given.

For the mask film 144R, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

Alternatively, a metal oxide such as an indium-gallium-zinc oxide (also referred to as an In—Ga—Zn oxide or IGZO) can be used for the mask film 144R. It is also possible to use an indium oxide, an indium zinc oxide (an In—Zn oxide), an indium tin oxide (an In—Sn oxide), an indium titanium oxide (an In—Ti oxide), an indium tin zinc oxide (an In—Sn—Zn oxide), an indium titanium zinc oxide (an In—Ti—Zn oxide), an indium gallium tin zinc oxide (an In—Ga—Sn—Zn oxide), or the like. Alternatively, an indium tin oxide containing silicon, or the like can be used.

Note that the element M (M is one or more selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) can be used instead of gallium. Specifically, M is preferably one or more kinds selected from gallium, aluminum, and yttrium.

The mask film 144R may contain an inorganic material. As the inorganic material, an oxide such as aluminum oxide, hafnium oxide, or silicon oxide, a nitride such as silicon nitride or aluminum nitride, or an oxynitride such as silicon oxynitride can be used. Such an inorganic material can be formed by a deposition method such as a sputtering method, a CVD method, or an ALD method.

The mask film 144R may contain an organic material. As the organic material, for example, a material that can be dissolved in a solvent chemically stable with respect to the organic compound film 112fR may be used. In particular, a material that is dissolved in water or alcohol can be suitably used for the mask film 144R. In formation of the mask film 144R, it is preferable that application of such a material that has been dissolved in a solvent such as water or alcohol be performed by a wet formation method and followed by heat treatment for evaporating the solvent. At this time, the heat treatment is preferably performed in a reduced-pressure atmosphere, in which case the solvent can be removed at a low temperature in a short time and thermal damage to the functional layer such as the light-emitting layer can be reduced accordingly.

A wet formation method can be used to form the mask film 144R.

For the mask film 144R an organic resin such as polyvinyl alcohol (PVA), polyvinyl butyral, polyvinylpyrrolidone, polyethylene glycol, polyglycerin, pullulan, water-soluble cellulose, or an alcohol-soluble polyamide resin can be used. For the mask film 144R, a fluorine resin such as a perfluoropolymer may be used.

### [Formation of Mask Film 146R]

As illustrated in FIG. 19C, the mask film 146R is formed over the mask film 144R. Although a stacked-layer structure of mask films is employed in this embodiment, the organic compound film 112fR can be protected using only either the mask film 144R or the mask film 146R as a single mask film.

The mask film 146R is preferably used as a hard mask when the mask film 144R is etched later. After the mask film 146R is processed, the mask film 144R is exposed. Thus, in the case where the mask film 146R is used as a hard mask, the combination of films having high etching selectivity therebetween is preferably selected for the mask film 144R and the mask film 146R.

A material of the mask film 146R can be selected from a variety of materials depending on an etching condition of the mask film 144R and an etching condition of the mask film 146R. For example, any of the films that can be used as the mask film 144R can be selected, or a material different from the material for the mask film 144R can be selected.

For example, an oxide film or an oxynitride film can be used as the mask film 146R. Typical examples of the oxide film and the oxynitride film include silicon oxide, silicon oxynitride, aluminum oxide, aluminum oxynitride, hafnium oxide, and hafnium oxynitride.

As the mask film 146R, a nitride film can be used, for example. Typical examples of the nitride film include silicon nitride, aluminum nitride, hafnium nitride, titanium nitride, tantalum nitride, tungsten nitride, gallium nitride, and germanium nitride.

For the combination of the mask film 144R and the mask film 146R, for example, it is possible to use an inorganic material such as aluminum oxide, hafnium oxide, or silicon oxide formed by an ALD method for the mask film 144R and to use a metal oxide containing indium, such as an indium gallium zinc oxide (also referred to as an In—Ga—Zn oxide or IGZO), formed by a sputtering method for the mask film 146R.

Alternatively, for the mask film 146R combined with the mask film 144R, one or two or more metals selected from tungsten, molybdenum, copper, aluminum, titanium, tantalum, and the like or an alloy containing any of the metals can be used. In the case where the mask film 146R is formed as a hard mask, the above metal or alloy is preferably used. In the case where the mask film 146R is formed as a hard mask, the thickness of the mask film 146R is preferably larger than that of the mask film 144R.

### [Formation of Resist Mask 143R]

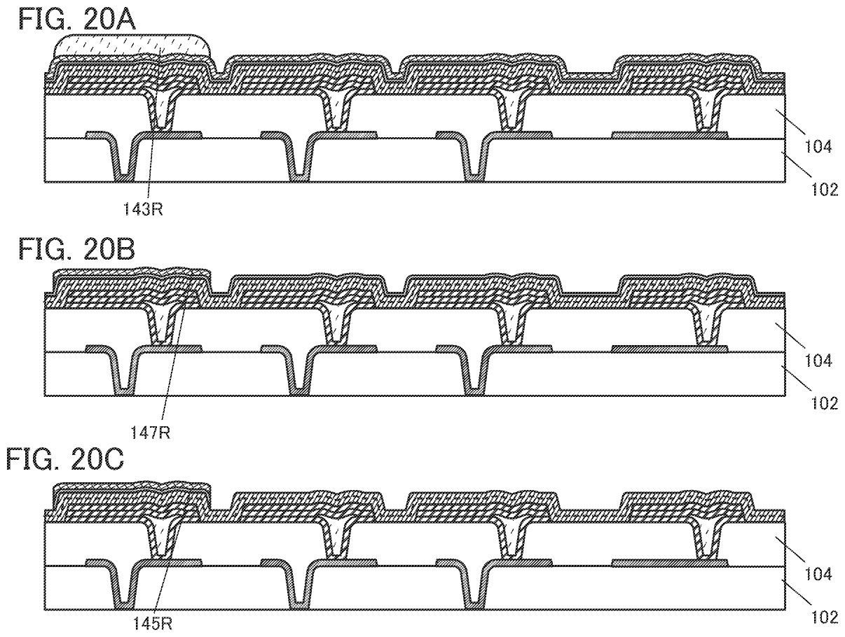

As illustrated in FIG. 20A, a resist mask 143R is formed in a position that is over the mask film 146R and overlaps with the conductive layer 164. In that case, the resist mask is not formed in a position overlapping with the auxiliary wiring 151.

For the resist mask 143R, a resist material containing a photosensitive resin, such as a positive type resist material or a negative type resist material, can be used.

The organic compound film 112fR or the like might be dissolved in the case where a material that dissolves the organic compound film 112R is used for a solvent of the resist material, the mask film 146R is not provided, and defects such as pinholes exist in the mask film 144R. In that case, the mask film 146R positioned over the mask film 144R at the time of formation of the resist mask 143R can prevent such defects.

In the case where a material that does not dissolve the organic compound film 112fR is used for the solvent of the resist material, the resist mask 143R may be formed directly on the mask film 144R without providing the mask film 146R.

### [Etching of Mask Film 146R]

As illustrated in FIG. 20B, part of the mask film 146R that is not covered with the resist mask 143R is removed by etching, so that a mask layer 147R is formed.

In the etching of the mask film 146R, an etching condition with high selectivity is preferably employed so that the mask film 144R is not removed by the etching. The etching of the mask film 146R can be performed by wet etching or dry etching.

### [Removal of Resist Mask 143R]

The resist mask 143R is removed as illustrated in FIG. 20B. The resist mask 143R can be removed by wet etching or dry etching. It is particularly preferable to perform dry etching (also referred to as plasma ashing) using an oxygen gas as an etching gas to remove the resist mask 143R.

The resist mask 143R is removed in a state where the organic compound film 112fR is covered with the mask film 144R; thus, damage to the organic compound film 112fR caused by the processing is inhibited. In particular, when the organic compound film 12fR is exposed to oxygen, the characteristics thereof might be adversely affected; accordingly, the organic compound film 112fR is preferably covered with the mask film 144R in the case where etching using the above oxygen gas is performed. Even in the case where the resist mask 143R is removed by wet etching, the organic compound film 112fR can be prevented from being dissolved because the organic compound film 112fR is not exposed to a chemical solution.

### [Etching of Mask Film 144R]

As illustrated in FIG. 20C, part of the mask film 144R is removed by etching using the mask layer 147R as a hard mask, so that a mask layer 145R is formed.

The etching of the mask film 144R can be performed by wet etching or dry etching.

[Etching of Organic Compound Film 112fR]

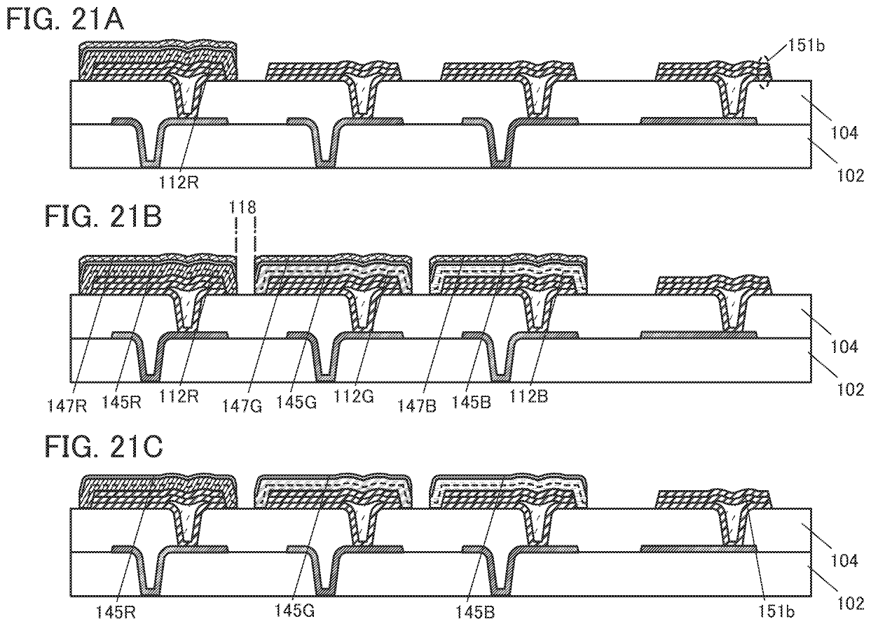

As illustrated in FIG. 21A, part of the organic compound film 112fR that is not covered with the mask layer 145 is removed by etching, whereby the organic compound layer 112R is formed.

For the etching of the organic compound film 112fR, it is preferable to use dry etching using an etching gas that does not contain oxygen as its main component. This is because, as described above, the exposure of the organic compound film 112fR to oxygen adversely affects characteristics in some cases. Specifically, the organic compound film 112fR may be changed in quality; however, using an etching gas that does not contain oxygen as its main component can inhibit the change, whereby a highly reliable display device can be achieved. Examples of the etching gas that does not contain oxygen as its main component include CF₄, C₄F₈, SF₆, CHF₃, Cl₂, H₂O, BCl₃, H₂, and a rare gas such as He. Alternatively, a mixed gas of the above gas and a dilution gas that does not contain oxygen may be used as the etching gas.

Note that the etching of the organic compound film 112fR is not limited to the above and may be performed by dry etching using another gas or wet etching.

When dry etching using, as an etching gas, an oxygen gas or a mixed gas containing an oxygen gas is used for the etching of the organic compound film 112fR, the etching rate can be increased. Consequently, etching under a low-power condition can be performed while the etching rate is kept adequately high; hence, damage due to the etching can be reduced. Furthermore, a defect such as attachment of a reaction product generated in the etching can be inhibited. For example, a mixed gas obtained by adding an oxygen gas to the etching gas that does not contain oxygen as its main component can be used as the etching gas.

After the etching, the taper angle of the end surface of the organic compound layer 112R is preferably greater than or equal to 450 and less than 90°.

[Formation to Etching of Green Organic Compound Film 112fG]

As illustrated in FIG. 21B, the organic compound layer 112G is formed using a mask layer 145G and a mask layer 147G with reference to the formation to etching of the organic compound film 112fR. The organic compound layer 112G is an organic compound layer for the green-light-emitting device.

[Formation to Etching of Blue Organic Compound Film 112fB]

As illustrated in FIG. 21B, the organic compound layer 112B is formed using a mask laver 145B and a mask layer 147B with reference to the formation to etching of the organic compound film 112fR. The organic compound layer 112B is an organic compound layer for the blue-light-emitting device.

An organic compound film is not provided over the second wiring layer 151b, and the second wiring layer 151b is exposed. Specifically, the conductive layer 164, which is the uppermost layer of the second wiring layer 151b, is exposed.

The term organic compound layer 112 is used when the organic compound layers 112R, 112G, and 112B do not need to be distinguished from each other. Slits 118 are formed between the organic compound layers 112R, 112G, and 112B. That is, the width of the slit 118 which is indicated by the arrow in FIG. 21B and is between the organic compound layers 112 obtained through a processing step using a photolithography method can be less than or equal to 8 μm, less than or equal to 3 μm, less than or equal to 2 μm, or less than or equal to 1 μm. The width of the slit 118 corresponds to the distance between the subpixels and can be found by measurement of the distance between the lower ends of the organic compound layers 112. The distance between the subpixels is shortened in this manner, whereby a display device with high resolution and a high aperture ratio can be provided.

The adjacent organic compound layers 112 are apart or separated from each other as shown by the slit 118, which makes it possible to divide a leakage current path and accordingly inhibit leakage current (also referred to as side leakage or side leakage current). Accordingly, a higher luminance, a higher contrast, higher display quality, higher power efficiency, lower power consumption, or the like can be achieved in the light-emitting device.

The end surfaces of the adjacent organic compound layers 112 preferably face each other with the slit 118 therebetween. Note that the end surfaces of organic compound layers formed using a metal mask cannot face each other. The end surfaces facing each other are clearly different from the end surfaces of the organic compound layers formed using a metal mask.

The insulating layer 104 is exposed when the organic compound film is etched. Thus, a depressed portion is sometimes formed in the insulating layer 104 in a region overlapping with the slit 118. Note that in the case where formation of the depressed portion is not desired, a film highly resistant to etching of the organic compound film is preferably used as the insulating layer 104. For example, an insulating film containing an inorganic material is preferably used as the insulating layer 104.

### |Removal of Mask Layer|

As illustrated in FIG. 21C, the mask layers 147R, 147G, and 147B are removed, and the top surfaces of the mask layers 145R. 145G, and 145B are exposed.

[Formation of Insulating Layer 125f]

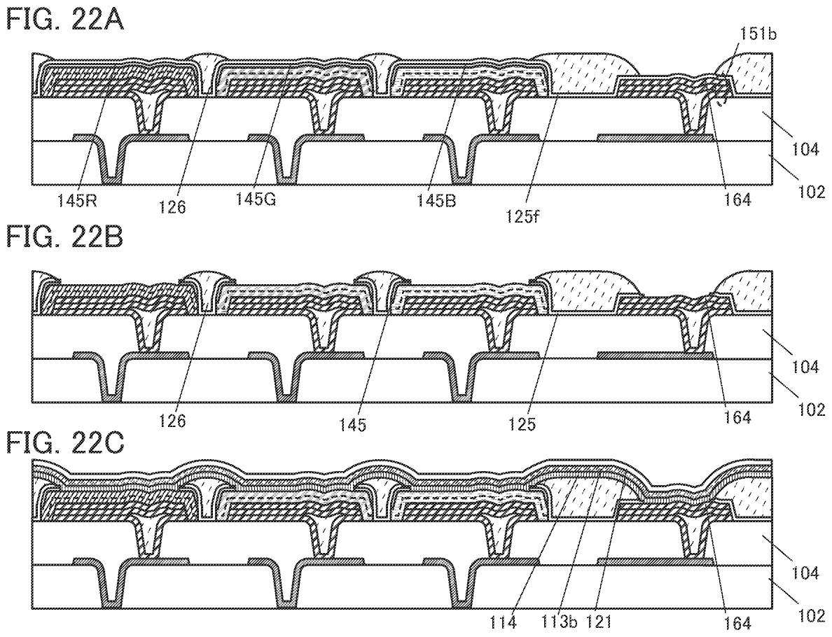

As illustrated in FIG. 22A, an insulating layer 125f is formed to cover the mask layers 145R, 145G, and 145B and the second wiring layer 151b.

The insulating layer 125f functions as a barrier layer that prevents diffusion of impurities such as water into the organic compound layer 112. The insulating layer 125f is preferably formed by an ALD method with excellent step coverage so as to suitably cover the side surface of the organic compound layer 112.

The same film as the mask layers 145R, 145G, and 145B and the mask layers 147R, 145G, and 145B are preferably used as the insulating layer 125f, in which case simultaneous removal is easily performed in etching treatment in a later step. For example, one or two or more inorganic materials selected from aluminum oxide, hafnium oxide, silicon oxide, and the like, which is formed by an ALD method, is preferably used for the insulating layer 125f, the mask layers 145R. 145G, and 145B, and the mask layers 147R, 145G, and 145B.

Note that the materials that can be used for the insulating layer 125f are not limited thereto. For example, any of the materials that can be used for the mask layers 145R. 145G, and 145B can be used as appropriate.

### [Formation of Insulating Layer 126]

As illustrated in FIG. 22A, the insulating layer 126 is formed in a region overlapping with the slit 118, for example. The insulating layer 126 can be formed by a method similar to that for the resin layer 163. For example, a photosensitive resin is formed, and then light exposure and development are performed, whereby the insulating layer 126 can be formed. The insulating layer 126 may be formed in the following manner: a resin is formed on the entire surface, and then part of the resin is etched by ashing or the like.

Here, a structure is illustrated in which the insulating layer 126 has a larger width than the slit 118. In addition, an opening is provided in a region of the insulating layer 126 which overlaps with part of the top surface of the second wiring layer 151b.

### [Etching of Insulating Layer 125f and Mask Layer 145]

As illustrated in FIG. 22B, portions of the insulating layer 125f and the mask layers 145R, 145G, and 145B that are not covered with the insulating layer 126 are removed by etching, so that part of the top surface of the organic compound layer 112 is exposed. The insulating layer 125 and part of the mask layers 145R, 145G, and 145B (denoted as 145 in the drawing) remain in a region overlapping with the insulating layer 126. It is preferable that the center portion of the insulating layer 126 be positioned above the end portion of the insulating layer 126 and that the center portion include a region rising above the end portion. The center portion of the insulating layer 126 is preferably positioned above the top surface of the organic compound layer 112. Furthermore, the end portion of the insulating layer 126 preferably has a tapered shape.

The insulating layer 125f and the mask layers 145R, 145G, and 145B are preferably etched in the same step. It is particularly preferable that the etching of the mask layers 145R, 145G, and 145B be performed by wet etching that gives less etching damage to the organic compound layer 112. For example, it is preferable to employ wet etching using a tetramethyl ammonium hydroxide (TMAH) aqueous solution, diluted hydrofluoric acid, oxalic acid, phosphoric acid, acetic acid, nitric acid, or a mixed solution thereof. In the case of employing a wet etching method, a mixed acid chemical solution containing water, phosphoric acid, diluted hydrofluoric acid, and nitric acid may be used. A chemical solution used for the wet etching treatment may be alkaline or acid.

At least one of the insulating layer 125f and the mask layers 145R, 145G, and 145B are preferably removed by being dissolved in a solvent such as water or alcohol. As the alcohol in which the insulating layer 125f and the mask layers 145R, 145G, and 145B can be dissolved, any of various alcohols such as ethyl alcohol, methyl alcohol, isopropyl alcohol (IPA), and glycerin can be used.

After the insulating layer 125f and the mask layers 145R, 145G, and 145B are removed, drying treatment is preferably performed to remove water contained in the organic compound layer 112 or the like and water adsorbed on the surface thereof. For example, heat treatment is preferably performed in an inert gas atmosphere or a reduced-pressure atmosphere. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. Employing a reduced-pressure atmosphere is preferable, in which case drying at a lower temperature is possible.

Part of the top surface of the second wiring layer 151b is exposed by the removal of part of the insulating layer 125f.

### [Formation of Common Layer 114]

As illustrated in FIG. 22C, the common layer 114 is formed to cover the organic compound layer 112, the insulating layer 125, the mask layer 145, the insulating layer 126, and the like.

For the common layer 114, any of the above-described materials that can be used for the electron-injection layer can be used; for example, an alkali metal, an alkaline earth metal, or a compound thereof can be used.

The common layer 114 can be formed by a method similar to that for the organic compound film 112fR or the like, and is preferably formed by evaporation.

[Formation of Common Electrode 113b]

As illustrated in FIG. 22C, the common electrode 113b is formed to cover the common layer 114.

The common electrode 113b can be formed by a deposition method such as an evaporation method or a sputtering method. Alternatively, a film formed by an evaporation method and a film formed by a sputtering method may be stacked.

The common electrode 113b is preferably formed to cover a region where the common layer 114 is formed.

In this embodiment, the common layer 114 is positioned between the conductive layer 164 included in the second wiring layer 151b and the common electrode 113b. In the case where the common layer 114 is positioned, a material with low electric resistance is preferably used for the common layer 114. Alternatively, it is preferable to form the common layer 114 thin, in which case the electric resistance of the common laver 114 in the thickness direction can be reduced. For example, an electron-injection or hole-injection material with a thickness greater than or equal to 1 nm and less than or equal to 5 nm, preferably greater than or equal to 1 nm and less than or equal to 3 nm is used for the common layer 114, whereby electric resistance between the conductive layer 164 and the common electrode 113b can be made small enough to be negligible.

Note that in the present invention, the common layer 114 is not necessarily positioned between the second wiring layer 151b and the common electrode 113b. In that case, the common layer 114 is formed to cover a region other than the light-emitting device. Alternatively, the common layer 114 in a region of the auxiliary wiring is removed from the common layer 114 formed in a region of the light-emitting device and the auxiliary wiring.

### [Formation of Protective Layer]

As illustrated in FIG. 22C, the protective layer 121 is formed over the common electrode 113b. An inorganic insulating film used as the protective layer 121 is preferably formed by a sputtering method, a PECVD method, or an ALD method. In particular, an ALD method is preferable because it provides excellent step coverage and is unlikely to cause a defect such as a pinhole. In addition, an organic insulating film is preferably formed by an ink-jet method, in which case a uniform film can be formed in a desired area.

### [Formation of Counter Substrate]

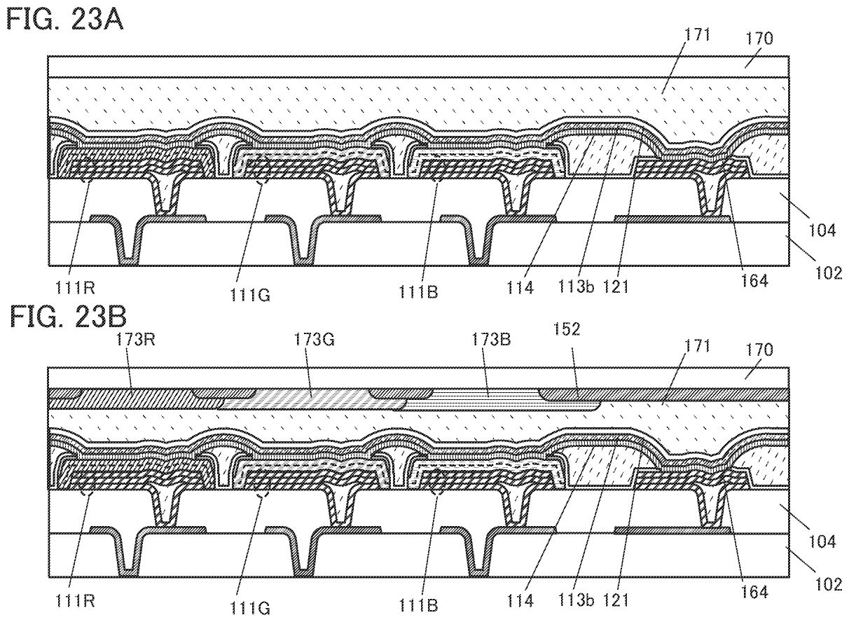

As illustrated in FIG. 23A, the substrate 170 is bonded with the adhesive layer 171. In the case where the display device has a hollow sealing structure, the substrate 170 is preferably bonded with a sealant or the like. Although a space is generated when the substrate is bonded with the sealant, the space is preferably filled with an inert gas (a gas containing nitrogen or argon).

For the adhesive layer 171, an organic material such as a reactive curable adhesive, a photocurable adhesive, a thermosetting adhesive, or/and an anaerobic adhesive can be used, for example.

Specifically, an adhesive containing an epoxy resin, an acrylic resin, a silicone resin, a phenol resin, a polyimide resin, an imide resin, a PVC (polyvinyl chloride) resin, a PVB (polyvinyl butyral) resin, an EVA (ethylene vinyl acetate) resin, or the like can be used for the adhesive layer 171 or the like.

As illustrated in FIG. 23B, the substrate 170 may be provided with the light-blocking layer 149 and the color filters 148R, 148G, and 148B. The light-blocking layer 149 is provided in a region overlapping with the insulating layer 126. The substrate 170 is preferably bonded such that the color filters 148R, 148G, and 148B overlap with the lower electrodes 111R, 111G, and 111B.

The color filters 148R, 148G, and 148B may be provided over the protective layer 121 instead of over the substrate 170.

The color filters 148R, 148G, and 148B can be formed at desired positions through etching treatment or the like using an ink-jet method or a photolithography method.

Light emitted toward the common electrode 113b side is colored resulting from absorption of light in a predetermined wavelength range by the color filters 148R, 148G, and 148B and the colored light exits through the substrate 170, enabling full color display.

### [Fabrication Method Example 2]

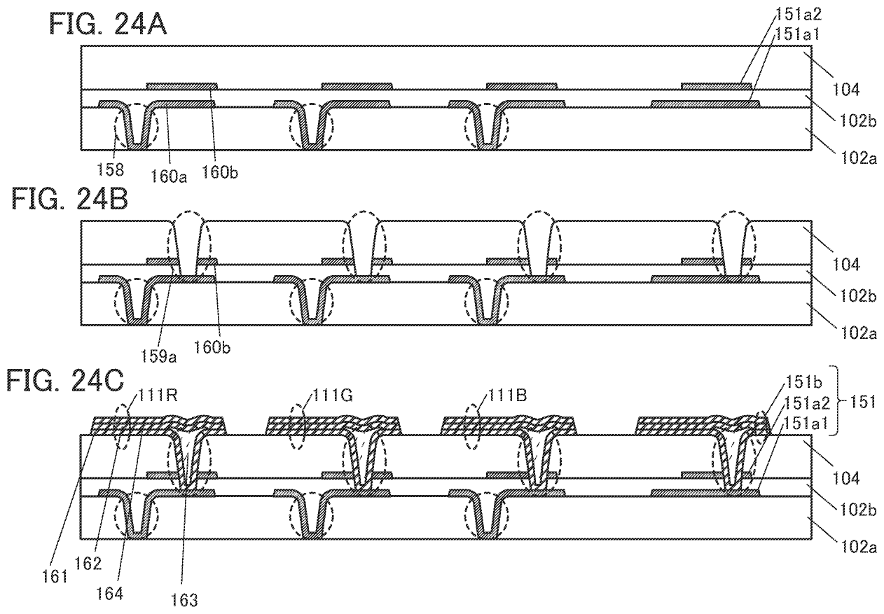

An example of a method for fabricating the display device, which is different from the above-described one, will be described with reference to FIG. 24A to FIG. 24C and the like. In the drawings, a region related to the pixel 150 is illustrated on the left side, and a region on the auxiliary wiring 151 is illustrated on the right side.

A substrate is prepared as in Fabrication method example 1, and an insulating layer 102a is formed as illustrated in FIG. 24A. The insulating layer 102a can be formed using a material and the like similar to those for the insulating layer 102 in Fabrication method example 1. Next, the contact hole 158 is formed in the insulating layer 102a as in Fabrication method example 1, and a conductive layer 160a is formed in the contact hole 158. The conductive layer 160a can be formed using a material and the like similar to those for the conductive layer 160 in Fabrication method example 1. The conductive layer 160a can correspond to a first wiring layer 151a1 included in the auxiliary wiring.

The conductive layer 160a has a shape along the shape of the contact hole 158 and thus has a depressed portion in a region overlapping with the contact hole 158.

Next, an insulating layer 102b is formed. For the insulating layer 102b, a material that can fill the depressed portion is preferably used. Thus, the insulating layer 102b is preferably formed using the organic material among the materials for the insulating layer 102 described in Fabrication method example 1.

Next, a conductive layer 160b is formed over the insulating layer 102b. The conductive layer 160a can be formed using a material and the like similar to those for the conductive layer 160 in Fabrication method example 1. The conductive layer 160b is formed to overlap with the conductive layer 160a. The conductive layer 160b can correspond to a first wiring layer 151a2 included in the auxiliary wiring.

As illustrated in FIG. 24B, the insulating layer 104 is formed. The insulating layer 104 can be formed using a material and the like similar to those for the insulating layer 104 in Fabrication method example 1.

Next, a contact hole 159a is formed in the insulating layer 104, the conductive layer 160b, and the insulating layer 102b. The contact hole 159a provided in a plurality of materials is sometimes referred to as a through contact or a through contact hole. The contact hole 159a can be formed in a manner similar to that of the contact hole 159 in Fabrication method example 1. The contact hole 159a is preferably formed by dry etching, in which case the sidewall surface of the contact hole 159a can be processed uniformly. Examples of the etching gas include CF₄, C₄F₈, SF₆, CHF₃, Cl₂, H₂O, BCl₃, H₂, and a rare gas such as He.

As illustrated in FIG. 24C, the conductive layer 161 is formed in the contact hole 159a The conductive layer 161 can be formed using a material and the like similar to those for the conductive layer 161 in Fabrication method example 1. The conductive layer 161 includes a region in contact with the side surface of the conductive layer 160b to obtain electrical connection. Such a structure is sometimes referred to as a side contact.

The conductive layer 161 has a shape along the shape of the contact hole 159a and thus has a depressed portion in a region overlapping with the contact hole 159a.

Next, the resin layer 163 is formed. For the resin layer 163, a material that can fill the depressed portion is preferably used. The resin layer 163 is preferably formed using any of the materials for the resin layer 163 described in Fabrication method example 1.

Next, the conductive layer 162 is formed. The conductive layer 162 can be formed using a material and the like similar to those for the conductive layer 162 in Fabrication method example 1.

After that, the conductive layer 164 is formed. The conductive layer 164 can be formed using a material and the like similar to those for the conductive layer 164 in Fabrication method example 1. Through the above steps, the lower electrodes 111R, 111G, and 111B and the auxiliary wiring 151 each having a stacked-layer structure of the conductive layer 164, the conductive layer 162, and the conductive layer 161 can be formed. The auxiliary wiring 151 in this embodiment is preferred in having a multilayered structure.

After such a structure is obtained, steps from the formation of the organic compound film and the like to bonding of the counter substrate are performed as in Fabrication method example 1, whereby the display device can be fabricated.

The through contact is preferably formed as in Fabrication method 2, in which case formation of a plurality of contact holes overlapping with one another without misalignment is possible and thus an aperture ratio can be kept high.

### Fabrication Method Example 3

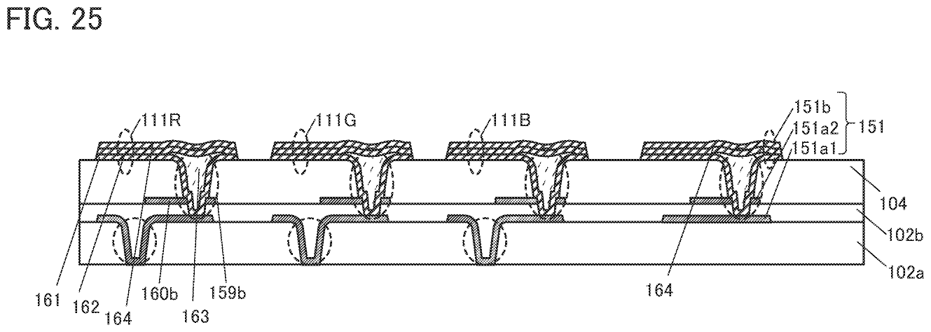

An example of a method for fabricating the display device, which is different from the above-described one, will be described with reference to FIG. 25 and the like. In drawings, a region related to the pixel 150 is illustrated on the left side, and a region on the auxiliary wiring 151 is illustrated on the right side.

A substrate is prepared as in Fabrication method examples 1 and 2, and the components up to the insulating layer 104 are formed as illustrated in FIG. 25 in a manner similar to that of Fabrication method 2. A contact hole 159b is formed in the insulating layer 104. The contact hole 159b is also sometimes referred to as a through contact or a through contact hole.

In the case where the contact hole 159b is divided into the upper and lower contact holes with the conductive layer 160b as a boundary, the contact hole 159b is formed such that the diameter of the contact hole formed above the conductive layer 160b is larger than the diameter of the lower contact hole including the contact hole formed in the conductive layer 160b. Like the contact hole 159a, the contact hole 159b is preferably formed by dry etching. Examples of the etching gas include CF₄, C₄F₈, SF₆, CHF₃, Cl₂, H₂O, BCl₃, H₂, and a rare gas such as He.

As illustrated in FIG. 25, the conductive layer 161 is formed in the contact hole 159b. The conductive layer 161 can be formed using a material and the like similar to those for the conductive layer 161 in Fabrication method example 1. The conductive layer 161 includes a region in contact with the side surface and the top surface of the conductive layer 160b to obtain electrical connection. Such a structure in contact with a side surface is sometimes referred to as a side contact.

After that, the resin layer 163, the conductive layer 161, the conductive layer 162, and the conductive layer 164 are formed as in Fabrication method 2. Through the above steps, the lower electrodes 111R, 111G, and 111B and the auxiliary wiring 151 each having a stacked-layer structure of the conductive layer 164, the conductive layer 162, and the conductive layer 161 can be formed. The auxiliary wiring 151 in this embodiment is preferred in having a multilayered structure.

After such a structure is obtained, steps from the formation of the organic compound film and the like to bonding of the counter substrate are performed as in Fabrication method example 1, whereby the display device can be fabricated.

The through contact including the contact holes with different diameters is preferably formed as in Fabrication method 3, in which case the surface where the conductive layers are in contact with each other, i.e., the contact surface, in the through electrode can be larger as well as an aperture ratio can be kept high.

### Fabrication Method Example 4

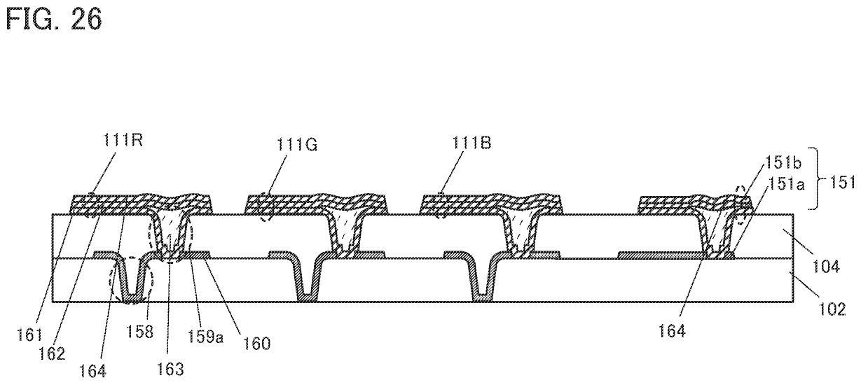

An example of a method for fabricating the display device, which is different from the above-described one, will be described with reference to FIG. 26 and the like. In drawings, a region related to the pixel 150 is illustrated on the left side, and a region on the auxiliary wiring 151 is illustrated on the right side.

A substrate is prepared as in Fabrication method examples 1 to 3. As in Manufacturing method example 1 above, the insulating layer 102 is formed and the contact hole 158 is formed, as illustrated in FIG. 26. Then, as in Manufacturing method example 1 above, the conductive layer 160 is formed in the contact hole 158.

Next, as in Manufacturing method example 1, the insulating layer 104 is formed over the conductive layer 160. When formed in the insulating layer 104, the contact hole 159a is the above-described through contact or a through contact hole in Manufacturing method examples 2 and 3.

Next, as in Manufacturing method example 1 above, the conductive layer 161 is formed in the contact hole 159a. The conductive layer 161 can be in contact with a side surface and a top surface of the conductive layer 160. After that, the resin layer 163, the conductive layer 162, and the conductive layer 164 are formed as in Fabrication method example 1 above. Through the above steps, the lower electrodes 111R, 111G, and 11I B and the auxiliary wiring 151 each having a stacked-layer structure of the conductive layer 164, the conductive layer 162, and the conductive layer 161 can be formed. The auxiliary wiring 151 in this embodiment is preferred in having a multilayered structure.

After such a structure is obtained, steps from the formation of the organic compound film and the like to bonding of the counter substrate are performed as in Fabrication method example 1, whereby the display device can be fabricated.

The through contact is preferably formed as in Fabrication method 4, in which case an aperture ratio can be kept high.

In the above manner, the display device can be fabricated.

This embodiment can be combined with any of the other embodiments as appropriate. In the case where a plurality of structure examples are described in one embodiment in this specification, the structure examples can be combined as appropriate.

### Embodiment 9

In this embodiment, a display device of one embodiment of the present invention will be described with reference to drawings.

### [Specific Example of Display Device]

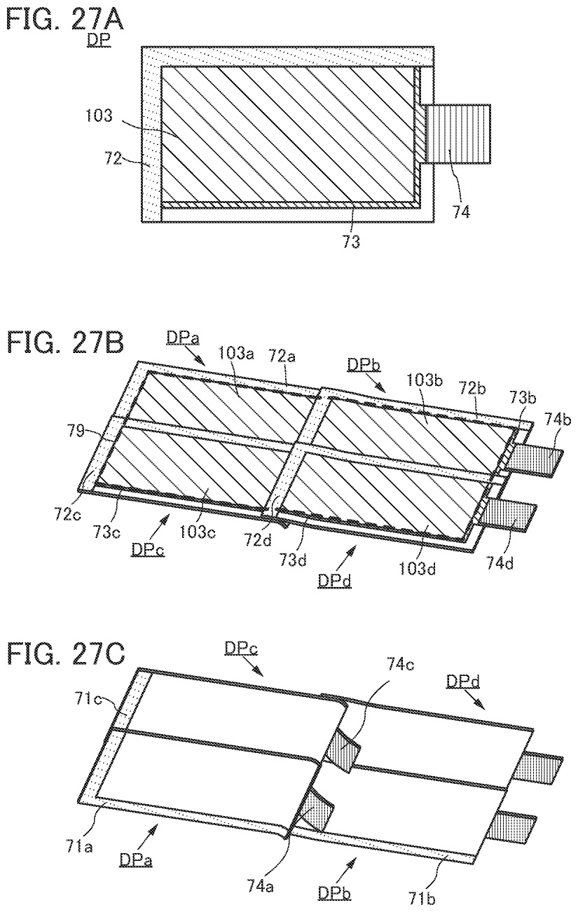

One embodiment of the display device described in the above embodiment is a display module DP provided with an FPC 74. A large display device using a plurality of the display modules DP will be described with reference to FIG. 27.

FIG. 27A is a top view of the display module DP. The display module DP includes a visible-light-transmitting region 72 and a visible-light-blocking region 73 that are adjacent to the pixel portion 103.

FIG. 27B and FIG. 27C are perspective views of a display device including four display modules DP. When a plurality of display modules DP are arranged in one or more directions (e.g., in one column or in a matrix), a large display device with a large display region can be fabricated.

In the case where a large display device is fabricated using the plurality of display modules DP, each of the display modules DP is not required to be large. Thus, a manufacturing apparatus for fabricating the display modules DP does not need to be increased in size, whereby space-saving can be achieved. Furthermore, since a manufacturing apparatus for small- and medium-sized display panels can be used and a novel manufacturing apparatus does not need to be utilized for a larger display device, manufacturing cost can be reduced. In addition, a decrease in yield caused by an increase in the size of the display modules DP can be inhibited.

A non-display region where wirings and the like are led is positioned in the periphery of the pixel portion 103. The non-display region corresponds to the visible-light-blocking region 73. When the plurality of display modules DP overlap with one another, one image is sometimes perceived as images separated by the non-display region or the like.

Thus, in one embodiment of the present invention, the visible-light-transmitting region 72 is provided in the display module DP, and in two display modules overlapping with each other, the pixel portion 103 of the display module DP placed on the lower side and the visible-light-transmitting region 72 of the display module DP placed on the upper side overlap with each other.

The visible-light-transmitting region 72 provided in this manner eliminates the need for actively downsizing the non-display region in the display module DP. Note that two display modules DP overlapping with each other are preferable because of the downsized non-display region. As a result, a large display device in which a seam between the display modules DP is hardly seen by a user can be obtained.

In the display module DP positioned on the upper side, the visible-light-transmitting region 72 may be provided in at least part of the non-display region. The visible-light-transmitting region 72 can overlap with the pixel portion 103 of the display module DP positioned on the lower side.

Furthermore, at least part of the non-display region of the display module DP positioned on the lower side overlaps with the pixel portion 103 or the visible-light-blocking region 73 of the display module DP positioned on the upper side.

The non-display region of the display module DP is preferably large because an increase in the distance between the end portion of the display module DP and an element in the display module DP can inhibit the deterioration of the element due to impurities entering from the outside of the display module DP.

In the case where the plurality of display modules DP are provided in the display device as described above, the pixel portion 103 is continuous between the adjacent display modules DP; thus, a display region with a large area can be provided.

The pixel portion 103 includes a plurality of pixels.

In the visible-light-transmitting region 72, a pair of substrates that constitute the display module DP, a resin material for sealing a display element sandwiched between the pair of substrates, and the like may be provided. In that case, for members provided in the visible-light-transmitting region 72, materials having a property of transmitting visible light are used.

In the visible-light-blocking region 73, a wiring electrically connected to the pixels included in the pixel portion 103 may be provided, for example. Moreover, one or both of a scan line driver circuit and a signal line driver circuit may be provided in the visible-light-blocking region 73. Furthermore, a terminal connected to the FPC 74, a wiring connected to the terminal, and the like may be provided in the visible-light-blocking region 73.

FIG. 27B and FIG. 27C illustrate an example in which the display modules DP each of which is illustrated in FIG. 27A are arranged in a 2×2 matrix (two display modules DP are arranged in the longitudinal direction and the lateral direction). FIG. 27B is a perspective view of the display surface side of the display modules DP, and FIG. 27C is a perspective view of the side opposite to the display surface side of the display modules DP.

Four display modules DP (display modules DPa, DPb, DPc, and DPd) are arranged to have regions overlapping with one another. Specifically, the display modules DPa, DPb, DPc, and DPd are arranged such that the visible-light-transmitting region 72 included in one display module DP (72a of the display module DPa, 72b of the display module DPb, 72c of the display module DPc, or 72d of the display module DPd) has a region overlapping with the pixel portion 103 (on the display surface side) included in another display module DP. In addition, the display modules DPa, DPb, DPc, and DPd are arranged such that the visible-light-blocking region 73 included in each of the display modules DP does not overlap with the pixel portion 103 of another display module DP. In a portion where four display modules DP overlap with one another, the display module DPb is stacked over the display module DPa, the display module DPc is stacked over the display module DPb, and the display module DPd is stacked over the display module DPc.

The short sides of the display modules DPa and DPb overlap with each other, and part of a pixel portion 103a and part of the visible-light-transmitting region 72b overlap with each other. Furthermore, the long sides of the display modules DPa and DPc overlap with each other, and part of the pixel portion 103a and part of the visible-light-transmitting region 72c overlap with each other.

Part of a pixel portion 103b overlaps with part of the visible-light-transmitting region 72c and part of the visible-light-transmitting region 72d. In addition, part of a pixel portion 103c overlaps with part of the visible-light-transmitting region 72d.

Thus, a region where the pixel portion 103a to a pixel portion 103d are placed almost seamlessly can be a display region 79.

Here, it is preferable that the display module DP have flexibility. For example, the pair of substrates included in the display module DP preferably have flexibility.

Thus, as illustrated in FIG. 27B and FIG. 27C, the vicinity of an FPC 74a of the display module DPa can be bent such that part of the display module DPa and part of the FPC 74a are placed under the pixel portion 103b of the display module DPb adjacent to the FPC 74a, for example. As a result, the FPC 74a can be placed without physical interference with the rear surface of the display module DPb. Furthermore, when the display module DPa and the display module DPb overlap with and are fixed to each other, it is not necessary to consider the thickness of the FPC 74a; thus, the level difference between the top surface of the visible-light-transmitting region 72b and the top surface of the display module DPa can be reduced. This can make the end portion of the display module DPb positioned over the pixel portion 103a less noticeable. As illustrated in FIG. 27C, an FPC 74c of the display module DPc is preferably bent in a manner similar to that of the FPC 74a.

Moreover, when each of the display modules DP has flexibility, the display module DPb can be curved gently such that the top surface of the pixel portion 103b of the display module DPb is level with the top surface of the pixel portion 103a of the display module DPa. Thus, the display regions can be level with each other except in the vicinity of a region where the display module DPa and the display module DPb overlap with each other, and the display quality of a video displayed on the display region 79 can be improved.

Although the relationship between the display module DPa and the display module DPb is taken as an example in the above description, the same can apply to the relationship between any other two adjacent display modules DP.

Note that to reduce a step between two adjacent display modules DP, the thicknesses of the display modules DP are preferably small. For example, the thicknesses of the display modules DP are preferably less than or equal to 1 mm, further preferably less than or equal to 300 μm, still further preferably less than or equal to 100 μm.

The display module DP preferably incorporates both a scan line driver circuit and a signal line driver circuit. In the case where a driver circuit is provided separately from the display panel, a printed circuit board including a driver circuit and a large number of wirings, terminals, and the like are provided on the back side (the side opposite to the display surface side) of the display panel. Thus, the number of components of the whole display device becomes enormous, which leads to an increase in weight of the display device in some cases. When the display module DP incorporates both a scan line driver circuit and a signal line driver circuit, the number of components of the display device can be reduced and the weight of the display device can be reduced. This leads to higher portability of the display device.

Here, the scan line driver circuit and the signal line driver circuit are required to operate at a high driving frequency in accordance with the frame frequency of an image to be displayed. In particular, the signal line driver circuit is required to operate at a higher driving frequency than the scan line driver circuit. Thus, some transistors used for the signal line driver circuit require the capability of supplying a large amount of current in some cases. Meanwhile, some transistors provided in the pixel portion require adequate withstand voltage for driving a display element in some cases.

In view of the above, the transistor included in the driver circuit and the transistor included in the pixel portion are preferably formed to have different structures. For example, a transistor with high withstand voltage is used as one or more of the transistors provided in the pixel portion, and a transistor with a high driving frequency is used as one or more of the transistors provided in the driver circuit.

Specifically, one or more of the transistors used for the signal line driver circuit include a gate insulating layer thinner than that of the transistor used for the pixel portion. By forming two kinds of transistors separately as described above, the signal line driver circuit can be formed over the substrate where the pixel portion is provided.

In each transistor used for the scan line driver circuit, the signal line driver circuit, and the pixel portion, a metal oxide is preferably used for a semiconductor where a channel is formed.

Alternatively, in each transistor used for the scan line driver circuit, the signal line driver circuit, and the pixel portion, silicon is preferably used for a semiconductor where a channel is formed.

As transistors used for the scan line driver circuit, the signal line driver circuit, and the pixel portion, a transistor in which a metal oxide is used for a semiconductor where a channel is formed and a transistor in which silicon is used for a semiconductor where a channel is formed are preferably used in combination.

This embodiment can be combined with any of the other embodiments as appropriate. In the case where a plurality of structure examples are described in one embodiment in this specification, the structure examples can be combined as appropriate.

### Embodiment 10

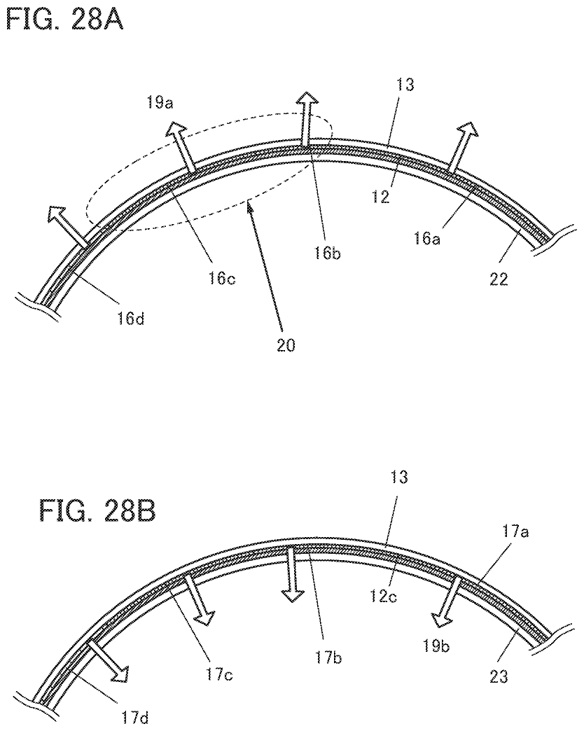

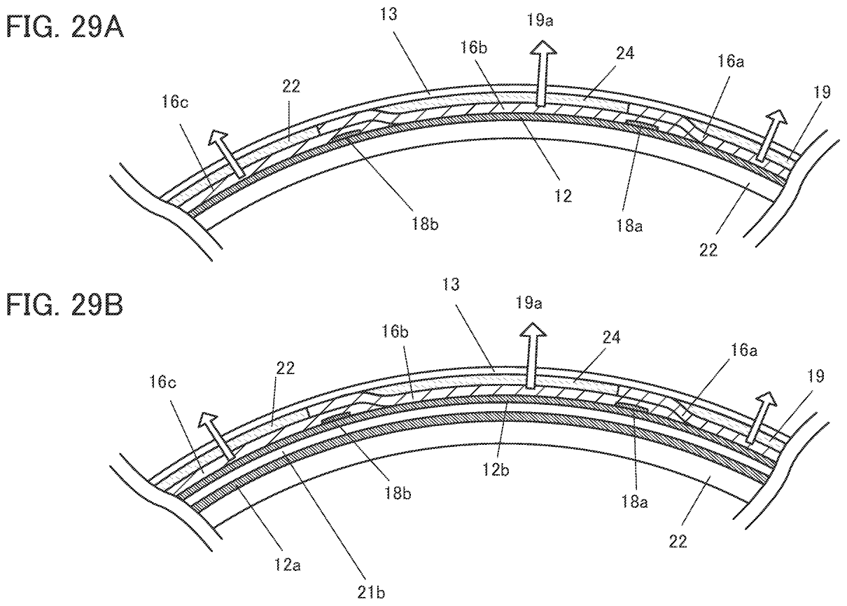

In this embodiment, a large display device using the plurality of flexible display modules DP will be described with reference to FIG. 28, FIG. 29, and the like. The large display device using the plurality of display modules DP has a curved display surface. When such a large display device is seen, a sense of immersion can be obtained.

FIG. 28A is a cross-sectional view of a display device in which a pixel portion is provided in a support 22 having a curved surface. Although an FPC is not illustrated in FIG. 28A, the FPC can be provided in a manner similar to that in the above embodiment. FIG. 29A is an enlarged view of a region 20 surrounded by a dotted line in FIG. 28A.

The support 22 can also be referred to as a housing or a support member and is formed using a component that can partly have a curved surface. In the case where the display device is provided inside a motor vehicle, for example, plastic, a metal, glass, rubber, or the like can be used for the support 22. Although the support 22 having a plate-like shape is illustrated in FIG. 28A, the shape of the support 22 is not limited to a plate-like shape and the support 22 has a shape partly having a curved surface.

In FIG. 28A, four display modules of a first display module 16a, a second display module 16b, a third display module 16c, and a fourth display module 16d are arranged side by side. Pixel portions of the display modules can be arranged side by side to form one display surface. Although FIG. 28A illustrates an example in which the four display modules form one display surface in the display device, there is no particular limitation and two or more display modules can form one display surface. Arrows in FIG. 28A indicate light-emitting directions 19a of the third display module 16c.

A wiring layer 12 is provided over the support 22. The wiring layer 12 includes a plurality of wirings. At least one of the plurality of wirings is electrically connected to an electrode included in the second display module 16b. The wiring layer 12 includes, in addition to the wirings, an insulating film covering the wirings. A contact hole is provided in the insulating film, and the plurality of wirings of the wiring layer 12 can be electrically connected to electrodes included in the display modules through the contact hole. The wirings of the wiring layer 12 can each function as a connection wiring, a power supply line, a signal line, a fixed potential line, or the like.

The wirings of the wiring layer 12 can be formed over the support 22 by a method in which a silver paste is selectively formed, a transposition method, or a transfer method.

In the display device illustrated in FIG. 28A, the wirings of the wiring layer 12 can function as common wirings. The common wirings refer to wirings that can be shared by at least the first display module 16a and the second display module 16b. For example, the wirings of the wiring layer 12 can be electrically connected to the electrode of the first display module 16a and can be electrically connected also to the electrode of the second display module 16b. Note that the common wirings may be shared also by the third display module 16c and the like. Such common wirings preferably function as power supply lines.

The viewing surfaces of the first display module 16a, the second display module 16b, and the third display module 16c are preferably covered with a cover member 13. As illustrated in FIG. 29A, the cover member 13 is bonded to each of the display modules with the use of a resin 24 or the like. For example, by adjusting the refractive index of the resin 24, lines (vertical stripes or horizontal stripes) that might be generated around the boundaries between the first display module 16a, the second display module 16b, and the third display module 16c can be less noticeable. The structure in which the cover member 13 is bonded to each of the display modules with the use of the resin 24 allows the first display module 16a, the second display module 16b, the third display module 16c, and the fourth display module 16d to be fixed firmly.

For the cover member 13, for example, polyimide (PI), aramid, polyethylene terephthalate (PET), polyethersulfone (PES), polyethylene naphthalate (PEN), polycarbonate (PC), nylon, polyetheretherketone (PEEK), polysulfone (PSF), polyetherimide (PET), polyarylate (PAR), polybutylene terephthalate (PBT), or a silicone resin can be used. A substrate containing any of these materials can be referred to as a plastic substrate. The plastic substrate has a light-transmitting property and has a film-like shape.

The cover member 13 may be formed using an optical film (a polarizing film, a circularly polarizing film, or a light-scattering film). Alternatively, a stacked-layer film in which a plurality of optical films are stacked may be used as the cover member 13.

In FIG. 29A, the end portion of the second display module 16b and the end portion of the third display module 16c overlap with each other. An electrode 18b of the third display module 16c is provided in the region where the end portions overlap with each other, and the electrode 18b is electrically connected to the wirings of the wiring layer 12. When the vicinity of the electrode 18b overlaps with the end of the pixel portion of the second display module 16b, a line (a vertical stripe or a horizontal stripe) that might be generated around the boundary between the third display module 16c and the second display module 16b can be less noticeable.

Also when a light-blocking layer such as a black matrix is placed to overlap with the vicinity of the boundary, a line (a vertical stripe or a horizontal stripe) that might be generated around the boundary between the third display module 16c and the second display module 16b can be less noticeable.

When the vicinity of an electrode 18a of the second display module 16b overlaps with the end of the pixel portion of the first display module 16a, a line (a vertical stripe or a horizontal stripe) that might be generated around the boundary between the first display module 16a and the second display module 16b can be less noticeable.

Also when a light-blocking layer such as a black matrix is placed to overlap with the vicinity of the boundary, a line (a vertical stripe or a horizontal stripe) that might be generated around the boundary between the first display module 16a and the second display module 16b can be less noticeable.

The wiring layer 12 can have a multilayer structure and an example of such a case is illustrated in FIG. 29B.

In FIG. 29B, the support 22 having a curved surface is provided with a stack including a wiring layer 12a, an insulating film 21b over the wiring layer 12a, and a wiring layer 12b over the insulating film 21b. The wirings of the wiring layer 12a and the wiring layer 12b may be arranged to intersect with each other. Like the wiring layer 12 in FIG. 29A, the wiring layer 12b can be electrically connected to the electrodes of the display modules. The wiring layer 12a can be electrically connected to the electrodes of the display modules through a contact hole provided in the insulating film 21b.

The wirings of the wiring layer 12 can function as some lead wirings of the first display module 16a, the second display module 16b, the third display module 16c, and the fourth display module 16d. The wiring density in each of the display modules can be reduced to decrease the parasitic capacitance, for example.

FIG. 28B illustrates a modification example of the structure in FIG. 28A. Light-emitting directions 19b in FIG. 28B are different from the light-emitting directions 19a in FIG. 28A. That is, the display surface in FIG. 28A has a convex shape and the display surface in FIG. 28B has a concave shape.

In FIG. 28B, a wiring layer 12c is provided, and a fifth display module 17a, a sixth display module 17b, a seventh display module 17c, and an eighth display module 17d are arranged side by side and fixed to a support 23 having a light-transmitting property. Note that the fifth display module 17a and the like can have structures similar to those of the first display module 16a and the like.

The material of the cover member 13 in the display device illustrated in FIG. 28B does not necessarily have a light-transmitting property, and a ceiling of a motor vehicle can be used for the cover member 13. Furthermore, a glass roof can be used for the cover member 13. The support 23 having a light-transmitting property is placed on the viewing surface, and the support 23 has a curved surface.

Although FIG. 28B illustrates an example in which the four display modules form one display surface in the display device, there is no particular limitation and two or more display modules can form one display surface.

The entire surface of the support illustrated in each of FIG. 28A to FIG. 29B is not necessarily a curved surface, and part of the surface may be a flat surface. The flat surface can be provided in accordance with, for example, a component inside a motor vehicle (e.g., a dashboard, a ceiling, a pillar, window glass, a steering wheel, a seat, or an inner portion of a door).

Furthermore, the display surface, i.e., the viewing surface, of the display device can be provided with a touch sensor. With the touch sensor, the display surface that can be operated by touch of a hand or a finger of a driver of a motor vehicle can be provided.

The flexible substrate included in the support is more fragile than a glass substrate. Thus, in the case where the touch sensor is provided, a surface protective film is preferably provided to prevent a scratch from being caused by touch of a hand or a finger. As the surface protective film, a silicon oxide film having optically good characteristics (a high visible light transmittance or a high infrared light transmittance) is preferably used. The surface protective film may be formed using DLC (diamond-like carbon), aluminum oxide (alumina, AlOx), a polyester-based material, a polycarbonate-based material, or the like. Note that a material having high hardness is suitable for the surface protective film. Providing the surface protective film can prevent dirt from attaching to the support.

In the case where the surface protective film is formed by a coating method, the surface protective film can be formed before the display device is fixed to the support having a curved surface or can be formed after the display device is fixed to the support having a curved surface.

In this manner, a large display device having a curved surface can be provided. When a large display device having a curved surface is seen, a sense of immersion can be obtained.

This embodiment can be implemented in combination with any of the other embodiments described in this specification and the like as appropriate. For example, part of the structure described in this embodiment may be implemented in combination with any of the other embodiments described in this specification and the like as appropriate.

### Embodiment 11

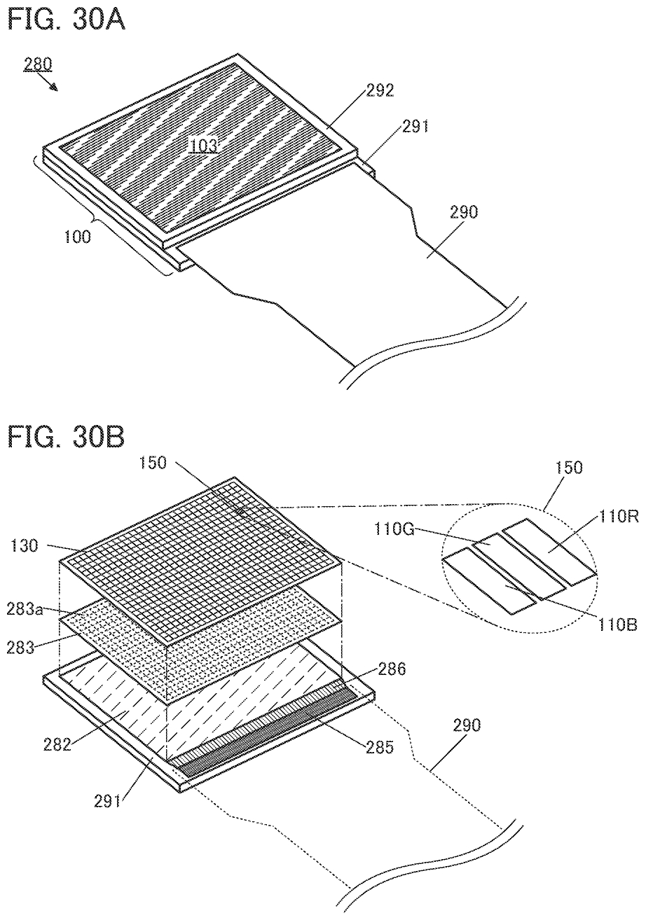

In this embodiment, a display device of one embodiment of the present invention will be described with reference to FIG. 30.

The display device in this embodiment can be a high-resolution display device. Accordingly, the display device in this embodiment can be used for display portions of information terminals (wearable devices) such as watch-type and bracelet-type information terminals and display portions of wearable devices that can be worn on a head, such as a VR device like a head-mounted display and a glasses-type AR device.

### [Display Module]

FIG. 30A is a perspective view of a display module 280. The display module 280 includes the display device 100 and an FPC 290.

The display module 280 includes a substrate 291 and a substrate 292. The display module 280 includes the pixel portion 103. The pixel portion 103 is a region of the display module 280 where an image is displayed, and is a region where light from pixels provided in the pixel portion 103 described later can be seen.

FIG. 30B is a perspective view schematically illustrating a structure on the substrate 291 side. Over the substrate 291, a circuit portion 282, a pixel circuit portion 283 over the circuit portion 282, and the pixel portion 103 over the pixel circuit portion 283 are stacked. A terminal portion 285 (sometimes referred to as an FPC terminal portion) to be connected to the FPC 290 is provided in a portion that is over the substrate 291 and does not overlap with the pixel portion 103. The terminal portion 285 and the circuit portion 282 are electrically connected to each other through a wiring portion 286 formed of a plurality of wirings.

The pixel portion 103 includes the plurality of pixels 150 arranged periodically. An enlarged view of one pixel 150 is shown on the right side of FIG. 30B. The pixel 150 includes the subpixels 110 that emit light of different colors. The plurality of light-emitting devices can be laid out in stripe arrangement as illustrated in FIG. 30B. Alternatively, a variety of arrangement methods of light-emitting devices, such as delta arrangement and PenTile arrangement, can be employed.

The pixel circuit portion 283 includes pixel circuits 283a including a plurality of transistors and the like arranged periodically.

One pixel circuit 283a is a circuit that controls light emission from light-emitting devices included in one pixel 150. One pixel circuit 283a may be provided with three circuits each of which controls light emission from one light-emitting device. For example, the pixel circuit 283a can include at least one selection transistor, one current control transistor (driving transistor), and a capacitor for one light-emitting device. In that case, a gate signal is input to a gate of the selection transistor, and a source signal is input to one of a source and a drain of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 103; hence, the aperture ratio (effective display area ratio) of the pixel portion 103 can be significantly high. For example, an aperture ratio of the pixel portion 103 can be higher than or equal to 40% and lower than 100%, preferably higher than or equal to 50% and lower than or equal to 95%, further preferably higher than or equal to 60% and lower than or equal to 95%. Furthermore, the pixels 150 can be laid out extremely densely, and thus the resolution of the pixel portion 103 can be extremely high. For example, the pixels 150 are preferably laid out in the pixel portion 103 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution and thus can be suitably used for a VR device such as a head-mounted display or a glasses-type AR device. For example, even with a structure in which the display portion of the display module 280 is seen through a lens, pixels of the extremely-high-density pixel portion 103 included in the display module 280 are prevented from being perceived when the display portion is enlarged by the lens, so that display providing a high sense of immersion can be performed. Without being limited thereto, the display module 280 can be suitably used for electronic devices including relatively small display portions. For example, the display module 280 can be suitably used in a display portion of a wearable electronic device such as a watch.

This embodiment can be combined with any of the other embodiments as appropriate. In the case where a plurality of structure examples are described in one embodiment in this specification, the structure examples can be combined as appropriate.

### Embodiment 12

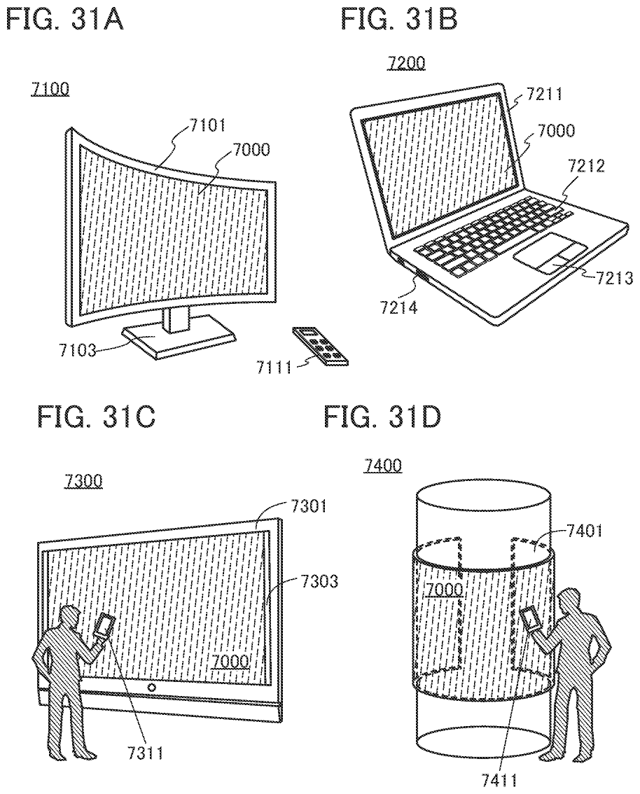

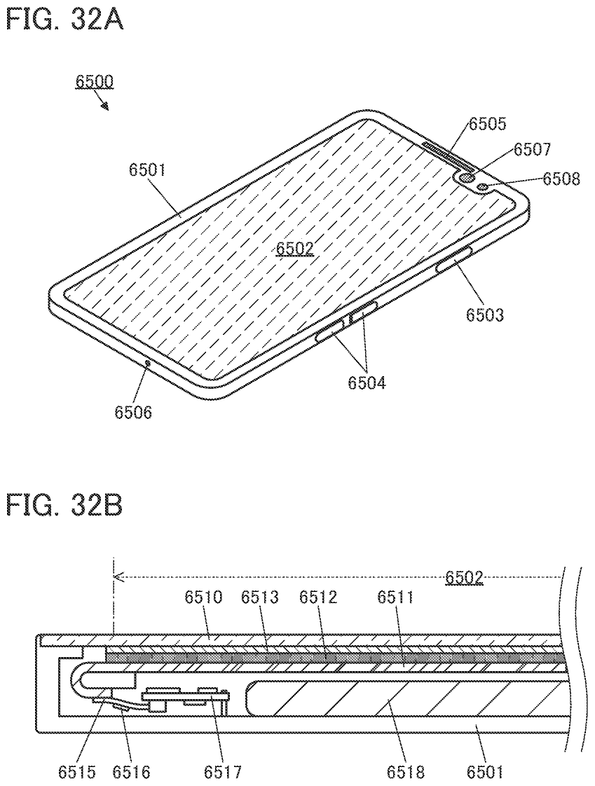

In this embodiment, electronic devices of one embodiment of the present invention will be described with reference to FIG. 31 and FIG. 32.

Electronic devices of this embodiment are each provided with the display device of one embodiment of the present invention in a display portion. The display device of one embodiment of the present invention can be easily increased in resolution and definition. Thus, the display device of one embodiment of the present invention can be used for display portions of a variety of electronic devices.

Examples of electronic devices include a digital camera, a digital video camera, a digital photo frame, a mobile phone, a portable game machine, a portable information terminal, and an audio reproducing device in addition to electronic devices with a relatively large screen, such as a television device, a desktop or laptop personal computer, a monitor of a computer or the like, digital signage, and a large game machine like a pachinko machine.

In particular, the display device of one embodiment of the present invention can have a high resolution, and thus can be suitably used for an electronic device having a relatively small display portion. Examples of such an electronic device include watch-type and bracelet-type information terminals (wearable devices) and wearable devices that can be worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. Furthermore, the pixel density (resolution) of the display device of one embodiment of the present invention is preferably higher than or equal to 100 ppi, preferably higher than or equal to 30) ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of such a display device having one or both of high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

FIG. 31A illustrates an example of a television device. In a television device 7100, a display portion 7000 is incorporated in a housing 7101. Here, the housing 7101 is supported by a stand 7103.

The pixel portion 103 of one embodiment of the present invention can be used as the display portion 7000.

Operation of the television device 7100 illustrated in FIG. 31A can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) information communication can be performed.

FIG. 31B illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The pixel portion 103 of one embodiment of the present invention can be used as the display portion 7000.

FIG. 31C and FIG. 31D illustrate examples of digital signage.

Digital signage 7300 illustrated in FIG. 31C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 31D is digital signage 7400 attached to a cylindrical pillar 7401. The digital signage 7400 includes the display portion 7000 provided along a curved surface of the pillar 7401.

The pixel portion 103 of one embodiment of the present invention can be used as the display portion 7000 in FIG. 31C and FIG. 31D.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 31C and FIG. 31D, it is preferable that the digital signage 7300 or the digital signage 7400 be capable of working with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

An electronic device 6500 illustrated in FIG. 32A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The pixel portion 103 of one embodiment of the present invention can be used in the display portion 6502.

FIG. 32B is a cross-sectional view including the end portion of the housing 6501 on the microphone 6506 side.

A protection member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while the thickness of the electronic device is reduced. Moreover, part of the display panel 6511 is folded back such that a connection portion with the FPC 6515 is provided on the back side of the pixel portion, whereby an electronic device with a narrow bezel can be achieved.

This embodiment can be combined with any of the other embodiments as appropriate. In the case where a plurality of structure examples are described in one embodiment in this specification, the structure examples can be combined as appropriate.

### REFERENCE NUMERALS

103: pixel portion, 111: lower electrode, 111R: lower electrode, 111G: lower electrode, 111B: lower electrode, 112: organic compound layer, 112R: organic compound layer, 112G: organic compound layer. 112B: organic compound layer, 113: upper electrode, 115: charge-generation layer, 151; auxiliary wiring, 151a: first wiring layer. 151b: second wiring layer

1. A display device comprising:
a first light-emitting device comprising a first lower electrode, a first light-emitting layer over the first lower electrode, a first layer over the first light-emitting layer, and a second light-emitting layer over the first layer;
a second light-emitting device comprising a second lower electrode, a third light-emitting layer over the second lower electrode, a second layer over the third light-emitting layer, and a fourth light-emitting layer over the second layer;
a common electrode included in the first light-emitting device and the second light-emitting device; and
an auxiliary wiring electrically connected to the common electrode,
wherein a color exhibited by a light-emitting material included in the first light-emitting layer is the same as a color exhibited by a light-emitting material included in the second light-emitting layer,
wherein a color exhibited by a light-emitting material included in the third light-emitting layer is the same as a color exhibited by a light-emitting material included in the fourth light-emitting layer,
wherein the first layer and the second layer each comprise lithium,
wherein the auxiliary wiring comprises a first wiring layer and a second wiring layer,
wherein the second wiring layer is electrically connected to the first wiring layer through a contact hole of an insulating layer, and
wherein the first wiring layer has a lattice shape in a top view.

2. A display device comprising:
a first light-emitting device comprising a first lower electrode, a first light-emitting layer over the first lower electrode, a first layer over the first light-emitting layer, and a second light-emitting layer over the first layer;
a second light-emitting device comprising a second lower electrode, a third light-emitting layer over the second lower electrode, a second layer over the third light-emitting layer, and a fourth light-emitting layer over the second layer;
a common electrode included in the first light-emitting device and the second light-emitting device; and
an auxiliary wiring electrically connected to the common electrode,
wherein a color exhibited by a light-emitting material included in the first light-emitting layer is the same as a color exhibited by a light-emitting material included in the second light-emitting layer,
wherein a color exhibited by a light-emitting material included in the third light-emitting layer is the same as a color exhibited by a light-emitting material included in the fourth light-emitting layer,
wherein the first layer and the second layer each comprise lithium,
wherein the auxiliary wiring comprises a first wiring layer and a second wiring layer,
wherein the second wiring layer is electrically connected to the first wiring layer through a contact hole of an insulating layer,
wherein the first wiring layer has a lattice shape in a top view, and
wherein each of the first lower electrode, the second lower electrode, and the second wiring layer comprises a region over the insulating layer.

3. A display device comprising:
a first light-emitting device comprising a first lower electrode, a first light-emitting layer over the first lower electrode, a first layer over the first light-emitting layer, and a second light-emitting layer over the first layer;
a second light-emitting device comprising a second lower electrode, a third light-emitting layer over the second lower electrode, a second layer over the third light-emitting layer, and a fourth light-emitting layer over the second layer;
a common electrode included in the first light-emitting device and the second light-emitting device; and
an auxiliary wiring electrically connected to the common electrode,
wherein a color exhibited by a light-emitting material included in the first light-emitting layer is the same as a color exhibited by a light-emitting material included in the second light-emitting layer,
wherein a color exhibited by a light-emitting material included in the third light-emitting layer is the same as a color exhibited by a light-emitting material included in the fourth light-emitting layer,
wherein the first layer and the second layer each comprise lithium,
wherein the auxiliary wiring comprises a first wiring layer and a second wiring layer,
wherein the second wiring layer is electrically connected to the first wiring layer through a contact hole of an insulating layer,
wherein each of the first wiring layer and the second wiring layer has a lattice shape in a top view,
wherein each of the first lower electrode, the second lower electrode, and the second wiring layer comprises a region over the insulating layer, and
wherein a width of the second wiring layer is smaller than a width of the first wiring layer.

4. A display device comprising:
a first light-emitting device comprising a first lower electrode, a first light-emitting layer over the first lower electrode, a first layer over the first light-emitting layer, and a second light-emitting layer over the first layer;
a first color filter overlapping with the first light-emitting device;
a second light-emitting device comprising a second lower electrode, a third light-emitting layer over the second lower electrode, a second layer over the third light-emitting layer, and a fourth light-emitting layer over the second layer;
a second color filter overlapping with the second light-emitting device;
a common electrode included in the first light-emitting device and the second light-emitting device; and
an auxiliary wiring electrically connected to the common electrode,
wherein a color exhibited by a light-emitting material included in the first light-emitting layer is the same as a color exhibited by a light-emitting material included in the second light-emitting layer,
wherein a color exhibited by a light-emitting material included in the third light-emitting layer is the same as a color exhibited by a light-emitting material included in the fourth light-emitting layer,
wherein the first layer and the second layer each comprise lithium,
wherein the auxiliary wiring comprises a first wiring layer and a second wiring layer,
wherein the second wiring layer is electrically connected to the first wiring layer through a contact hole of an insulating layer, and
wherein the first wiring layer has a lattice shape in a top view.

5. A display device comprising:
a first light-emitting device comprising a first lower electrode, a first light-emitting layer over the first lower electrode, a first layer over the first light-emitting layer, and a second light-emitting layer over the first layer;
a first color filter overlapping with the first light-emitting device;
a second light-emitting device comprising a second lower electrode, a third light-emitting layer over the second lower electrode, a second layer over the third light-emitting layer, and a fourth light-emitting layer over the second layer;
a second color filter overlapping with the second light-emitting device;
a common electrode included in the first light-emitting device and the second light-emitting device; and
an auxiliary wiring electrically connected to the common electrode,
wherein a color exhibited by a light-emitting material included in the first light-emitting layer is the same as a color exhibited by a light-emitting material included in the second light-emitting layer,
wherein a color exhibited by a light-emitting material included in the third light-emitting layer is the same as a color exhibited by a light-emitting material included in the fourth light-emitting layer,
wherein the first layer and the second layer each comprise lithium,
wherein the auxiliary wiring comprises a first wiring layer and a second wiring layer,
wherein the second wiring layer is electrically connected to the first wiring layer through a contact hole of an insulating layer,
wherein the first wiring layer has a lattice shape in a top view, and
wherein each of the first lower electrode, the second lower electrode, and the second wiring layer comprises a region over the insulating layer.

6. A display device comprising:
a first light-emitting device comprising a first lower electrode, a first light-emitting layer over the first lower electrode, a first layer over the first light-emitting layer, and a second light-emitting layer over the first layer;
a first color filter overlapping with the first light-emitting device;
a second light-emitting device comprising a second lower electrode, a third light-emitting layer over the second lower electrode, a second layer over the third light-emitting layer, and a fourth light-emitting layer over the second layer;
a second color filter overlapping with the second light-emitting device;
a common electrode included in the first light-emitting device and the second light-emitting device; and
an auxiliary wiring electrically connected to the common electrode,
wherein a color exhibited by a light-emitting material included in the first light-emitting layer is the same as a color exhibited by a light-emitting material included in the second light-emitting layer,
wherein a color exhibited by a light-emitting material included in the third light-emitting layer is the same as a color exhibited by a light-emitting material included in the fourth light-emitting layer,
wherein the first layer and the second layer each comprise lithium,
wherein the auxiliary wiring comprises a first wiring layer and a second wiring layer,
wherein the second wiring layer is electrically connected to the first wiring layer through a contact hole of an insulating layer,
wherein each of the first wiring layer and the second wiring layer has a lattice shape in a top view,
wherein each of the first lower electrode, the second lower electrode, and the second wiring layer comprises a region over the insulating layer, and
wherein a width of the second wiring layer is smaller than a width of the first wiring layer.

7. The display device according to claim 1,
wherein a distance between the first lower electrode and the common electrode is shorter than a distance between the second lower electrode and the common electrode.

8. The display device according to claim 1,
wherein an end portion of the first lower electrode and an end portion of the second lower electrode each have a tapered shape.

9. The display device according to claim 1,
wherein a taper angle of an end surface of an organic compound layer comprising the first light-emitting layer and the second light-emitting layer is greater than or equal to 450 and less than 90° in a cross-sectional view.

10. The display device according to claim 1,
wherein a taper angle of an end surface of an organic compound layer comprising the third light-emitting layer and the fourth light-emitting layer is greater than or equal to 45° and less than 90° in a cross-sectional view.
